(19) United States
(12) Patent Application Publication
(10) Pub. No.: US 2026/0313815 A1
(43) Pub. Date: Oct. 8, 2026

(54) ELECTRONIC DEVICE AND OPERATION METHOD THEREOF

(71) Applicant: Samsung Electronics Co., Ltd., Suwon-si (KR)

(72) Inventors: Gyudae JANG, Suwon-si (KR); Byoungjun KIM, Suwon-si (KR); Sunglak KIM, Suwon-si (KR); Hyunmuk KIM, Suwon-si (KR); Jooyeol RYU, Suwon-si (KR); Shinhyuk YOON, Suwon-si (KR); Jaeyoung JUN, Suwon-si (KR); Jinwook CHOI, Suwon-si (KR)

(21) Appl. No.: 19/461,237

(22) Filed: Jan. 27, 2026

Related U.S. Application Data
(63) Continuation of application No. PCT/KR2024/010786, filed on Jul. 25, 2024.

(30) Foreign Application Priority Data
Aug. 28, 2023 (KR) 10-2023-0112697
Sep. 27, 2023 (KR) 10-2023-0130366

(51) Int. Cl. H05K 5/02; H02J 7/00; H02J 7/50; H05K 5/00

(52) U.S. Cl. CPC H05K 5/0247; H02J 7/575; H02J 7/855; H05K 5/0086; H05K 5/0226

(57) ABSTRACT

An electronic device is provided. The electronic device includes a first housing in which a first charging circuit, a first battery, a first load, and a first sensing resistor are disposed, a second housing in which a second battery, a second load, and a second sensing resistor are disposed, a third housing in which a third battery, a third load, and a third sensing resistor are disposed, a first hinge rotatably connecting the first housing and the second housing, a second hinge rotatably connecting the first housing and the third housing, a flexible display disposed in the first housing, the second housing, and the third housing, memory configured to store a program including instructions, and at least one processor. The instructions, when executed by the at least one processor individually or collectively, are configured to instruct the electronic device to control a first discharge power provided from the first battery to the first load on the basis of a first current of the first sensing resistor. The instructions, when executed by the at least one controller, are configured to instruct the electronic device to control a second discharge power provided from the second battery to the second load on the basis of a second current of the second sensing resistor. The instructions, when executed by the at least one controller, are configured to instruct the electronic device to control a third discharge power provided from the third battery to the third load on the basis of a third current of the third sensing resistor.

### CROSS-REFERENCE TO RELATED APPLICATION(S)

This application is a continuation application, claiming priority under 35 U.S.C. § 365(c), of an International application No. PCT/KR2024/010786, filed on Jul. 25, 2024, which is based on and claims the benefit of a Korean patent application number 10-2023-0112697, filed on Aug. 28, 2023, in the Korean Intellectual Property Office, and of a Korean patent application number 10-2023-0130366, filed on Sep. 27, 2023, in the Korean Intellectual Property Office, the disclosure of each of which is incorporated by reference herein in its entirety.

### BACKGROUND

### 1. Field

The disclosure relates to an electronic device and an operation method thereof.

### 2. Description of Related Art

In line with the remarkable advancements in information/communication technology and semiconductor technology, the dissemination and use of various electronic devices have been rapidly increasing. In particular, recent electronic devices are being developed to be carried and used for communication.

Electronic devices may refer to devices that perform specific functions according to installed programs, such as home appliances, electronic notebooks, portable multimedia players, mobile communication terminals, tablet PCs, video/audio devices, desktop/laptop computers, or car navigation systems.

A foldable device may be equipped with a foldable (or bendable) display (e.g., a foldable display or a flexible display) and may be used in a folded or unfolded state. A foldable device may be equipped with a separate battery for each of multiple housings.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device and an operation method thereof.

Additional aspects will be set forth in part in the description which follows and, in part, will be apparent from the description, or may be learned by practice of the presented embodiments.

In accordance with an aspect of the disclosure, an electronic device is provided. The electronic device includes a first housing having a first charging circuit, a first battery, a first load, and a first sensing resistor disposed therein, a second housing having a second battery, a second load, and a second sensing resistor disposed therein, a third housing having a third battery, a third load, and a third sensing resistor disposed therein, a first hinge rotatably connecting the first housing and the second housing, a second hinge rotatably connecting the first housing and the third housing, a flexible display disposed in the first housing, the second housing, and the third housing, memory configured to store a program including instructions, and at least one processor. The instructions are configured to, when executed by the at least one processor individually or collectively, cause the electronic device to control first discharge power provided from the first battery to the first load, based on a first current of the first sensing resistor. The instructions are configured to, when executed by the at least one processor individually or collectively, cause the electronic device to control second discharge power provided from the second battery to the second load, based on a second current of the second sensing resistor. The instructions are configured to, when executed by the at least one processor individually or collectively, cause the electronic device to control third discharge power provided from the third battery to the third load, based on a third current of the third sensing resistor.

In accordance with another aspect of the disclosure, a method performed ban electronic device is provided. The method includes an operation of controlling, based on a first current of a first sensing resistor disposed in a first housing of the electronic device, a first discharge power provided from a first battery of the electronic device disposed in the first housing to a first load of the electronic device disposed in the first housing. The method includes an operation of controlling, based on a second current of a second sensing resistor disposed in a second housing of the electronic device, a second discharge power provided from a second battery of the electronic device disposed in the second housing to a second load of the electronic device disposed in the second housing. The method includes an operation of controlling, based on a third current of a third sensing resistor disposed in a third housing of the electronic device, a third discharge power provided from a third battery of the electronic device disposed in the third housing to a third load of the electronic device disposed in the third housing. The electronic device includes a first charging circuit disposed in the first housing, and a flexible display disposed in the first housing, the second housing, and the third housing.

In accordance with another aspect of the disclosure, one or more non-transitory computer-readable recording media storing one or more computer programs including computer-executable instructions configured to, when executed by at least one processor of an electronic device individually or collectively, cause the electronic device to perform operations, is provided. The operations include an operation of controlling, based on a first current of a first sensing resistor disposed in a first housing of the electronic device, a first discharge power provided from a first battery of the electronic device disposed in the first housing to a first load of the electronic device disposed in the first housing. The operations include an operation of controlling, based on a second current of a second sensing resistor disposed in a second housing of the electronic device, a second discharge power provided from a second battery of the electronic device disposed in the second housing to a second load of the electronic device disposed in the second housing. The operations include an operation of controlling, based on a third current of a third sensing resistor disposed in a third housing of the electronic device, a third discharge power provided from a third battery of the electronic device disposed in the third housing to a third load of the electronic device disposed in the third housing. The electronic device includes a first charging circuit disposed in the first housing, and a flexible display disposed in the first housing, the second housing, and the third housing.

In accordance with another aspect of the disclosure, an electronic device is provided. The electronic device includes a first housing having a first charging circuit, a first battery, a first load, and a first sensing resistor disposed therein, a second housing having a second battery, a second load, and a second sensing resistor disposed therein, a third housing having a third battery, a third load, and a third sensing resistor disposed therein, a first hinge rotatably connecting the first housing and the second housing, a second hinge rotatably connecting the second housing and the third housing, a flexible display disposed in the first housing, the second housing, and the third housing, memory configured to store a program including instructions, and at least one processor. The instructions are configured to, when executed by the at least one processor individually or collectively, cause the electronic device to control first discharge power provided from the first battery to the first load, based on a first current of the first sensing resistor. The instructions are configured to, when executed by the at least one processor individually or collectively, cause the electronic device to control second discharge power provided from the second battery to the second load, based on a second current of the second sensing resistor. The instructions are configured to, when executed by the at least one processor individually or collectively, cause the electronic device to control third discharge power provided from the third battery to the third load, based on a third current of the third sensing resistor.

In accordance with another aspect of the disclosure, a method performed by an electronic device is provided. The method includes an operation of, based on a first current of a first sensing resistor disposed in a first housing of the electronic device, controlling first discharge power provided from a first battery disposed in the first housing to a first load disposed in the first housing. The method includes an operation of, based on a second current of a second sensing resistor disposed in a second housing of the electronic device, controlling second discharge power provided from a second battery disposed in the second housing to a second load disposed in the second housing. The method includes an operation of, based on a third current of a third sensing resistor disposed in a third housing of the electronic device, controlling third discharge power provided from a third battery disposed in the third housing to a third load disposed in the third housing. The electronic device includes a first charging circuit disposed in the first housing, and a flexible display disposed in the first housing, the second housing, and the third housing.

In accordance with another aspect of the disclosure, one or more non-transitory computer-readable recording media storing one or more computer programs including computer-executable instructions configured to, when executed by at least one processor of an electronic device individually or collectively, cause the electronic device to perform operations, is provided. The at least one operation includes an operation of, based on a first current of a first sensing resistor disposed in a first housing of the electronic device, controlling first discharge power provided from a first battery disposed in the first housing to a first load disposed in the first housing. The at least one operation includes an operation of, based on a second current of a second sensing resistor disposed in a second housing of the electronic device, controlling second discharge power provided from a second battery disposed in the second housing to a second load disposed in the second housing. The at least one operation includes an operation of, based on a third current of a third sensing resistor disposed in a third housing of the electronic device, controlling third discharge power provided from a third battery disposed in the third housing to a third load disposed in the third housing. The electronic device includes a first charging circuit disposed in the first housing, and a flexible display disposed in the first housing, the second housing, and the third housing.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment, according to an embodiment of the disclosure;

FIG. 2 is a front view of a Z-type electronic device in an unfolded state, according to an embodiment of the disclosure;

FIG. 3 is a rear view of a Z-type electronic device in an unfolded state, according to an embodiment of the disclosure;

FIG. 4 is a perspective view of a Z-type electronic device in a folded state, according to an embodiment of the disclosure;

FIG. 5 is a front perspective view of a Z-type electronic device in a single-folded state, according to an embodiment of the disclosure;

FIG. 6 is a rear perspective view of a Z-type electronic device in a single-folded state, according to an embodiment of the disclosure;

FIG. 7 is a front view of a Z-type electronic device in a folded state, according to an embodiment of the disclosure;

FIG. 8 is a rear view of a Z-type electronic device in a folded state, according to an embodiment of the disclosure;

FIG. 9 is a right side view of a Z-type electronic device in a folded state, according to an embodiment of the disclosure;

FIG. 10 is a left side view of a Z-type electronic device in a folded state, according to an embodiment of the disclosure;

FIG. 11 is a circuit diagram showing a charging circuit, batteries, sensing resistors, and current control field effect transistors (FETs) of an electronic device, according to an embodiment of the disclosure;

FIG. 12 is a diagram showing a protection circuit, a battery, a sensing resistor, and current control FETs of an electronic device, according to an embodiment of the disclosure;

FIG. 13 is a block diagram illustrating a first charging circuit and a direct path disposed in the first housing of an electronic device, according to an embodiment of the disclosure;

FIG. 14 is a diagram illustrating a charging path and a discharging path of an electronic device, according to an embodiment of the disclosure;

FIG. 15 is a block diagram illustrating a second charging circuit and a direct path disposed in the first housing of an electronic device, according to an embodiment of the disclosure;

FIG. 16 is a diagram illustrating a charging path and a discharging path of an electronic device, according to an embodiment of the disclosure;

FIG. 17 is a block diagram illustrating a second charging circuit and a direct path disposed in the second housing of an electronic device, according to an embodiment of the disclosure;

FIG. 18 is a diagram illustrating a charging path and a discharging path of an electronic device, according to an embodiment of the disclosure;

FIG. 19 is a front perspective view of a G-type electronic device in an unfolded state, according to an embodiment of the disclosure;

FIG. 20 is a rear perspective view of a G-type electronic device in an unfolded state, according to an embodiment of the disclosure;

FIG. 21 is a perspective view of a G-type electronic device in a folded state, according to an embodiment of the disclosure;

FIG. 22 is a front perspective view of a G-type electronic device in a single-folded state, according to an embodiment of the disclosure;

FIG. 23 is a rear view of a G-type electronic device in a single-folded state, according to an embodiment of the disclosure;

FIG. 24 is a lower side view of a G-type electronic device in a folded state, according to an embodiment of the disclosure;

FIG. 25 is a left side view of a G-type electronic device in a folded state, according to an embodiment of the disclosure;

FIG. 26 is a right side view of a G-type electronic device in a folded state, according to an embodiment of the disclosure;

FIG. 27 is a block diagram illustrating a charging circuit, batteries, sensing resistors, and current control FETs of an electronic device, according to an embodiment of the disclosure;

FIG. 28 is a diagram illustrating a protection circuit, a battery, a sensing resistor, and current control FETs of an electronic device, according to an embodiment of the disclosure;

FIG. 29 is a block diagram illustrating a first charging circuit and a direct path disposed in the first housing of an electronic device, according to an embodiment of the disclosure;

FIG. 30 is a diagram illustrating a charging path and a discharging path of an electronic device, according to an embodiment of the disclosure;

FIG. 31 is a block diagram illustrating a second charging circuit and a direct path disposed in the first housing of an electronic device, according to an embodiment of the disclosure;

FIG. 32 is a diagram illustrating a charging path and a discharging path of an electronic device, according to an embodiment of the disclosure;

FIG. 33 is a block diagram illustrating a second charging circuit and a direct path disposed in the second housing of an electronic device, according to an embodiment of the disclosure;

FIG. 34 is a diagram illustrating a charging path and a discharging path of an electronic device, according to an embodiment of the disclosure;

FIG. 35 is a block diagram of an N-order foldable electronic device, according to an embodiment of the disclosure;

FIG. 36 is a flowchart of a method of operating an electronic device, according to an embodiment of the disclosure;

FIG. 37 is a flowchart of a method of operating an electronic device, according to an embodiment of the disclosure;

FIG. 38 is a flowchart of a method of operating an electronic device, according to an embodiment of the disclosure;

FIG. 39 is a flowchart of a method of operating an electronic device, according to an embodiment of the disclosure; and

FIG. 40 is a flowchart of a method of operating an electronic device, according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

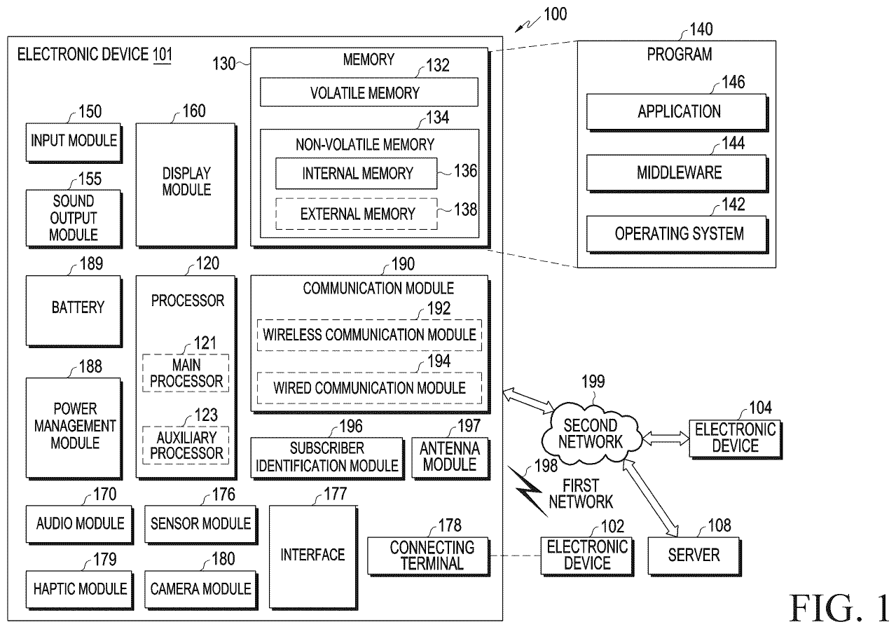

FIG. 1 is a block diagram illustrating an electronic device in a network environment according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include at least one of the volatile memory 132 or the non-volatile memory 134. The non-volatile memory 134 may include at least one of internal memory 136 or external memory 138.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth^{TM}, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

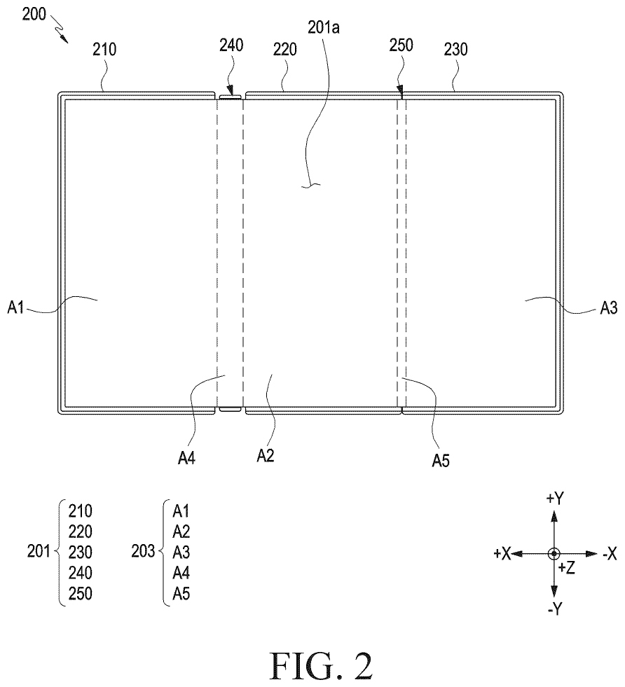

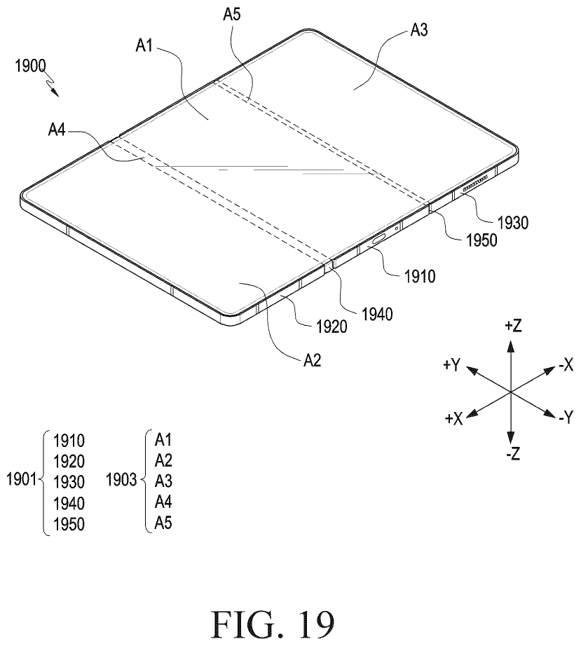

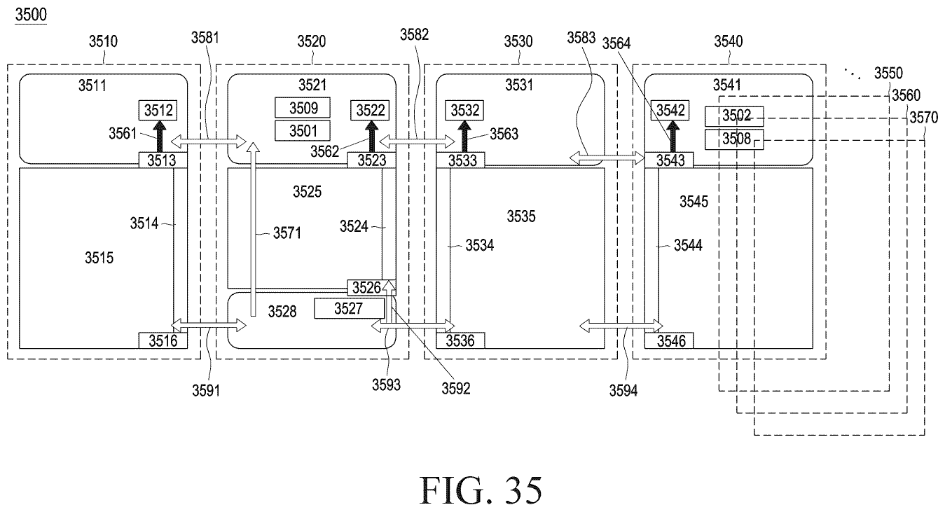

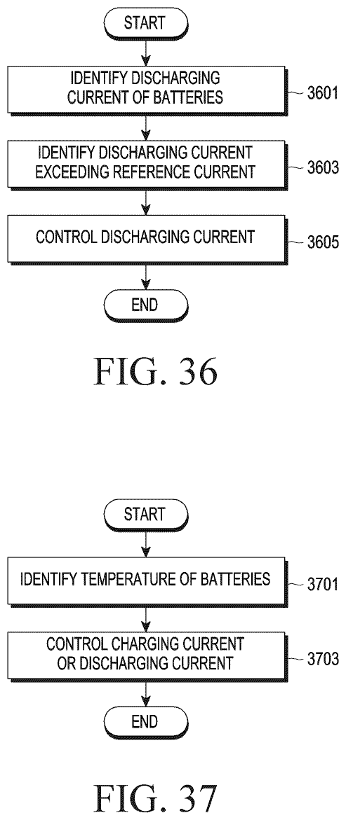

According to an embodiment, the electronic device 101 may be a multi-foldable device. A multi-foldable device may be a device having multiple housings rotatably connected by multiple hinges, respectively. The first embodiments of FIG. 2 to FIG. 18 may be Z-type embodiments among multi-foldable devices. The second embodiments of FIG. 19 to FIG. 34 may be G-type embodiments among multi-foldable devices. FIG. 35 may be an embodiment of an N-order foldable device. The embodiments of FIGS. 36 to 40 may be common embodiments applicable to the first embodiments of the Z-type, the second embodiments of the G-type, and the third embodiment of the N-order foldable device, respectively. The first embodiments, the second embodiments, and the third embodiment may differ only in the type of multi-foldable device but may include identical or similar components. Descriptions overlapping between the first embodiments and the second embodiments may be omitted. Portions omitted in the description of the first embodiments may be understood by referring to the description of the second embodiments. Portions omitted in the description of the second embodiments may be understood by referring to the description of the first embodiments. Those skilled in the art will understand that the first embodiments and the second embodiments may be interchangeably applied within the applicable scope.

According to an embodiment, the folding state of the electronic device 101 (200 in FIG. 2, or 1900 in FIG. 19) may include a state in which the electronic device 101 (200 in FIG. 2, or 1900 in FIG. 19) is unfolded (unfolded state), a folded state, or an intermediate state in which the same is partially unfolded or partially folded. The unfolded state may be a state in which the hinge is fully unfolded. The folded state may be a state in which the hinge is fully folded. The intermediate state may be a state in which the hinge forms an angle between a first angle at which the same is fully folded and a second angle at which the same is fully unfolded. The folding state of the electronic device 101 (200 in FIG. 2, or 1900 in FIG. 19) may include a single-folded state. The single-folded state may be a state in which, when the electronic device 101 (200 in FIG. 2, or 1900 in FIG. 19) includes multiple hinges, one hinge is fully folded, and the remaining hinge(s) are fully unfolded. The folded state of a hinge may be a state in which one hinge is folded. The folded state of the electronic device may be a state in which all hinges of the electronic device are folded. The unfolded state of a hinge may be a state in which one hinge is unfolded. The unfolded state of the electronic device may be a state in which all hinges of the electronic device are unfolded.

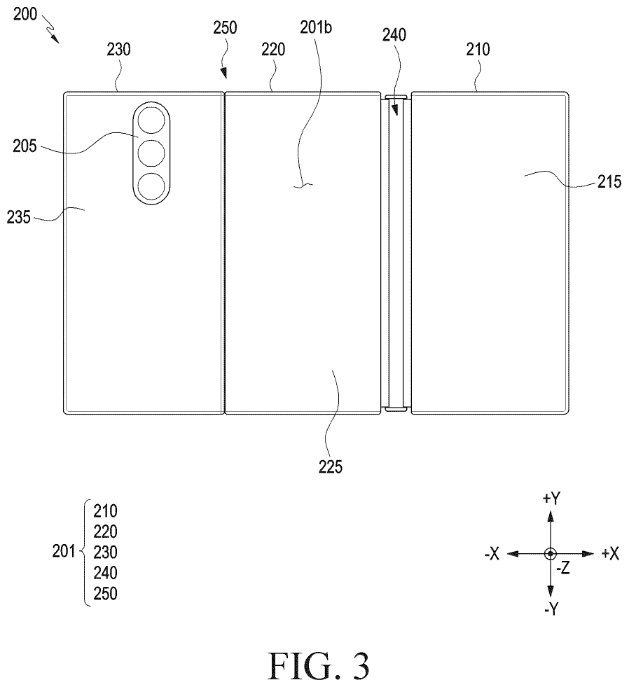

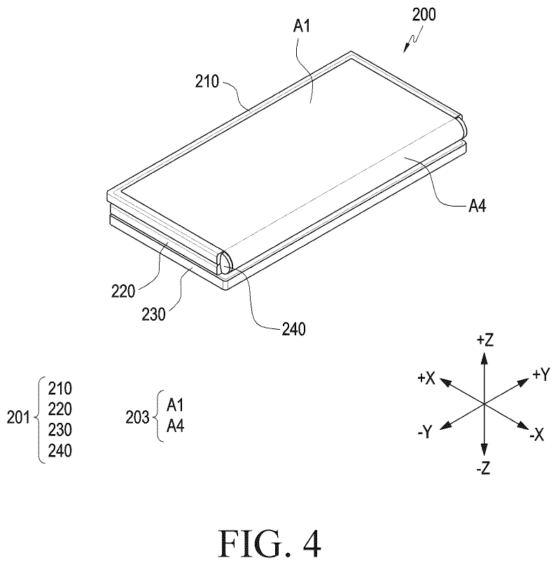

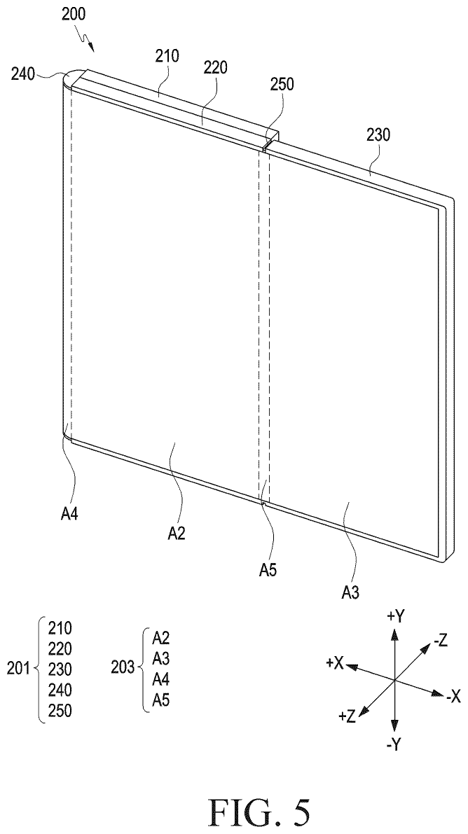

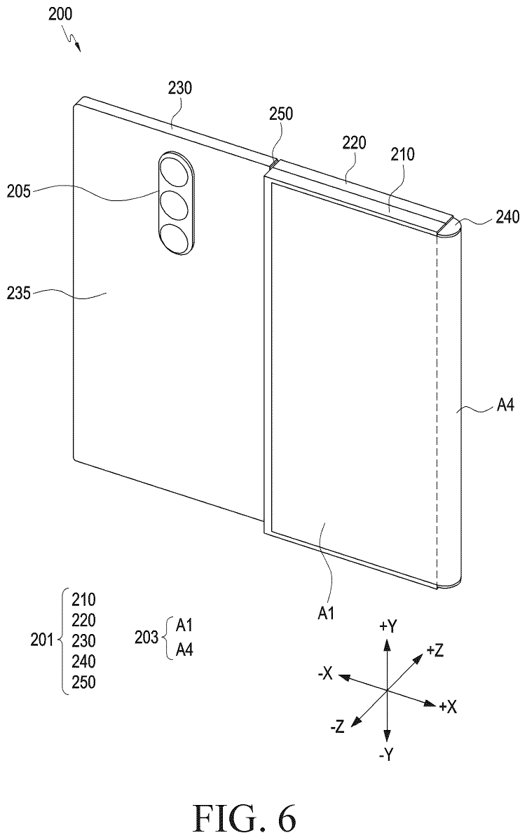

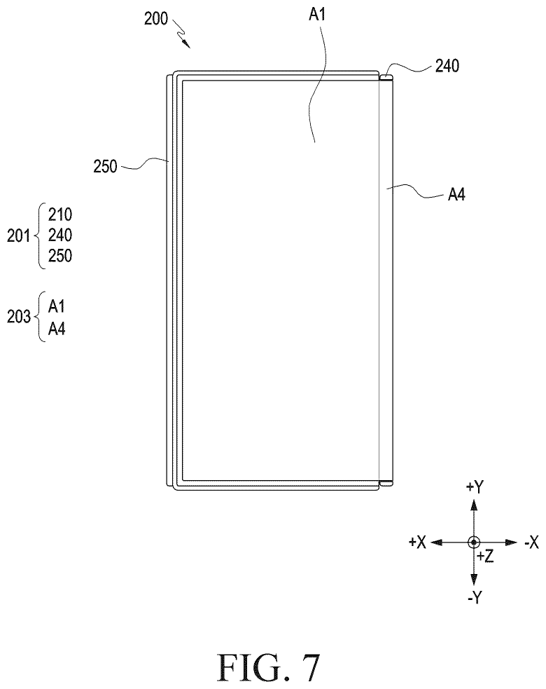

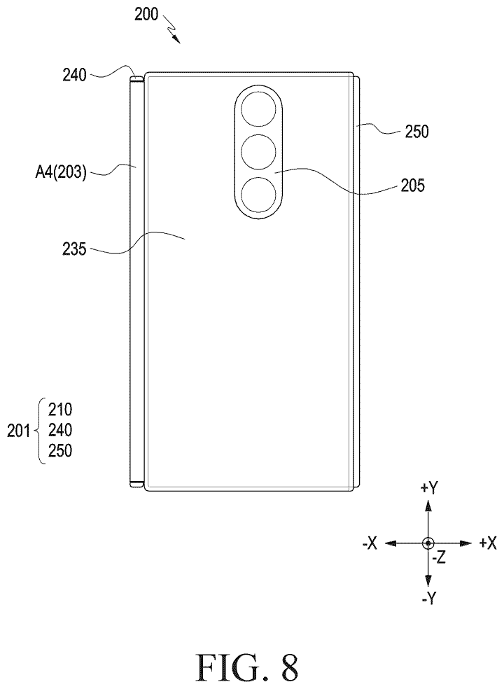

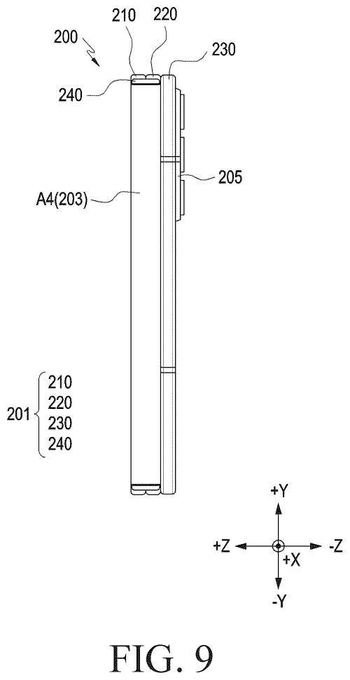

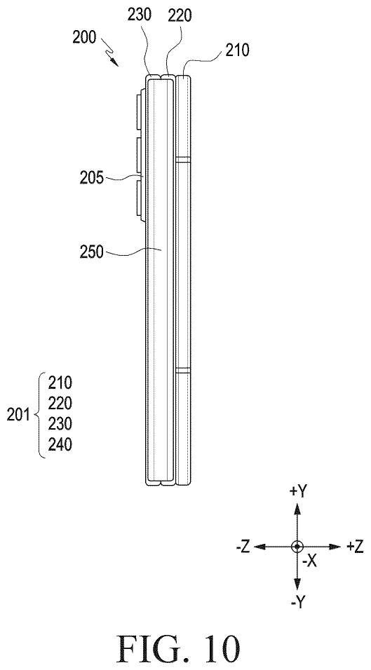

FIG. 2 is a front view of a Z-type electronic device in an unfolded state, according to an embodiment of the disclosure. FIG. 3 is a rear view of a Z-type electronic device in an unfolded state, according to an embodiment of the disclosure. FIG. 4 is a perspective view of a Z-type electronic device in a folded state, according to an embodiment of the disclosure. FIG. 5 is a front perspective view of a Z-type electronic device in a single-folded state, according to an embodiment of the disclosure. FIG. 6 is a rear perspective view of a Z-type electronic device in a single-folded state, according to an embodiment of the disclosure. FIG. 7 is a front view of a Z-type electronic device in a folded state, according to an embodiment of the disclosure. FIG. 8 is a rear view of a Z-type electronic device in a folded state, according to an embodiment of the disclosure. FIG. 9 is a right side view of a Z-type electronic device in a folded state, according to an embodiment of the disclosure. FIG. 10 is a left side view of a Z-type electronic device in a folded state, according to an embodiment of the disclosure.

Referring to FIGS. 2 to 10, the structure of a Z-type electronic device 200 may be described. The electronic device 200, as an example of the electronic device 101 shown in FIG. 1, may be a foldable (or bendable) device 200. The configuration of the electronic device 200 in FIGS. 2 to 18 may be partially or entirely identical to the configuration of the electronic device 101 in FIG. 1.

Hereinafter, for convenience of description, a spatial coordinate system (or Cartesian coordinate system) including an X-axis, a Y-axis, or a Z-axis may be illustrated in the drawings.

According to an embodiment, the electronic device 200 may include a housing 201 and a flexible or foldable display (hereinafter abbreviated to “flexible display 203”) (e.g., the display module 160 in FIG. 1) disposed in a space formed by the housing 201.

According to an embodiment, the housing 201 of the electronic device 200 may be defined and/or referred to as a foldable housing 201 or a deformable housing 201.

According to an embodiment, in an unfolded state of the electronic device 200 (e.g., FIG. 2), the surface on which the flexible display 203 is disposed (or the surface where the flexible display 203 is visible from the outside of the electronic device 200) may be defined as the front surface 201a of the electronic device 200. In an unfolded state of the electronic device 200 (e.g., FIG. 3), the surface opposite to the front surface 201a may be defined as the rear surface 201b of the electronic device 200. In addition, the surface surrounding the space between the front surface 201a and the rear surface 201b may be defined as the side surface of the electronic device 200.

According to an embodiment, the housing 201 may include a first housing 210, a second housing 220, a third housing 230, a first hinge 240, or a second hinge 250. The first hinge 240 may be defined and/or referred to as a first hinge assembly. The second hinge 250 may be defined and/or referred to as a second hinge assembly.

According to an embodiment, the first hinge 240 may be connected to the first housing 210 or the second housing 220. The second housing 220 may be rotatably connected to the first housing 210 by using the first hinge 240. According to an embodiment, the second hinge 250 may be connected to the second housing 220 or the third housing 230. The third housing 230 may be rotatably connected to the second housing 220 by using the second hinge 250.

According to an embodiment, the electronic device 200 may include a sensor region. The sensor region may be disposed on the housing 201. An illuminance sensor and an image sensor may be disposed in the sensor region. The illuminance sensor may detect the amount of light around the electronic device 200, and the image sensor may convert light incident through a camera lens into a digital signal. The illuminance sensor and the image sensor may be visually exposed to the flexible display 203. According to an embodiment, the illuminance sensor and the image sensor may not be visually exposed. For example, the camera may be configured as an under-display camera (UDC). Pixels in a region of the flexible display 203 corresponding to the position of the UDC may be configured differently from pixels in other regions such that the image sensor and/or camera may not be visually exposed.

According to an embodiment, the first housing 210 may be connected to the first hinge 240. The first housing 210 may include a first front surface facing in a first direction (e.g., the +Z direction in FIG. 2) and a first rear surface facing in a second direction (e.g., the −Z direction in FIG. 3) opposite to the first direction. The second housing 220 may be connected to the first hinge 240. The second housing 220 may include a second front surface facing the first direction (e.g., the +Z direction in FIG. 2) and a second rear surface facing in the second direction (e.g., the −Z direction in FIG. 3) opposite to the first direction.

According to an embodiment, the first housing 210 may rotate relative to the second housing 220 about the first hinge 240. The first housing 210 and the second housing 220 may be provided in a folded state (e.g., FIGS. 4, 5, and 6) or in an unfolded state (e.g., FIGS. 2 and 3). When the first housing 210 and the second housing 220 are in the folded state, the first rear surface of the first housing 210 may face the second rear surface of the second housing 220. When the first housing 210 and the second housing 220 are in the folded state, the first front surface of the first housing 210 may face in a direction opposite to the second front surface of the second housing 220. When the first housing 210 and the second housing 220 are in the unfolded state, the first front surface of the first housing 210 may face in the same direction as the second front surface of the second housing 220. When the first housing 210 and the second housing 220 are in the unfolded state, the first rear surface of the first housing 210 may face in the same direction as the second rear surface of the second housing 220.

According to an embodiment, the second housing 220 may be connected to the second hinge 250. The third housing 230 may be connected to the second hinge 250. The third housing 230 may include a third front surface facing in a first direction (e.g., the +Z direction in FIG. 2) and a third rear surface facing in a second direction (e.g., the −Z direction in FIG. 3) opposite to the first direction.

According to an embodiment, the second housing 220 may rotate relative to the third housing 230 about the second hinge 250. The second housing 220 and the third housing 230 may be provided in a folded state (e.g., FIG. 4) or in an unfolded state (e.g., FIGS. 2, 3, 5, and 6). When the second housing 220 and the third housing 230 are in the folded state, the second front surface of the second housing 220 may face the third front surface of the third housing 230. When the second housing 220 and the third housing 230 are in the folded state, the second rear surface of the second housing 220 may face in a direction opposite to the third rear surface of the third housing 230. When the second housing 220 and the third housing 230 are in the unfolded state, the second front surface of the second housing 220 may face in the same direction as the third front surface of the third housing 230. When the second housing 220 and the third housing 230 are in the unfolded state, the second rear surface of the second housing 220 may face in the same direction as the third rear surface of the third housing 230.

According to an embodiment, the fully folded state of the electronic device 200 may be defined as a state in which the first housing 210 and the second housing 220 are in a folded state, and the second housing 220 and the third housing 230 are simultaneously in a folded state. The fully unfolded state of the electronic device 200 may be defined as a state in which the first housing 210 and the second housing 220 are in an unfolded state, and the second housing 220 and the third housing 230 are simultaneously in an unfolded state.

According to an embodiment, when the first housing 210 and the second housing 220 are in a fully folded state, the first rear surface and the second rear surface may face each other. According to an embodiment, the first housing 210 and the second housing 220 may be disposed on both sides of the first hinge 240 and may have an overall symmetrical shape with respect to the first hinge 240. However, the first housing 210 and the second housing 220 do not necessarily have a symmetrical shape. Depending on whether the state of the first housing 210 and the second housing 220 is an unfolded status, a folded status, or an intermediate status (a partially unfolded or partially folded status), the angle or distance between the first housing 210 and the second housing 220 may vary.

According to an embodiment, when the second housing 220 and the third housing 230 are in a fully folded state, the second front surface and the third front surface may face each other. According to an embodiment, the second housing 220 and the third housing 230 may be disposed on both sides of the second hinge 250 and may have an overall symmetrical shape with respect to the second hinge 250. However, the second housing 220 and the third housing 230 do not necessarily have a symmetrical shape. Depending on whether the state of the second housing 220 and the third housing 230 is an unfolded status, a folded status, or an intermediate status (a partially unfolded or partially folded status), the angle or distance between the second housing 220 and the third housing 230 may vary.

According to an embodiment, as shown in FIG. 2, the first housing 210, the second housing 220, and the third housing 230 may collectively form a recess for accommodating the flexible display 203. According to an embodiment, at least a portion of the first housing 210, the second housing 220, and the third housing 230 may be formed of a metal material or a non-metal material having a degree of rigidity selected to support the flexible display 203. At least a portion formed of the metal material may provide a ground plane for the electronic device 200 and may be electrically connected to a ground line formed on a printed circuit board disposed within the foldable housing 201.

According to an embodiment, the first housing 210 may include a first rear cover 215. The first rear cover 215 may be disposed on one side of the first hinge 240 on the rear surface 201b of the electronic device 200 and may have, for example, a substantially rectangular edge. The edge of the first rear cover 215 may be surrounded by the side surfaces of the first housing 210.

According to an embodiment, the second housing 220 may include a second rear cover 225. The second rear cover 225 may be disposed on the other side of the first hinge 240 or on one side of the second hinge 250 on the rear surface 201b of the electronic device 200 and may have, for example, a substantially rectangular edge. The edge of the second rear cover 225 may be surrounded by the side surfaces of the second housing 220.

According to an embodiment, the third housing 230 may include a third rear cover 235. The third rear cover 235 may be disposed on the other side of the second hinge 250 on the rear surface 201b of the electronic device 200 and may have, for example, a substantially rectangular edge. The edge of the third rear cover 235 may be surrounded by the side surfaces of the third housing 230.

According to an embodiment, the first rear cover 215 and the second rear cover 225 may have a substantially symmetrical shape with respect to the first hinge 240. The second rear cover 225 and the third rear cover 235 may have a substantially symmetrical shape with respect to the second hinge 250. However, the first rear cover 215, the second rear cover 225, and the third rear cover 235 do not necessarily have a mutually symmetrical shape, and in an embodiment, the electronic device 200 may include a first rear cover 215, a second rear cover 225, and a third rear cover 235 of various shapes. In an embodiment, the first rear cover 215 may be formed integrally with the first housing 210. The second rear cover 225 may be formed integrally with the second housing 220. The third rear cover 235 may be formed integrally with the third housing 230.

According to an embodiment, the first rear cover 215, the second rear cover 225, the third rear cover 235, the first housing 210, the second housing 220, and the third housing 230 may form a space in which various components (e.g., a printed circuit board or a battery) of the electronic device 200 may be disposed. According to an embodiment, one or more components may be disposed or visually exposed on the rear surface 201b of the electronic device 200. One or more components or sensors (e.g., cameras 205) may be visually exposed through the third rear cover 235.

According to an embodiment, the flexible display 203 may be disposed in a space formed by the housing 201. For example, the flexible display 203 may be seated in a recess formed by the housing 201 and may be visible from the outside through the front surface 201a (e.g., the first front surface, the second front surface, and/or the third front surface) of the electronic device 200. According to an embodiment, the flexible display 203 may constitute most of the front surface 201a (e.g., the first front surface, the second front surface, and/or the third front surface) of the electronic device 200. Accordingly, the front surface 201a (e.g., the first front surface, the second front surface, and/or the third front surface) of the electronic device 200 may include the flexible display 203, a partial region of the first housing 210 adjacent to the flexible display 203, a partial region of the second housing 220 adjacent to the flexible display 203, and a partial region of the third housing 230 adjacent to the flexible display 203. The rear surface 201b (e.g., the first rear surface, the second rear surface, and/or the third rear surface) of the electronic device 200 may include the first rear cover 215, a partial region of the first housing 210 adjacent to the first rear cover 215, the second rear cover 225, a partial region of the second housing 220 adjacent to the second rear cover 225, the third rear cover 235, and a partial region of the third housing 230 adjacent to the third rear cover 235.

According to an embodiment, the flexible display 203 may refer to a display configured such that at least a partial region of the flexible display 203 may be deformed into a flat or curved surface. For example, the flexible display 203 may be configured to be at least partially folded or at least partially unfolded.

According to an embodiment, the flexible display 203 may include a first display region A1, a second display region A2, a third display region A3, a first folding region A4, or a second folding region A5. The first display region A1 may be disposed on one side of the first folding region A4, and the second display region A2 may be disposed on the other side of the first folding region A4. The second display region A2 may be disposed on one side of the second folding region A5, and the third display region A3 may be disposed on the other side of the second folding region A5.

According to an embodiment, the first display region A1 may be disposed on the first housing 210. The second display region A2 may be disposed on the second housing 220. The third display region A3 may be disposed on the third housing 230. According to an embodiment, the first folding region A4 may connect the first display region A1 and the second display region A2 and may be disposed on the first hinge 240. The second folding region A5 may connect the second display region A2 and the third display region A3 and may be disposed on the second hinge 250. The division of the regions of the flexible display 203 shown in FIG. 2 is exemplary, and the display may be divided into multiple (e.g., six or more, or three) regions depending on the structure or function.

According to an embodiment, the flexible display 203 may be combined with or disposed adjacent to a touch panel equipped with a touch sensing circuit and a pressure sensor capable of measuring the intensity (pressure) of a touch. For example, as an example of a touch panel, the flexible display 203 may be combined with or disposed adjacent to an electromagnetic induction panel for detecting a stylus pen of an electromagnetic resonance (EMR) type.

According to an embodiment, the first display region A1 and the second display region A2 may have an overall symmetrical shape with respect to the first folding region A4. The second display region A2 and the third display region A3 may have an overall symmetrical shape with respect to the second folding region A5.

According to an embodiment, when the electronic device 200 is in a fully folded state (e.g., FIG. 4), the first folding region A4 located on the first hinge 240 may be exposed to the outside of the electronic device 200, while the second folding region A5 located on the second hinge 250 may be disposed inside the electronic device 200 and not exposed to the outside. In an embodiment, the first hinge 240 may be defined and/or referred to as an out-folding hinge that exposes a portion of the flexible display 203 to the outside of the electronic device 200 in the folded state. The second hinge 250 may be defined and/or referred to as an in-folding hinge that does not expose a portion of the flexible display 203 to the exterior in the folded state. In an embodiment, the first hinge 240 may be provided as an in-folding hinge, and the second hinge 250 may be provided as an out-folding hinge.

Prior to describing each figure, the characteristics of a common electronic device 101 in FIG. 1, 200 in FIG. 2, 1900 in FIG. 19, or 3500 in FIG. 35 of an embodiment will be described.

According to an embodiment, the operation of the electronic device 101 in FIG. 1, 200 in FIG. 2, 1900 in FIG. 19, or 3500 in FIG. 35 may be controlled by the controller (e.g., 120 in FIG. 1) of the electronic device 101 in FIG. 1, 200 in FIG. 2, 1900 in FIG. 19, or 3500 in FIG. 35. The performance of a specific operation by the electronic device 101 in FIG. 1, 200 in FIG. 2, 1900 in FIG. 19, or 3500 in FIG. 35 may refer to the control of the electronic device 101 in FIG. 1, 200 in FIG. 2, 1900 in FIG. 19, or 3500 in FIG. 35, or a component included in the electronic device 101 in FIG. 1, 200 in FIG. 2, 1900 in FIG. 19, or 3500 in FIG. 35, by the controller (e.g., 120 in FIG. 1) of the electronic device 101 in FIG. 1, 200 in FIG. 2, 1900 in FIG. 19, or 3500 in FIG. 35. The electronic device 101 in FIG. 1, 200 in FIG. 2, 1900 in FIG. 19, or 3500 in FIG. 35 may include one or more controllers (e.g., one or more controllers including the processor 120 in FIG. 1), and for convenience of description, even in case that multiple controllers (e.g., one or more controllers including the processor 120 in FIG. 1) are implemented, “operations of the electronic device 101 in FIG. 1, 200 in FIG. 2, 1900 in FIG. 19, or 3500 in FIG. 35” will hereinafter be used interchangeably with “operations of the controller 120.”

According to an embodiment, the electronic device 101 in FIG. 1, 200 in FIG. 2, 1900 in FIG. 19, or 3500 in FIG. 35 may be a device (e.g., a laptop computer, a tablet, a portable communication device (e.g., a smartphone), a computer device, a portable multimedia device, a portable medical device, a camera, a wearable device, or a home appliance) that receives power from a power source. The power source may be a device (e.g., a wired charging device or a wireless charging device) that provides power (e.g., wired power or wireless power) to the electronic device 101 in FIG. 1, 200 in FIG. 2, 1900 in FIG. 19, or 3500 in FIG. 35. The power source may be a device (e.g., an adapter) that transfers external power to the electronic device 101 in FIG. 1, 200 in FIG. 2, 1900 in FIG. 19, or 3500 in FIG. 35. The power source is a device that provides power and is not limited by type. The electronic device 101 in FIG. 1, 200 in FIG. 2, 1900 in FIG. 19, or 3500 in FIG. 35 is a device that receives power and is not limited by type.

According to an embodiment, the electronic device 101 in FIG. 1, 200 in FIG. 2, 1900 in FIG. 19, or 3500 in FIG. 35 may include a power circuit. The electronic device 101 in FIG. 1, 200 in FIG. 2, 1900 in FIG. 19, or 3500 in FIG. 35 (e.g., controller 120) may receive power (e.g., wired power or wireless power) from a power source through the power circuit. For example, the power circuit may include a wired power circuit (e.g., a circuit including a wired connector) and/or a wireless power circuit (e.g., a circuit including a receiving coil and a rectifier).

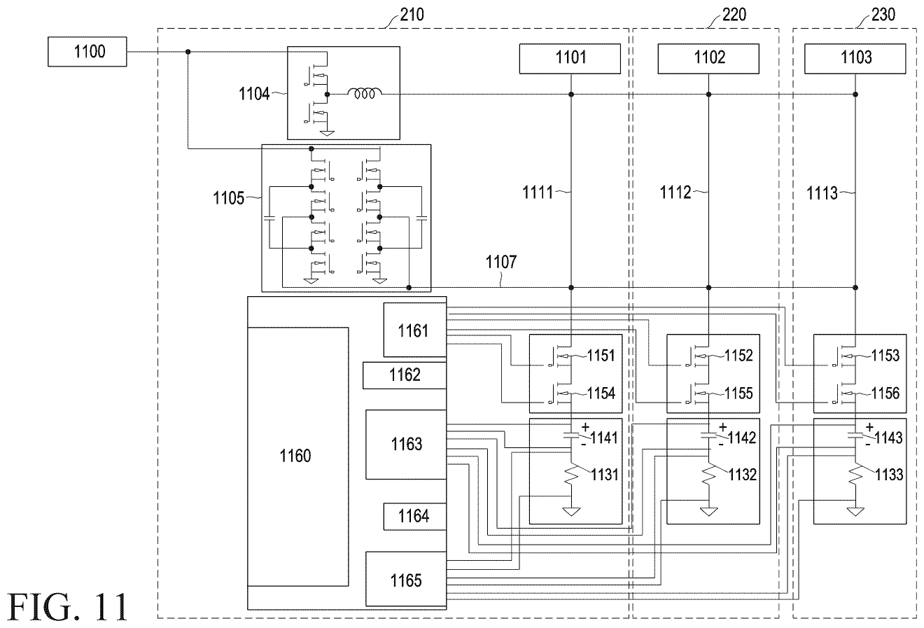

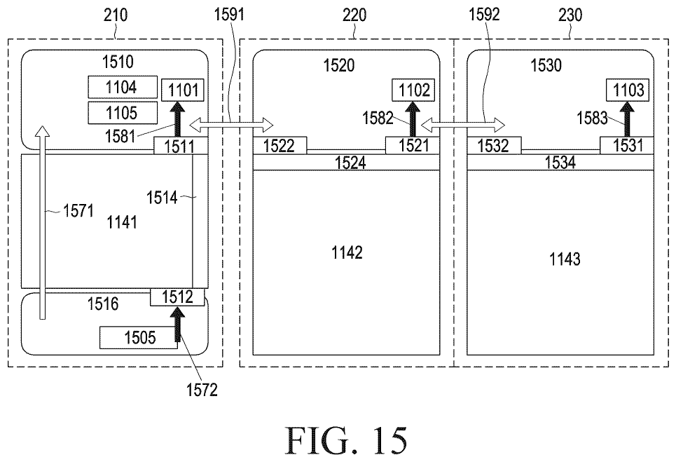

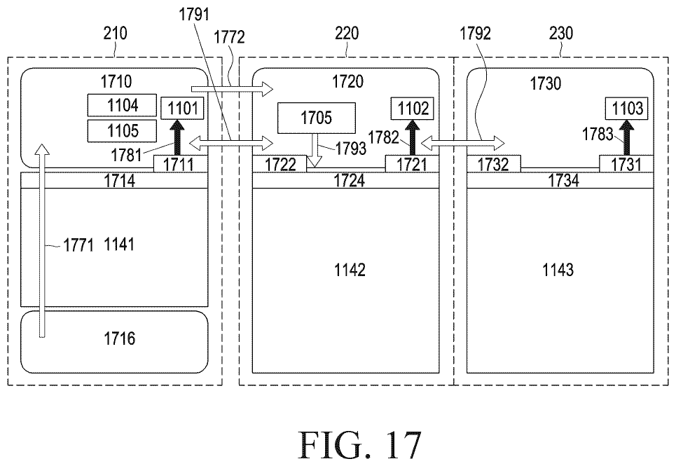

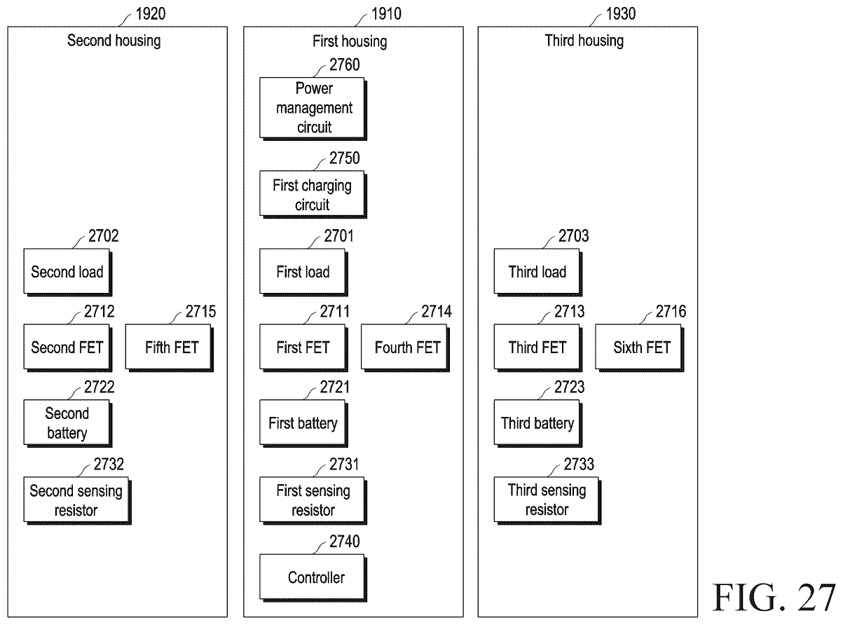

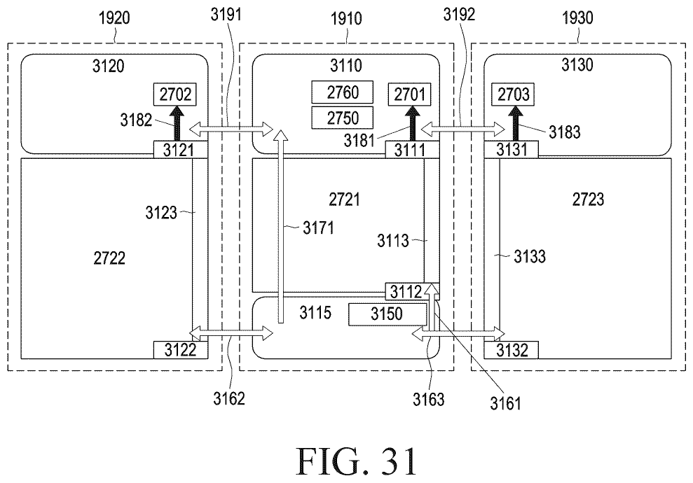

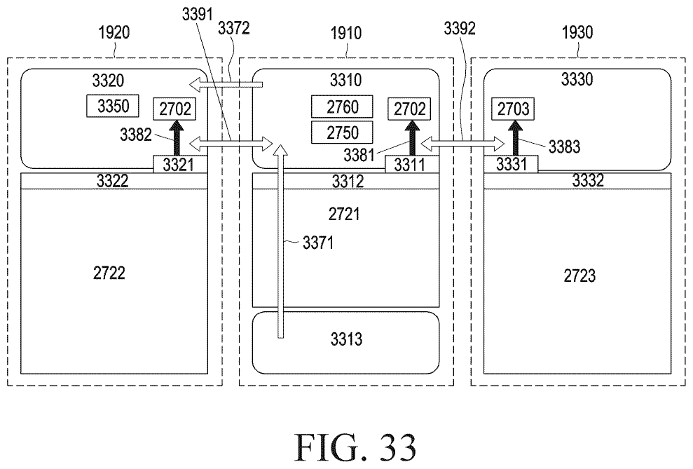

According to an embodiment, the electronic device 101 in FIG. 1, 200 in FIG. 2, 1900 in FIG. 19, or 3500 in FIG. 35 may include a charging circuit (e.g., 1105 in FIG. 11, 1505 in FIG. 15, 1705 in FIG. 17, 2750 in FIG. 27, 3150 in FIG. 31, 3350 in FIG. 33, 3501, 3502 in FIG. 35), a battery (e.g., 1141, 1142, 1143 in FIG. 11, 2721, 2722, 2723 in FIG. 27, or 3515, 3525, 3535, 3545 in FIG. 35), and a load (e.g., 1101, 1102, 1103 in FIG. 11, 2701, 2702, 2703 in FIG. 27, or 3512, 3522, 3532, 3542 in FIG. 35). For example, the output terminal of the charging circuit may be electrically connected to the battery. For example, the electronic device 101 in FIG. 1, 200 in FIG. 2, 1900 in FIG. 19, or 3500 in FIG. 35 (e.g., controller 120) may provide power to the charging circuit through the power circuit. The electronic device 101 in FIG. 1, 200 in FIG. 2, 1900 in FIG. 19, or 3500 in FIG. 35 (e.g., controller 120) may provide power to the battery through the charging circuit. The charging circuit may be a circuit that provides power to the battery, based on power provided from an external power source (e.g., a wired charging device or a wireless charging device). The charging circuit may receive power from the power circuit. The charging circuit may provide power to the battery, based on the power provided from the power circuit. The charging circuit may convert an input voltage into an output voltage. The output voltage of the charging circuit may be the input voltage (e.g., charging voltage) of the battery. The battery may be charged based on the output voltage (e.g., charging voltage) of the charging circuit. The battery may be electrically connected to the load. For example, the electronic device 101 in FIG. 1, 200 in FIG. 2, 1900 in FIG. 19, or 3500 in FIG. 35 (e.g., controller 120) may provide power from the battery to the load. The load may be a component of the electronic device 101 in FIG. 1, 200 in FIG. 2, 1900 in FIG. 19, or 3500 in FIG. 35 and may consume power. According to an embodiment, a converter may be disposed between the battery and the load. The converter may convert the power provided from the battery to be appropriate for the power required by the load. The converter may provide power to the load, based on the power provided to the converter.

According to an embodiment, the electronic device 101 in FIG. 1, 200 in FIG. 2, 1900 in FIG. 19, or 3500 in FIG. 35 may receive power from an external power source (e.g., a wired charging device or a wireless charging device) through a terminal (e.g., a universal serial bus (USB) terminal).

Charging may refer to the provision of power to the battery. A charging path may be the path of power (e.g., a charging current) provided to the battery. Discharging may refer to the provision of power from the battery. A discharging path may be the path of power (e.g., a discharging current) provided from the battery to the load.

In an electronic device according to a comparative example, power provided from a battery may not be transferred through a direct path (e.g., a path within a single housing) to a load within the same housing, but may be transferred through a bypass path (e.g., a path through multiple housings). In the electronic device according to the comparative example, power transfer through a bypass path (e.g., a path through multiple housings) may result in greater power consumption compared to power transfer through a direct path (e.g., a path within a single housing).

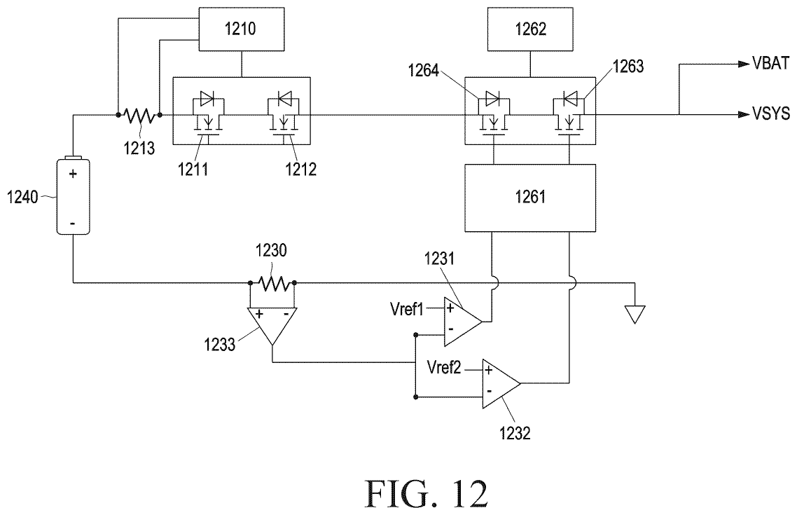

FIG. 11 is a circuit diagram showing a charging circuit, batteries, sensing resistors, and current control field effect transistors (FETs) of an electronic device according to an embodiment of the disclosure. FIG. 12 is a diagram showing a protection circuit, a battery, a sensing resistor, and current control FETs of an electronic device according to an embodiment of the disclosure.

Referring to FIGS. 11 and 12, an electronic device 200 according to various embodiments may be described.

The embodiment in FIG. 11 is an embodiment of a Z-type electronic device 200 but may also be applied to a G-type electronic device (e.g., 1900 in FIG. 19). For example, the embodiment in FIG. 27 (described later) may be described with reference to the embodiment in FIG. 11. This will be described later with reference to FIG. 27.

Referring to FIG. 11, according to an embodiment, the electronic device 200 may include a first housing 210 including a controller 1160 (e.g., a processor 120), an interface power management integrated circuit (IF-PMIC) 1104, a first charging circuit 1105, a first battery 1141, a first sensing resistor 1131, and a first load 1101. The electronic device 200 may include a second housing 220 including a second battery 1142, a second sensing resistor 1132, and a second load 1102. The electronic device 200 may include a third housing 230 including a third battery 1143, a third sensing resistor 1133, and a third load 1103. The electronic device 200 may include a first FET 1151 (e.g., a discharging FET) disposed in the first housing 210 and electrically connected to the first battery 1141. The discharging FET may be an FET that controls power (e.g., a discharging current) provided from the battery (e.g., 1141). The electronic device 200 may include a second FET 1152 (e.g., a discharging FET) disposed in the second housing 220 and electrically connected to the second battery 1142. The electronic device 200 may include a third FET 1153 (e.g., a discharging FET) disposed in the third housing 230 and electrically connected to the third battery 1143. The electronic device 200 may include a fourth FET 1154 (e.g., a charging FET) disposed in the first housing 210 and electrically connected to the first battery 1141. The charging FET may be an FET that controls power (e.g., a charging current) provided to the battery (e.g., 1141). The electronic device 200 may include a fifth FET 1155 (e.g., a charging FET) disposed in the second housing 220 and electrically connected to the second battery 1142. The electronic device 200 may include a sixth FET 1156 (e.g., a charging FET) disposed in the third housing 230 and electrically connected to the third battery 1143.

According to an embodiment, the electronic device 200 (e.g., controller 1160) may provide power to the first battery 1141, the second battery 1142, and/or the third battery 1143 through the first charging circuit 1105, based on power provided from an external power source 1100 (e.g., a wired charging device or a wireless charging device). The electronic device 200 may control the fourth FET 1154 to provide power (e.g., charging power) from the first charging circuit 1105 to the first battery 1141 through a charging path 1107. While power is provided from the first charging circuit 1105 to the first battery 1141, the electronic device 200 may control the first FET 1151 to operate as a bypass. The electronic device 200 may control the first FET 1151 to provide power (e.g., discharge power) from the first battery 1141 to the first load 1101 through a first path 1111 of the first housing 210. While power is provided from the first battery 1141 to the first load 1101, the electronic device 200 may control the fourth FET 1154 to operate as a bypass. The electronic device 200 may control the fifth FET 1155 to provide power (e.g., charging power) from the first charging circuit 1105 to the second battery 1142 through the charging path 1107. While power is provided from the first charging circuit 1105 to the second battery 1142, the electronic device 200 may control the second FET 1152 to operate as a bypass. The electronic device 200 may control the second FET 1152 to provide power (e.g., discharge power) from the second battery 1142 to the second load 1102 through a second path 1112 of the second housing 220. While power is provided from the second battery 1142 to the second load 1102, the electronic device 200 may control the fifth FET 1155 to operate as a bypass. The electronic device 200 may control the sixth FET 1156 to provide power (e.g., charging power) from the first charging circuit 1105 to the third battery 1143 through the charging path 1107. While power is provided from the first charging circuit 1105 to the third battery 1143, the electronic device 200 may control the third FET 1153 to operate as a bypass. The electronic device 200 may control the third FET 1153 to provide power (e.g., discharge power) from the third battery 1143 to the third load 1103 through a third path 1113 of the third housing 230. While power is provided from the third battery 1143 to the third load 1103, the electronic device 200 may control the sixth FET 1156 to operate as a bypass.

Referring to FIG. 11, according to an embodiment, the electronic device 200 may include a current control block 1161, a protection block 1162, a voltage sensing block 1163, a fuel gauge 1164, and/or a current sensing block 1165. The current control block 1161, the protection block 1162, the voltage sensing block 1163, the fuel gauge 1164, and/or the current sensing block 1165 may be disposed in the first housing 210. The current control block 1161 may control the driving voltage provided to the FETs (e.g., 1151, 1152, 1153, 1154, 1155, and/or 1156). The protection block 1162 may interrupt the current flowing through the FETs (e.g., 1151, 1152, 1153, 1154, 1155, and/or 1156). The voltage sensing block 1163 may sense the voltage of the battery (e.g., 1141, 1142, 1143). The fuel gauge 1164 may identify information (e.g., the state of charging, charging capacity, remaining capacity, lifespan, the number of times of charging/discharging, and battery resistance) of the battery (e.g., 1141, 1142, 1143). The current sensing block 1165 may sense the current flowing through the sensing resistors (e.g., 1131, 1132, 1133) (or the voltage corresponding to the current flowing through the sensing resistors (e.g., 1131, 1132, 1133)). The electronic device 200 (e.g., controller 1160) may control the first FET 1151, the second FET 1152, the third FET 1153, the fourth FET 1154, the fifth FET 1155, and/or the sixth FET 1156 by using the current control block 1161, the protection block 1162, the voltage sensing block 1163, the fuel gauge 1164, and/or the current sensing block 1165.

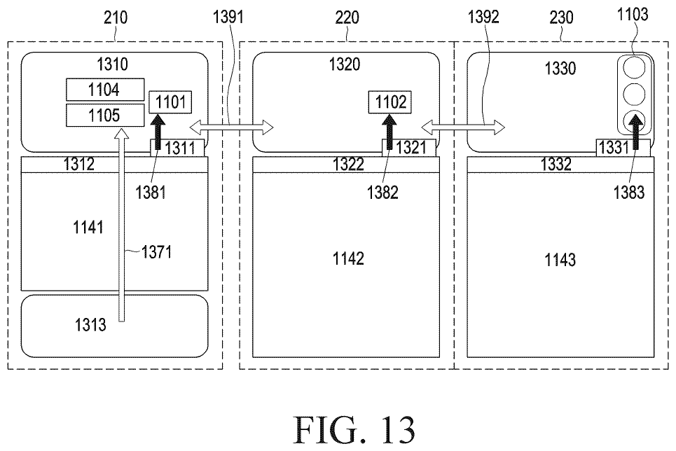

FIG. 12 is a diagram illustrating a protection circuit (e.g., 1312, 1322, 1332 in FIG. 13, 1514, 1524, 1534 in FIG. 15, or 1714, 1724, 1734 in FIG. 17). The current control block 1261 in FIG. 12 may be the current control block 1161 in FIG. 11. The protection block 1262 in FIG. 12 may be the protection block 1162 in FIG. 11. The discharging FET 1263 in FIG. 12 may correspond to the first FET 1151, the second FET 1152, or the third FET 1153 in FIG. 11. The charging FET 1264 in FIG. 12 may correspond to the fourth FET 1154, the fifth FET 1155, or the sixth FET 1156 in FIG. 11. The sensing resistor 1230 in FIG. 12 may correspond to the first sensing resistor 1131, the second sensing resistor 1132, or the third sensing resistor 1133 in FIG. 11. The battery 1240 in FIG. 12 may correspond to the first battery 1141, the second battery 1142, or the third battery 1143 in FIG. 11. In FIG. 12, VBAT may indicate that the circuit in FIG. 12 is electrically connected to a charging path (e.g., 1107) of a battery (e.g., 1240, 1141, 1142, 1143). In FIG. 12, VSYS may indicate that the circuit in FIG. 12 is electrically connected to a discharging path (e.g., 1111, 1112, 1113) to a load (e.g., 1101, 1102, 1103). The current sensing block (e.g., the block including 1231, 1232, and 1233) in FIG. 12 may be the current sensing block 1165 in FIG. 11. The electronic device 200 (e.g., controller 1160) may compare the current (or corresponding voltage) flowing through the sensing resistor 1230 with a reference current (or a corresponding reference voltage) by using the current sensing block (e.g., the block including 1231, 1232, and 1233). For example, the electronic device 200 may identify the current (e.g., sensing voltage) flowing through the sensing resistor 1230 (or voltage (e.g., sensing voltage) corresponding to the sensing current) by using the comparator 1233 to compare the voltage across both ends of the sensing resistor 1230. The current (e.g., sensing current) flowing through the sensing resistor 1230 may be a charging current (e.g., current flowing to the battery 1240) or a discharging current (e.g., current flowing from the battery 1240) depending on the direction. The electronic device 200 may compare the charging current (e.g., current flowing to the battery 1240) (or voltage corresponding to the charging current) with a reference current (or a reference voltage (e.g., first reference voltage Vref1) corresponding to the reference current) by using the first comparator 1231. The electronic device 200 may control the FET (e.g., charging FET 1264), based on the current (e.g., charging current) flowing through the sensing resistor 1230 being greater than the reference current (e.g., first reference current). The electronic device 200 may control the FET (e.g., charging FET 1264) to reduce the current (e.g., charging current) flowing through the sensing resistor 1230, based on the current (e.g., charging current) flowing through the sensing resistor 1230 being greater than the reference current (e.g., first reference current). The electronic device 200 may lower the gate voltage provided to the FET (e.g., charging FET 1264), based on the current (e.g., charging current) flowing through the sensing resistor 1230 being greater than the reference current (e.g., first reference current). While the charging current is provided to the battery 1240 through the charging FET 1264, the electronic device 200 may control the discharging FET 1263 to operate as a bypass. The electronic device 200 may compare the discharging current (e.g., current flowing from the battery 1240) (or voltage corresponding to the discharging current) with a reference current (or a reference voltage (e.g., second reference voltage Vref2) corresponding to the reference current) by using the second comparator 1232. The electronic device 200 may control the FET (e.g., discharging FET 1263), based on the current (e.g., discharging current) flowing through the sensing resistor 1230 being greater than the reference current (e.g., second reference current). The electronic device 200 may control the FET (e.g., discharging FET 1263) to reduce the current (e.g., discharging current) flowing through the sensing resistor 1230, based on the current (e.g., discharging current) flowing through the sensing resistor 1230 being greater than the reference current (e.g., second reference current). The electronic device 200 may lower the gate voltage provided to the FET (e.g., discharging FET 1263), based on the current (e.g., discharging current) flowing through the sensing resistor 1230 being greater than the reference current (e.g., second reference current). While the discharging current is provided from the battery 1240 through the discharging FET 1263, the electronic device 200 may control the charging FET 1264 to operate as a bypass.

According to an embodiment, the electronic device (e.g., 200 in FIG. 2, 1900 in FIG. 19) may use a protection circuit (e.g., a protection circuit module (PCM)) to block overcharging, over-discharging, and overcurrent of a battery, based on power provided to the battery or power provided from the battery. The protection circuit may include a base resistor and base field effect transistors (FETs) (e.g., charging FETs and discharging FETs). The electronic device (e.g., 200 in FIG. 2, 1900 in FIG. 19) may control the base FETs of the protection circuit to block power provided to the battery or power provided from the battery, based on the sensing value of the base resistor of the protection circuit.

Referring to FIG. 12, the protection circuit (e.g., 1312, 1322, 1332 in FIG. 13, 1514, 1524, 1534 in FIG. 15, or 1714, 1724, 1734 in FIG. 17) and the expansion of the protection circuit (e.g., 1312, 1322, 1332 in FIG. 13, 1514, 1524, 1534 in FIG. 15, or 1714, 1724, 1734 in FIG. 17) may be described.

According to an embodiment, the protection circuit (e.g., 1312, 1322, 1332 in FIG. 13, 1514, 1524, 1534 in FIG. 15, or 1714, 1724, 1734 in FIG. 17) may include a base resistor 1213 and base FETs 1211, 1212. The electronic device 200 (e.g., controller 1160) may control the base FETs 1211, 1212 by using the PCM block 1210, based on the sensing value (e.g., current value or voltage value) of the base resistor 1213. The PCM block 1210 may control the base FETs 1211, 1212 to block power provided to the battery 1240 or power provided from the battery 1240. The electronic device 200 may block overcharging, over-discharging, and overcurrent of the battery 1240 by using the PCM block 1210, based on the sensing value (e.g., current value or voltage value) of the base resistor 1213.

According to an embodiment, the protection circuit (e.g., 1312, 1322, 1332 in FIG. 13, 1514, 1524, 1534 in FIG. 15, or 1714, 1724, 1734 in FIG. 17) may include a base resistor 1213, base FETs 1211, 1212, a discharging FET 1263, a charging FET 1264, and a sensing resistor 1230. The electronic device 200 (e.g., controller 1160) may control the base FETs 1211, 1212 of the protection circuit (e.g., 1312, 1322, 1332 in FIG. 13, 1514, 1524, 1534 in FIG. 15, or 1714, 1724, 1734 in FIG. 17) to block power provided to the battery 1240 or power provided from the battery 1240. The electronic device 200 (e.g., controller 1160) may also control the discharging FET 1263 or the charging FET 1264 of the protection circuit (e.g., 1312, 1322, 1332 in FIG. 13, 1514, 1524, 1534 in FIG. 15, or 1714, 1724, 1734 in FIG. 17) to block power provided to the battery 1240 or power provided from the battery 1240. The electronic device 200 (e.g., controller 1160) may control the discharging FET 1263 or the charging FET 1264 of the protection circuit (e.g., 1312, 1322, 1332 in FIG. 13, 1514, 1524, 1534 in FIG. 15, or 1714, 1724, 1734 in FIG. 17) to control (e.g., increase or decrease) the current (e.g., charging current) provided to the battery 1240 or the current (e.g., discharging current) provided from the battery 1240.

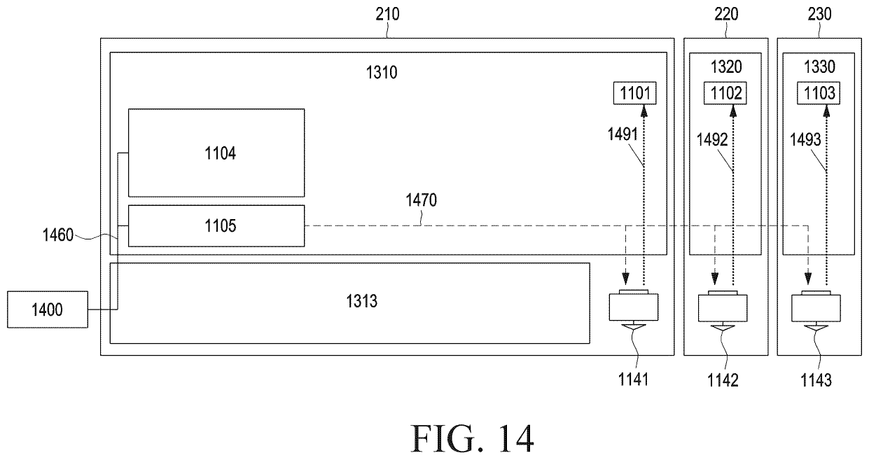

FIG. 13 is a block diagram illustrating a first charging circuit and a direct path disposed in the first housing of an electronic device, according to an embodiment of the disclosure. FIG. 14 is a diagram illustrating a charging path and a discharging path of an electronic device, according to an embodiment of the disclosure. FIGS. 13 and 14 may be described with reference to the previously described embodiments.

The electronic device shown in FIGS. 13 and 14 may be the Z-type electronic device 200 in FIGS. 2 to 6.

Referring to FIGS. 13 and 14, a direct path (e.g., 1381, 1382, 1383) of the electronic device 200 according to an embodiment may be described. The direct path (e.g., 1381, 1382, 1383) is a path through which power is provided from a battery (e.g., 1141, 1142, 1143) to a load (e.g., 1101, 1102, 1103), and may be a path disposed in the same housing (e.g., 210, 220, 230) as the housing (e.g., 210, 220, 230) where the battery (e.g., 1141, 1142, 1143) and the load (e.g., 1101, 1102, 1103) are disposed.

Referring to FIGS. 13 and 14, according to various embodiments, the electronic device 200 may include a first housing 210 including an IF-PMIC 1104, a first charging circuit 1105, a first battery 1141, a first protection circuit 1312, and a first load 1101. The IF-PMIC 1104, the first charging circuit 1105, and the first load 1101 may be disposed on the first substrate 1310 of the first housing 210. The electronic device 200 may include a second housing 220 including a second battery 1142, a second protection circuit 1322, and a second load 1102. The second load 1102 may be disposed on the second substrate 1320 of the second housing 220. The electronic device 200 may include a third housing 230 including a third battery 1143, a third protection circuit 1332, and a third load 1103. The third load 1103 may be disposed on the third substrate 1330 of the third housing 230.

Referring to FIGS. 13 and 12, according to various embodiments, the first protection circuit 1312 may include a base resistor (e.g., 1213 in FIG. 12) and base FETs (e.g., a charging FET (e.g., 1211 in FIG. 12)). The second protection circuit 1322 may include a base resistor (e.g., 1213 in FIG. 12) and base FETs (e.g., a charging FET (e.g., 1211 in FIG. 12)). The third protection circuit 1332 may include a base resistor (e.g., 1213 in FIG. 12) and base FETs (e.g., a charging FET (e.g., 1211 in FIG. 12)). The electronic device 200 (e.g., controller 1160) may use the protection circuit (e.g., 1312, 1322, 1332) to block overcharging, over-discharging, and overcurrent of the battery (e.g., 1141, 1142, 1143), based on power provided to the battery (e.g., 1141, 1142, 1143) or power provided from the battery (e.g., 1141, 1142, 1143). The electronic device 200 may control the base FETs (e.g., a charging FET (e.g., 1211 in FIG. 12) and a discharging FET (e.g., 1212 in FIG. 12)) of the protection circuit (e.g., 1312, 1322, 1332) to block power provided to the battery (e.g., 1141, 1142, 1143) or power provided from the battery (e.g., 1141, 1142, 1143), based on the sensing value of the base resistor (e.g., 1213 in FIG. 12) of the protection circuit (e.g., 1312, 1322, 1332).

Referring to FIGS. 13, 11, and 12, according to various embodiments of the disclosure, the first protection circuit 1312 may include a first sensing resistor 1131 (e.g., 1230 in FIG. 12). The second protection circuit 1322 may include a second sensing resistor 1132 (e.g., 1230 in FIG. 12). The third protection circuit 1332 may include a third sensing resistor 1133 (e.g., 1230 in FIG. 12). The first protection circuit 1312 may include a first FET 1151 (e.g., the discharging FET 1263 in FIG. 12) electrically connected to the first battery 1141. The second protection circuit 1322 may include a second FET 1152 (e.g., the discharging FET 1263 in FIG. 12) electrically connected to the second battery 1142. The third protection circuit 1332 may include a third FET 1153 (e.g., the discharging FET 1263 in FIG. 12) electrically connected to the third battery 1143. The first protection circuit 1312 may include a fourth FET 1154 (e.g., the charging FET 1264 in FIG. 12) electrically connected to the first battery 1141. The second protection circuit 1322 may include a fifth FET 1155 (e.g., the charging FET 1264 in FIG. 12) electrically connected to the second battery 1142. The third protection circuit 1332 may include a sixth FET 1156 (e.g., the charging FET 1264 in FIG. 12) electrically connected to the third battery 1143.

Referring to FIGS. 13 and 14, according to various embodiments of the disclosure, the electronic device 200 may receive power from an external power source 1400 (e.g., 1100 in FIG. 11) (e.g., a wired charging device or a wireless charging device). For example, the electronic device 200 may receive power from an external power source 1400 (e.g., 1100 in FIG. 11) through a terminal (e.g., a USB terminal). The electronic device 200 may include an FPCB 1371 that electrically connects the terminal (e.g., a USB terminal disposed on the USB substrate 1313) of the first housing 210 with the IF-PMIC 1104 and/or the first charging circuit 1105 of the first substrate 1310. The FPCB 1371 may be part of a power reception path 1460. The electronic device 200 may provide charging power to the first battery 1141, the second battery 1142, and/or the third battery 1143 through the first charging circuit 1105, based on power provided from the external power source 1400.

Referring to FIGS. 11, 12, 13, and 14, according to various embodiments of the disclosure, the electronic device 200 may include a first connector 1311 (e.g., a battery connector) that electrically connects the components disposed on the first substrate 1310 of the first housing 210 with the first battery 1141. The first connector 1311 may be electrically connected to the first protection circuit 1312. Power provided from the first charging circuit 1105 may be provided to the first battery 1141 through the first connector 1311 and the first protection circuit 1312. Power provided from the first charging circuit 1105 may be provided to the first battery 1141 through the first FET 1151 and the fourth FET 1154 of the first protection circuit 1312. The electronic device 200 (e.g., controller 1160) may control the fourth FET 1154 to provide power (e.g., charging power) from the first charging circuit 1105 to the first battery 1141 through a charging path 1470. While power is provided from the first charging circuit 1105 to the first battery 1141, the electronic device 200 may control the fourth FET 1154 (e.g., the charging FET 1264 in FIG. 12), based on the sensing value (e.g., current value or voltage value) of the first sensing resistor 1131 (e.g., 1230 in FIG. 12) of the first protection circuit 1312. The electronic device 200 may control the gate voltage provided to the fourth FET 1154 (e.g., the charging FET 1264 in FIG. 12), based on the sensing value (e.g., current value or voltage value) of the first sensing resistor 1131 (e.g., 1230 in FIG. 12). For example, while power is provided from the first charging circuit 1105 to the first battery 1141, the electronic device 200 may lower the gate voltage provided to the fourth FET 1154 (e.g., the charging FET 1264 in FIG. 12), based on the current (e.g., charging current) of the first sensing resistor 1131 (e.g., 1230 in FIG. 12) being greater than a reference current. While power is provided from the first charging circuit 1105 to the first battery 1141, the electronic device 200 may control the first FET 1151 to operate as a bypass.

Referring to FIGS. 11, 12, 13, and 14, according to various embodiments of the disclosure, the electronic device 200 may include a second connector 1321 (e.g., a battery connector) that electrically connects the components disposed on the second substrate 1320 of the second housing 220 with the second battery 1142. The second connector 1321 may be electrically connected to the second protection circuit 1322. The electronic device 200 may include a first FPCB 1391 that electrically connects the components of the first substrate 1310 of the first housing 210 with the components of the second substrate 1320 of the second housing 220. The first FPCB 1391 may be part of a charging path 1470. Power provided from the first charging circuit 1105 of the first housing 210 may be provided to the second battery 1142 through the first FPCB 1391, the second connector 1321, and the second protection circuit 1322. Power provided from the first charging circuit 1105 may be provided to the second battery 1142 through the second FET 1152 and the fifth FET 1155 of the second protection circuit 1322. The electronic device 200 (e.g., controller 1160) may control the fifth FET 1155 to provide power (e.g., charging power) from the first charging circuit 1105 to the second battery 1142 through the charging path 1470. While power is provided from the first charging circuit 1105 to the second battery 1142, the electronic device 200 may control the fifth FET 1155 (e.g., the charging FET 1264 in FIG. 12), based on the sensing value (e.g., current value or voltage value) of the second sensing resistor 1132 (e.g., 1230 in FIG. 12) of the second protection circuit 1322. The electronic device 200 may control the gate voltage provided to the fifth FET 1155 (e.g., the charging FET 1264 in FIG. 12), based on the sensing value (e.g., current value or voltage value) of the second sensing resistor 1132 (e.g., 1230 in FIG. 12). For example, while power is provided from the first charging circuit 1105 to the second battery 1142, the electronic device 200 may lower the gate voltage provided to the fifth FET 1155 (e.g., the charging FET 1264 in FIG. 12), based on the current (e.g., charging current) of the second sensing resistor 1132 (e.g., 1230 in FIG. 12) being greater than a reference current. While power is provided from the first charging circuit 1105 to the second battery 1142, the electronic device 200 may control the second FET 1152 to operate as a bypass.

Referring to FIGS. 11, 12, 13, and 14, according to various embodiments of the disclosure, the electronic device 200 may include a third connector 1331 (e.g., a battery connector) that electrically connects the components disposed on the third substrate 1330 of the third housing 230 with the third battery 1143. The third connector 1331 may be electrically connected to the third protection circuit 1332. The electronic device 200 may include a second FPCB 1392 that electrically connects the components of the second substrate 1320 of the second housing 220 with the components of the third substrate 1330 of the third housing 230. The second FPCB 1392 may be part of a charging path 1470. Power provided from the first charging circuit 1105 of the first housing 210 may be provided to the third battery 1143 through the first FPCB 1391, the second FPCB 1392, the third connector 1331, and the third protection circuit 1332. Power provided from the first charging circuit 1105 may be provided to the third battery 1143 through the third FET 1153 and the sixth FET 1156 of the third protection circuit 1332. The electronic device 200 (e.g., controller 1160) may control the sixth FET 1156 to provide power (e.g., charging power) from the first charging circuit 1105 to the third battery 1143 through the charging path 1470. While power is provided from the first charging circuit 1105 to the third battery 1143, the electronic device 200 may control the sixth FET 1156 (e.g., the charging FET 1264 in FIG. 12), based on the sensing value (e.g., current value or voltage value) of the third sensing resistor 1133 (e.g., 1230 in FIG. 12) of the third protection circuit 1332. The electronic device 200 may control the gate voltage provided to the sixth FET 1156 (e.g., the charging FET 1264 in FIG. 12), based on the sensing value (e.g., current value or voltage value) of the third sensing resistor 1133 (e.g., 1230 in FIG. 12). For example, while power is provided from the first charging circuit 1105 to the third battery 1143, the electronic device 200 may lower the gate voltage provided to the sixth FET 1156 (e.g., the charging FET 1264 in FIG. 12), based on the current (e.g., charging current) of the third sensing resistor 1133 (e.g., 1230 in FIG. 12) being greater than a reference current. While power is provided from the first charging circuit 1105 to the third battery 1143, the electronic device 200 may control the third FET 1153 to operate as a bypass.

Referring to FIGS. 11, 12, 13, and 14, according to various embodiments of the disclosure, the electronic device 200 may include a first wire 1381 that electrically connects the first load 1101 and the first connector 1311 of the first housing 210. The first wire 1381 may be disposed in the first housing 210. The first wire 1381 may be part of a first discharging path 1491. Power provided from the first battery 1141 may be provided to the first load 1101 through the first protection circuit 1312, the first connector 1311, and the first wire 1381. Power provided from the first battery 1141 may be provided to the first load 1101 through the first FET 1151 and the fourth FET 1154. The electronic device 200 (e.g., controller 1160) may control the first FET 1151 (e.g., the discharging FET 1263 in FIG. 12) to provide power (e.g., discharge power) from the first battery 1141 to the first load 1101 through the first discharging path 1491. While power is provided from the first battery 1141 to the first load 1101, the electronic device 200 may control the first FET 1151 (e.g., the discharging FET 1263 in FIG. 12), based on the sensing value (e.g., current value or voltage value) of the first sensing resistor 1131 (e.g., 1230 in FIG. 12) of the first protection circuit 1312. The electronic device 200 may control the gate voltage provided to the first FET 1151 (e.g., the discharging FET 1263 in FIG. 12), based on the sensing value (e.g., current value or voltage value) of the first sensing resistor 1131 (e.g., 1230 in FIG. 12). For example, while power is provided from the first battery 1141 to the first load 1101, the electronic device 200 may lower the gate voltage provided to the first FET 1151 (e.g., the discharging FET 1263 in FIG. 12), based on the current (e.g., discharging current) of the first sensing resistor 1131 (e.g., 1230 in FIG. 12) being greater than a reference current. While power is provided from the first battery 1141 to the first load 1101, the electronic device 200 may control the fourth FET 1154 to operate as a bypass.

Referring to FIGS. 11, 12, 13, and 14, according to various embodiments of the disclosure, the electronic device 200 may include a second wire 1382 that electrically connects the second load 1102 and the second connector 1321 of the second housing 220. The second wire 1382 may be disposed in the second housing 220. The second wire 1382 may be part of a second discharging path 1492. Power provided from the second battery 1142 may be provided to the second load 1102 through the second protection circuit 1322, the second connector 1321, and the second wire 1382. Power provided from the second battery 1142 may be provided to the second load 1102 through the second FET 1152 and the fifth FET 1155. The electronic device 200 (e.g., controller 1160) may control the second FET 1152 (e.g., the discharging FET 1263 in FIG. 12) to provide power (e.g., discharge power) from the second battery 1142 to the second load 1102 through the second discharging path 1492. While power is provided from the second battery 1142 to the second load 1102, the electronic device 200 may control the second FET 1152 (e.g., the discharging FET 1263 in FIG. 12), based on the sensing value (e.g., current value or voltage value) of the second sensing resistor 1132 (e.g., 1230 in FIG. 12) of the second protection circuit 1322. The electronic device 200 may control the gate voltage provided to the second FET 1152 (e.g., the discharging FET 1263 in FIG. 12), based on the sensing value (e.g., current value or voltage value) of the second sensing resistor 1132 (e.g., 1230 in FIG. 12). For example, while power is provided from the second battery 1142 to the second load 1102, the electronic device 200 may lower the gate voltage provided to the second FET 1152 (e.g., the discharging FET 1263 in FIG. 12), based on the current (e.g., discharging current) of the second sensing resistor 1132 (e.g., 1230 in FIG. 12) being greater than a reference current. While power is provided from the second battery 1142 to the second load 1102, the electronic device 200 may control the fifth FET 1155 to operate as a bypass.

Referring to FIGS. 11, 12, 13, and 14, according to various embodiments of the disclosure, the electronic device 200 may include a third wire 1383 that electrically connects the third load 1103 and the third connector 1331 of the third housing 230. The third wire 1383 may be disposed in the third housing 230. The third wire 1383 may be part of a third discharging path 1493. Power provided from the third battery 1143 may be provided to the third load 1103 through the third protection circuit 1332, the third connector 1331, and the third wire 1383. Power provided from the third battery 1143 may be provided to the third load 1103 through the third FET 1153 and the sixth FET 1156. The electronic device 200 (e.g., controller 1160) may control the third FET 1153 (e.g., the discharging FET 1263 in FIG. 12) to provide power (e.g., discharge power) from the third battery 1143 to the third load 1103 through the third discharging path 1493. While power is provided from the third battery 1143 to the third load 1103, the electronic device 200 may control the third FET 1153 (e.g., the discharging FET 1263 in FIG. 12), based on the sensing value (e.g., current value or voltage value) of the third sensing resistor 1133 (e.g., 1230 in FIG. 12) of the third protection circuit 1332. The electronic device 200 may control the gate voltage provided to the third FET 1153 (e.g., the discharging FET 1263 in FIG. 12), based on the sensing value (e.g., current value or voltage value) of the third sensing resistor 1133 (e.g., 1230 in FIG. 12). For example, while power is provided from the third battery 1143 to the third load 1103, the electronic device 200 may lower the gate voltage provided to the third FET 1153 (e.g., the discharging FET 1263 in FIG. 12), based on the current (e.g., discharging current) of the third sensing resistor 1133 (e.g., 1230 in FIG. 12) being greater than a reference current. While power is provided from the third battery 1143 to the third load 1103, the electronic device 200 may control the sixth FET 1156 to operate as a bypass.

FIG. 15 is a block diagram illustrating a second charging circuit and a direct path disposed in the first housing of an electronic device, according to an embodiment of the disclosure.

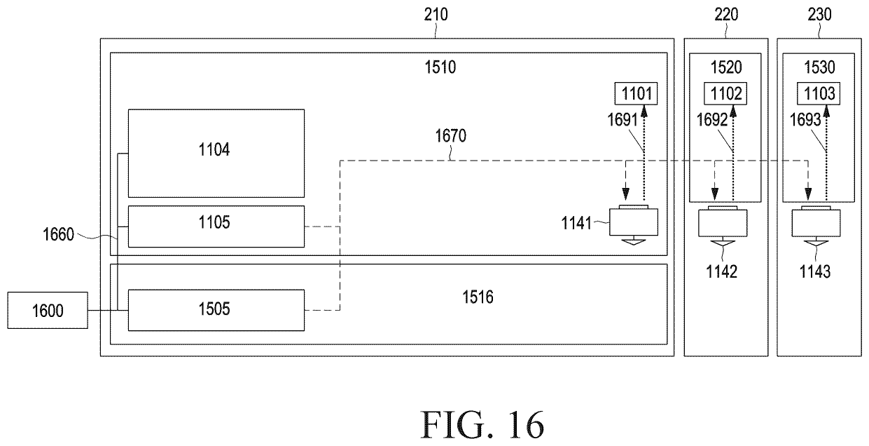

FIG. 16 is a diagram illustrating a charging path and a discharging path of an electronic device, according to an embodiment of the disclosure.

FIGS. 15 and 16 may be described with reference to the previously described embodiments.

The electronic device shown in FIGS. 15 and 16 may be the Z-type electronic device 200 in FIGS. 2 to 6.

Referring to FIGS. 15 and 16, a direct path (e.g., 1572, 1581, 1582, 1583) of the electronic device 200 according to various embodiments may be described.

Referring to FIGS. 15 and 16, according to various embodiments of the disclosure, the electronic device 200 may include a first housing 210 including an IF-PMIC 1104, a first charging circuit 1105, a second charging circuit 1505, a first battery 1141, a first protection circuit 1514, and a first load 1101. The IF-PMIC 1104, the first charging circuit 1105, and the first load 1101 may be disposed on the first substrate 1510 of the first housing 210. The electronic device 200 may include a second housing 220 including a second battery 1142, a second protection circuit 1524, and a second load 1102. The second load 1102 may be disposed on the second substrate 1520 of the second housing 220. The electronic device 200 may include a third housing 230 including a third battery 1143, a third protection circuit 1534, and a third load 1103. The third load 1103 may be disposed on the third substrate 1530 of the third housing 230. The second charging circuit 1505 may be disposed on the fourth substrate 1516 (e.g., USB substrate) of the first housing 210.

Referring to FIGS. 15 and 12, according to an embodiments of the disclosure, the first protection circuit 1514 may include a base resistor (e.g., 1213 in FIG. 12) and base FETs (e.g., a charging FET (e.g., 1211 in FIG. 12)). The second protection circuit 1524 may include a base resistor (e.g., 1213 in FIG. 12) and base FETs (e.g., a charging FET (e.g., 1211 in FIG. 12)). The third protection circuit 1534 may include a base resistor (e.g., 1213 in FIG. 12) and base FETs (e.g., a charging FET (e.g., 1211 in FIG. 12)). The electronic device 200 (e.g., controller 1160) may use the protection circuit (e.g., 1514, 1524, 1534) to block overcharging, over-discharging, and overcurrent of the battery (e.g., 1141, 1142, 1143), based on power provided to the battery (e.g., 1141, 1142, 1143) or power provided from the battery (e.g., 1141, 1142, 1143). The electronic device 200 may control the base FETs (e.g., the charging FET (e.g., 1211 in FIG. 12) and the discharging FET (e.g., 1212 in FIG. 12)) of the protection circuit (e.g., 1514, 1524, 1534) to block power provided to the battery (e.g., 1141, 1142, 1143) or power provided from the battery (e.g., 1141, 1142, 1143), based on the sensing value of the base resistor (e.g., 1213 in FIG. 12) of the protection circuit (e.g., 1514, 1524, 1534).

Referring to FIGS. 15, 11, and 12, according to various embodiments of the disclosure, the first protection circuit 1514 may include a first sensing resistor 1131 (e.g., 1230 in FIG. 12). The second protection circuit 1524 may include a second sensing resistor 1132 (e.g., 1230 in FIG. 12). The third protection circuit 1534 may include a third sensing resistor 1133 (e.g., 1230 in FIG. 12). The first protection circuit 1514 may include a first FET 1151 (e.g., the discharging FET 1263 in FIG. 12) electrically connected to the first battery 1141. The second protection circuit 1524 may include a second FET 1152 (e.g., the discharging FET 1263 in FIG. 12) electrically connected to the second battery 1142. The third protection circuit 1534 may include a third FET 1153 (e.g., the discharging FET 1263 in FIG. 12) electrically connected to the third battery 1143. The first protection circuit 1514 may include a fourth FET 1154 (e.g., the charging FET 1264 in FIG. 12) electrically connected to the first battery 1141. The second protection circuit 1524 may include a fifth FET 1155 (e.g., the charging FET 1264 in FIG. 12) electrically connected to the second battery 1142. The third protection circuit 1534 may include a sixth FET 1156 (e.g., the charging FET 1264 in FIG. 12) electrically connected to the third battery 1143.

Referring to FIGS. 15 and 16, according to various embodiments, the electronic device 200 may receive power from an external power source 1600 (e.g., 1100 in FIG. 11) (e.g., a wired charging device or a wireless charging device). For example, the electronic device 200 may receive power from an external power source 1600 (e.g., 1100 in FIG. 11) through a terminal (e.g., a USB terminal). The electronic device 200 may include an FPCB 1571 that electrically connects the terminal (e.g., a USB terminal disposed on the fourth substrate 1516 (e.g., USB substrate)) of the first housing 210 with the IF-PMIC 1104 and/or the first charging circuit 1105 of the first substrate 1510. The FPCB 1571 may be part of a power reception path 1660. The electronic device 200 may provide charging power to the first battery 1141, the second battery 1142, and/or the third battery 1143 through the first charging circuit 1105, based on power provided from the external power source 1600.

Referring to FIGS. 11, 12, 15, and 16, according to various embodiments of the disclosure, the electronic device 200 may include a first connector 1511 (e.g., a battery connector) that electrically connects the components disposed on the first substrate 1510 of the first housing 210 with the first battery 1141. The first connector 1511 may be electrically connected to the first protection circuit 1514. Power provided from the first charging circuit 1105 may be provided to the first battery 1141 through the first connector 1511 and the first protection circuit 1514. Power provided from the first charging circuit 1105 may be provided to the first battery 1141 through the first FET 1151 and the fourth FET 1154 of the first protection circuit 1514. The electronic device 200 (e.g., controller 1160) may control the fourth FET 1154 to provide power (e.g., charging power) from the first charging circuit 1105 to the first battery 1141 through a charging path 1670. While power is provided from the first charging circuit 1105 to the first battery 1141, the electronic device 200 may control the fourth FET 1154 (e.g., the charging FET 1264 in FIG. 12), based on the sensing value (e.g., current value or voltage value) of the first sensing resistor 1131 (e.g., 1230 in FIG. 12) of the first protection circuit 1312. The electronic device 200 may control the gate voltage provided to the fourth FET 1154 (e.g., the charging FET 1264 in FIG. 12), based on the sensing value (e.g., current value or voltage value) of the first sensing resistor 1131 (e.g., 1230 in FIG. 12). For example, while power is provided from the first charging circuit 1105 to the first battery 1141, the electronic device 200 may lower the gate voltage provided to the fourth FET 1154 (e.g., the charging FET 1264 in FIG. 12), based on the current (e.g., charging current) of the first sensing resistor 1131 (e.g., 1230 in FIG. 12) being greater than a reference current. While power is provided from the first charging circuit 1105 to the first battery 1141, the electronic device 200 may control the first FET 1151 to operate as a bypass.

Referring to FIGS. 11, 12, 15, and 16, according to various embodiments, power received from an external power source 1600 (e.g., 1100 in FIG. 11) (e.g., a wired charging device or a wireless charging device) may be provided to the second charging circuit 1505 through the wire of the fourth substrate 1516 (e.g., USB substrate). The electronic device 200 may provide power (e.g., charging power) to the first battery 1141 through the second charging circuit 1505, based on power received from an external power source 1600 (e.g., 1100 in FIG. 11) (e.g., a wired charging device or a wireless charging device).

Referring to FIGS. 11, 12, 15, and 16, according to various embodiments of the disclosure, the electronic device 200 may include a second connector 1512 (e.g., a battery connector) that electrically connects the components disposed on the fourth substrate 1516 of the first housing 210 with the first battery 1141. The second connector 1512 may be electrically connected to the first protection circuit 1514. Power provided from the second charging circuit 1505 may be provided to the first battery 1141 via path 1572 through the second connector 1512 and the first protection circuit 1514. Power provided from the second charging circuit 1505 may be provided to the first battery 1141 through the first FET 1151 and the fourth FET 1154 of the first protection circuit 1514. The electronic device 200 (e.g., controller 1160) may control the fourth FET 1154 to provide power (e.g., charging power) from the second charging circuit 1505 to the first battery 1141 through a charging path 1670. While power is provided from the second charging circuit 1505 to the first battery 1141, the electronic device 200 may control the fourth FET 1154 (e.g., the charging FET 1264 in FIG. 12), based on the sensing value (e.g., current value or voltage value) of the first sensing resistor 1131 (e.g., 1230 in FIG. 12) of the first protection circuit 1312. The electronic device 200 may control the gate voltage provided to the fourth FET 1154 (e.g., the charging FET 1264 in FIG. 12), based on the sensing value (e.g., current value or voltage value) of the first sensing resistor 1131 (e.g., 1230 in FIG. 12). For example, while power is provided from the second charging circuit 1505 to the first battery 1141, the electronic device 200 may lower the gate voltage provided to the fourth FET 1154 (e.g., the charging FET 1264 in FIG. 12), based on the current (e.g., charging current) of the first sensing resistor 1131 (e.g., 1230 in FIG. 12) being greater than a reference current. While power is provided from the second charging circuit 1505 to the first battery 1141, the electronic device 200 may control the first FET 1151 to operate as a bypass.

Referring to FIGS. 13 and 15, in the case of FIG. 13, the first protection circuit 1312 of the first housing 210 may be mounted adjacent to the first substrate 1310. In the case of FIG. 15, the first protection circuit 1514 of the first housing 210 may be mounted adjacent to the first substrate 1510 and the fourth substrate 1516. The first protection circuit 1514 in FIG. 15 may have a bidirectional structure in which the same is connected to the first connector 1511 and the second connector 1512. The first protection circuit 1514 in FIG. 15 may be electrically connected to the components of the first substrate 1510 through the first connector 1511 and may be electrically connected to the components of the fourth substrate 1516 through the second connector 1512.

Referring to FIGS. 11, 12, 15, and 16, according to various embodiments of the disclosure, the electronic device 200 may include a third connector 1522 (e.g., a battery connector) that electrically connects the components disposed on the second substrate 1520 of the second housing 220 with the second battery 1142. The third connector 1522 may be electrically connected to the second protection circuit 1524. The electronic device 200 may include a first FPCB 1591 that electrically connects the components of the first substrate 1510 of the first housing 210 with the components of the second substrate 1520 of the second housing 220. The first FPCB 1591 may be part of a charging path 1670. Power provided from the first charging circuit 1105 of the first housing 210 may be provided to the second battery 1142 through the first FPCB 1591, the third connector 1522, and the second protection circuit 1524. Power provided from the first charging circuit 1105 may be provided to the second battery 1142 through the second FET 1152 and the fifth FET 1155 of the second protection circuit 1524. The electronic device 200 (e.g., controller 1160) may control the fifth FET 1155 to provide power (e.g., charging power) from the first charging circuit 1105 to the second battery 1142 through the charging path 1670. While power is provided from the first charging circuit 1105 to the second battery 1142, the electronic device 200 may control the fifth FET 1155 (e.g., the charging FET 1264 in FIG. 12), based on the sensing value (e.g., current value or voltage value) of the second sensing resistor 1132 (e.g., 1230 in FIG. 12) of the second protection circuit 1524. The electronic device 200 may control the gate voltage provided to the fifth FET 1155 (e.g., the charging FET 1264 in FIG. 12), based on the sensing value (e.g., current value or voltage value) of the second sensing resistor 1132 (e.g., 1230 in FIG. 12). For example, while power is provided from the first charging circuit 1105 to the second battery 1142, the electronic device 200 may lower the gate voltage provided to the fifth FET 1155 (e.g., the charging FET 1264 in FIG. 12), based on the current (e.g., charging current) of the second sensing resistor 1132 (e.g., 1230 in FIG. 12) being greater than a reference current. While power is provided from the first charging circuit 1105 to the second battery 1142, the electronic device 200 may control the second FET 1152 to operate as a bypass.

Referring to FIGS. 11, 12, 15, and 16, according to various embodiments of the disclosure, the electronic device 200 may include a fourth connector 1532 (e.g., a battery connector) that electrically connects the components disposed on the third substrate 1530 of the third housing 230 with the third battery 1143. The fourth connector 1532 may be electrically connected to the third protection circuit 1534. The electronic device 200 may include a second FPCB 1592 that electrically connects the components of the second substrate 1520 of the second housing 220 with the components of the third substrate 1530 of the third housing 230. The second FPCB 1592 may be part of a charging path 1670. Power provided from the first charging circuit 1105 of the first housing 210 may be provided to the third battery 1143 through the first FPCB 1591, the second FPCB 1592, the fourth connector 1532, and the third protection circuit 1534. Power provided from the first charging circuit 1105 may be provided to the third battery 1143 through the third FET 1153 and the sixth FET 1156 of the third protection circuit 1534. The electronic device 200 (e.g., controller 1160) may control the sixth FET 1156 to provide power (e.g., charging power) from the first charging circuit 1105 to the third battery 1143 through the charging path 1670. While power is provided from the first charging circuit 1105 to the third battery 1143, the electronic device 200 may control the sixth FET 1156 (e.g., the charging FET 1264 in FIG. 12), based on the sensing value (e.g., current value or voltage value) of the third sensing resistor 1133 (e.g., 1230 in FIG. 12) of the third protection circuit 1534. The electronic device 200 may control the gate voltage provided to the sixth FET 1156 (e.g., the charging FET 1264 in FIG. 12), based on the sensing value (e.g., current value or voltage value) of the third sensing resistor 1133 (e.g., 1230 in FIG. 12). For example, while power is provided from the first charging circuit 1105 to the third battery 1143, the electronic device 200 may lower the gate voltage provided to the sixth FET 1156 (e.g., the charging FET 1264 in FIG. 12), based on the current (e.g., charging current) of the third sensing resistor 1133 (e.g., 1230 in FIG. 12) being greater than a reference current. While power is provided from the first charging circuit 1105 to the third battery 1143, the electronic device 200 may control the third FET 1153 to operate as a bypass.

Referring to FIGS. 11, 12, 15, and 16, according to various embodiments of the disclosure, the electronic device 200 may include a first wire 1581 that electrically connects the first load 1101 and the first connector 1511 of the first housing 210. The first wire 1581 may be disposed in the first housing 210. The first wire 1581 may be part of a first discharging path 1691. Power provided from the first battery 1141 may be provided to the first load 1101 through the first protection circuit 1514, the first connector 1511, and the first wire 1581. Power provided from the first battery 1141 may be provided to the first load 1101 through the first FET 1151 and the fourth FET 1154. The electronic device 200 (e.g., controller 1160) may control the first FET 1151 (e.g., the discharging FET 1263 in FIG. 12) to provide power (e.g., discharge power) from the first battery 1141 to the first load 1101 through the first discharging path 1691. While power is provided from the first battery 1141 to the first load 1101, the electronic device 200 may control the first FET 1151 (e.g., the discharging FET 1263 in FIG. 12), based on the sensing value (e.g., current value or voltage value) of the first sensing resistor 1131 (e.g., 1230 in FIG. 12) of the first protection circuit 1514. The electronic device 200 may control the gate voltage provided to the first FET 1151 (e.g., the discharging FET 1263 in FIG. 12), based on the sensing value (e.g., current value or voltage value) of the first sensing resistor 1131 (e.g., 1230 in FIG. 12). For example, while power is provided from the first battery 1141 to the first load 1101, the electronic device 200 may lower the gate voltage provided to the first FET 1151 (e.g., the discharging FET 1263 in FIG. 12), based on the current (e.g., discharging current) of the first sensing resistor 1131 (e.g., 1230 in FIG. 12) being greater than a reference current. While power is provided from the first battery 1141 to the first load 1101, the electronic device 200 may control the fourth FET 1154 to operate as a bypass.

Referring to FIGS. 11, 12, 15, and 16, according to various embodiments of the disclosure, the electronic device 200 may include a fifth connector 1521 (e.g., a battery connector) that electrically connects the components disposed on the second substrate 1520 of the second housing 220 with the second battery 1142. The fifth connector 1521 may be electrically connected to the second protection circuit 1524. The second protection circuit 1524 in FIG. 15 may have a bidirectional structure in which the same is connected to the third connector 1522 and the fifth connector 1521. The electronic device 200 may include a second wire 1582 that electrically connects the second load 1102 and the fifth connector 1521 of the second housing 220. The second wire 1582 may be disposed in the second housing 220. The second wire 1582 may be part of a second discharging path 1692. Power provided from the second battery 1142 may be provided to the second load 1102 through the second protection circuit 1524, the fifth connector 1521, and the second wire 1582. Power provided from the second battery 1142 may be provided to the second load 1102 through the second FET 1152 and the fifth FET 1155. The electronic device 200 (e.g., controller 1160) may control the second FET 1152 (e.g., the discharging FET 1263 in FIG. 12) to provide power (e.g., discharge power) from the second battery 1142 to the second load 1102 through the second discharging path 1692. While power is provided from the second battery 1142 to the second load 1102, the electronic device 200 may control the second FET 1152 (e.g., the discharging FET 1263 in FIG. 12), based on the sensing value (e.g., current value or voltage value) of the second sensing resistor 1132 (e.g., 1230 in FIG. 12) of the second protection circuit 1524. The electronic device 200 may control the gate voltage provided to the second FET 1152 (e.g., the discharging FET 1263 in FIG. 12), based on the sensing value (e.g., current value or voltage value) of the second sensing resistor 1132 (e.g., 1230 in FIG. 12). For example, while power is provided from the second battery 1142 to the second load 1102, the electronic device 200 may lower the gate voltage provided to the second FET 1152 (e.g., the discharging FET 1263 in FIG. 12), based on the current (e.g., discharging current) of the second sensing resistor 1132 (e.g., 1230 in FIG. 12) being greater than a reference current. While power is provided from the second battery 1142 to the second load 1102, the electronic device 200 may control the fifth FET 1155 to operate as a bypass.

Referring to FIGS. 11, 12, 15, and 16, according to various embodiments, the electronic device 200 may include a sixth connector 1531 (e.g., a battery connector) that electrically connects the components disposed on the third substrate 1530 of the third housing 230 with the third battery 1143. The sixth connector 1531 may be electrically connected to the third protection circuit 1534. The third protection circuit 1534 in FIG. 15 may have a bidirectional structure in which the same is connected to the fourth connector 1532 and the sixth connector 1531. The electronic device 200 may include a third wire 1583 that electrically connects the third load 1103 and the sixth connector 1531 of the third housing 230. The third wire 1583 may be disposed in the third housing 230. The third wire 1583 may be part of a third discharging path 1693. Power provided from the third battery 1143 may be provided to the third load 1103 through the third protection circuit 1534, the sixth connector 1531, and the third wire 1583. Power provided from the third battery 1143 may be provided to the third load 1103 through the third FET 1153 and the sixth FET 1156. The electronic device 200 (e.g., controller 1160) may control the third FET 1153 (e.g., the discharging FET 1263 in FIG. 12) to provide power (e.g., discharge power) from the third battery 1143 to the third load 1103 through the third discharging path 1693. While power is provided from the third battery 1143 to the third load 1103, the electronic device 200 may control the third FET 1153 (e.g., the discharging FET 1263 in FIG. 12), based on the sensing value (e.g., current value or voltage value) of the third sensing resistor 1133 (e.g., 1230 in FIG. 12) of the third protection circuit 1534. The electronic device 200 may control the gate voltage provided to the third FET 1153 (e.g., the discharging FET 1263 in FIG. 12), based on the sensing value (e.g., current value or voltage value) of the third sensing resistor 1133 (e.g., 1230 in FIG. 12). For example, while power is provided from the third battery 1143 to the third load 1103, the electronic device 200 may lower the gate voltage provided to the third FET 1153 (e.g., the discharging FET 1263 in FIG. 12), based on the current (e.g., discharging current) of the third sensing resistor 1133 (e.g., 1230 in FIG. 12) being greater than a reference current. While power is provided from the third battery 1143 to the third load 1103, the electronic device 200 may control the sixth FET 1156 to operate as a bypass.

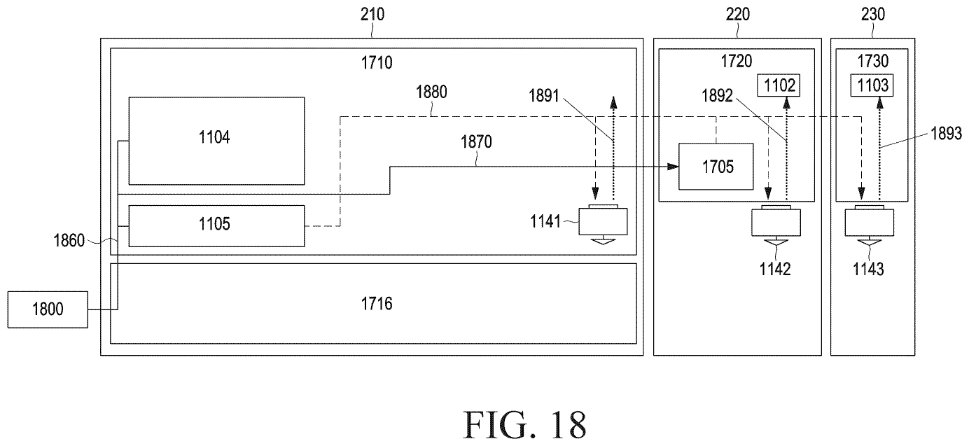

FIG. 17 is a block diagram illustrating a second charging circuit and a direct path disposed in the second housing of an electronic device, according to an embodiment of the disclosure. FIG. 18 is a diagram illustrating a charging path and a discharging path of an electronic device, according to an embodiment of the disclosure. FIGS. 17 and 18 may be described with reference to the previously described embodiments of the disclosure.

The electronic device 200 in FIGS. 17 and 18 may be the Z-type electronic device 200 in FIGS. 2 to 6.

Referring to FIGS. 17 and 18, a direct path (e.g., 1781, 1782, 1783) of the electronic device 200 according to various embodiments may be described.

Referring to FIGS. 17 and 18, according to various embodiments, the electronic device 200 may include a first housing 210 including an IF-PMIC 1104, a first charging circuit 1105, a first battery 1141, a first protection circuit 1714, and a first load 1101. The IF-PMIC 1104, the first charging circuit 1105, and the first load 1101 may be disposed on the first substrate 1710 of the first housing 210. The electronic device 200 may include a second housing 220 including a second charging circuit 1705, a second battery 1142, a second protection circuit 1724, and a second load 1102. The second charging circuit 1705 and the second load 1102 may be disposed on the second substrate 1720 of the second housing 220. The electronic device 200 may include a third housing 230 including a third battery 1143, a third protection circuit 1734, and a third load 1103. The third load 1103 may be disposed on the third substrate 1730 of the third housing 230.

Referring to FIGS. 17 and 12, according to various embodiments, the first protection circuit 1714 may include a base resistor (e.g., 1213 in FIG. 12) and base FETs (e.g., a charging FET (e.g., 1211 in FIG. 12)). The second protection circuit 1724 may include a base resistor (e.g., 1213 in FIG. 12) and base FETs (e.g., a charging FET (e.g., 1211 in FIG. 12)). The third protection circuit 1734 may include a base resistor (e.g., 1213 in FIG. 12) and base FETs (e.g., a charging FET (e.g., 1211 in FIG. 12)). The electronic device 200 (e.g., controller 1160) may use the protection circuit (e.g., 1714, 1724, 1734) to block overcharging, over-discharging, and overcurrent of the battery (e.g., 1141, 1142, 1143), based on power provided to the battery (e.g., 1141, 1142, 1143) or power provided from the battery (e.g., 1141, 1142, 1143). The electronic device 200 may control the base FETs (e.g., the charging FET (e.g., 1211 in FIG. 12) and the discharging FET (e.g., 1212 in FIG. 12)) of the protection circuit (e.g., 1714, 1724, 1734) to block power provided to the battery (e.g., 1141, 1142, 1143) or power provided from the battery (e.g., 1141, 1142, 1143), based on the sensing value of the base resistor (e.g., 1213 in FIG. 12) of the protection circuit (e.g., 1714, 1724, 1734).

Referring to FIGS. 17, 11, and 12, according to various embodiments, the first protection circuit 1714 may include a first sensing resistor 1131 (e.g., 1230 in FIG. 12). The second protection circuit 1724 may include a second sensing resistor 1132 (e.g., 1230 in FIG. 12). The third protection circuit 1734 may include a third sensing resistor 1133 (e.g., 1230 in FIG. 12). The first protection circuit 1714 may include a first FET 1151 (e.g., the discharging FET 1263 in FIG. 12) electrically connected to the first battery 1141. The second protection circuit 1724 may include a second FET 1152 (e.g., the discharging FET 1263 in FIG. 12) electrically connected to the second battery 1142. The third protection circuit 1734 may include a third FET 1153 (e.g., the discharging FET 1263 in FIG. 12) electrically connected to the third battery 1143. The first protection circuit 1714 may include a fourth FET 1154 (e.g., the charging FET 1264 in FIG. 12) electrically connected to the first battery 1141. The second protection circuit 1724 may include a fifth FET 1155 (e.g., the charging FET 1264 in FIG. 12) electrically connected to the second battery 1142. The third protection circuit 1734 may include a sixth FET 1156 (e.g., the charging FET 1264 in FIG. 12) electrically connected to the third battery 1143.

Referring to FIGS. 17 and 18, according to various embodiments, the electronic device 200 may receive power from an external power source 1800 (e.g., 1100 in FIG. 11) (e.g., a wired charging device or a wireless charging device). For example, the electronic device 200 may receive power from an external power source 1800 (e.g., 1100 in FIG. 11) through a terminal (e.g., a USB terminal). The electronic device 200 may include an FPCB 1771 that electrically connects the terminal (e.g., a USB terminal disposed on the USB substrate 1716) of the first housing 210 with the IF-PMIC 1104 and/or the first charging circuit 1105 of the first substrate 1710. The FPCB 1771 may be part of a power reception path 1860. The electronic device 200 may provide charging power to the first battery 1141, the second battery 1142, and/or the third battery 1143 through the first charging circuit 1105, based on power provided from the external power source 1800.

Referring to FIGS. 11, 12, 17, and 18, according to various embodiments, the electronic device 200 may include a first connector 1711 (e.g., a battery connector) that electrically connects the components disposed on the first substrate 1710 of the first housing 210 with the first battery 1141. The first connector 1711 may be electrically connected to the first protection circuit 1714. Power provided from the first charging circuit 1105 may be provided to the first battery 1141 through the first connector 1711 and the first protection circuit 1714. Power provided from the first charging circuit 1105 may be provided to the first battery 1141 through the first FET 1151 and the fourth FET 1154 of the first protection circuit 1714. The electronic device 200 (e.g., controller 1160) may control the fourth FET 1154 to provide power (e.g., charging power) from the first charging circuit 1105 to the first battery 1141 through a charging path 1880. While power is provided from the first charging circuit 1105 to the first battery 1141, the electronic device 200 may control the fourth FET 1154 (e.g., the charging FET 1264 in FIG. 12), based on the sensing value (e.g., current value or voltage value) of the first sensing resistor 1131 (e.g., 1230 in FIG. 12) of the first protection circuit 1312. The electronic device 200 may control the gate voltage provided to the fourth FET 1154 (e.g., the charging FET 1264 in FIG. 12), based on the sensing value (e.g., current value or voltage value) of the first sensing resistor 1131 (e.g., 1230 in FIG. 12). For example, while power is provided from the first charging circuit 1105 to the first battery 1141, the electronic device 200 may lower the gate voltage provided to the fourth FET 1154 (e.g., the charging FET 1264 in FIG. 12), based on the current (e.g., charging current) of the first sensing resistor 1131 (e.g., 1230 in FIG. 12) being greater than a reference current. While power is provided from the first charging circuit 1105 to the first battery 1141, the electronic device 200 may control the first FET 1151 to operate as a bypass.

Referring to FIGS. 11, 12, 17, and 18, according to various embodiments, the electronic device 200 may include a second connector 1722 (e.g., a battery connector) that electrically connects the components disposed on the second substrate 1720 of the second housing 220 with the second battery 1142. The second connector 1722 may be electrically connected to the second protection circuit 1724. The electronic device 200 may include a first FPCB 1791 that electrically connects the components of the first substrate 1710 of the first housing 210 with the components of the second substrate 1720 of the second housing 220. The first FPCB 1791 may be part of a charging path 1880. Power provided from the first charging circuit 1105 of the first housing 210 may be provided to the second battery 1142 through the first FPCB 1791, the second connector 1722, and the second protection circuit 1724. Power provided from the first charging circuit 1105 may be provided to the second battery 1142 through the second FET 1152 and the fifth FET 1155 of the second protection circuit 1724. The electronic device 200 (e.g., controller 1160) may control the fifth FET 1155 to provide power (e.g., charging power) from the first charging circuit 1105 to the second battery 1142 through the charging path 1880. While power is provided from the first charging circuit 1105 to the second battery 1142, the electronic device 200 may control the fifth FET 1155 (e.g., the charging FET 1264 in FIG. 12), based on the sensing value (e.g., current value or voltage value) of the second sensing resistor 1132 (e.g., 1230 in FIG. 12) of the second protection circuit 1524. The electronic device 200 may control the gate voltage provided to the fifth FET 1155 (e.g., the charging FET 1264 in FIG. 12), based on the sensing value (e.g., current value or voltage value) of the second sensing resistor 1132 (e.g., 1230 in FIG. 12). For example, while power is provided from the first charging circuit 1105 to the second battery 1142, the electronic device 200 may lower the gate voltage provided to the fifth FET 1155 (e.g., the charging FET 1264 in FIG. 12), based on the current (e.g., charging current) of the second sensing resistor 1132 (e.g., 1230 in FIG. 12) being greater than a reference current. While power is provided from the first charging circuit 1105 to the second battery 1142, the electronic device 200 may control the second FET 1152 to operate as a bypass.

Referring to FIGS. 11, 12, 17, and 18, according to various embodiments, the electronic device 200 may include an FPCB 1772 that electrically connects the components of the first substrate 1710 of the first housing 210 with the components of the second substrate 1720 of the second housing 220. The FPCB 1772 may be part of a power reception path 1870. The second charging circuit 1705 may receive power from an external power source 1800 through the FPCB 1771 and the FPCB 1772. The electronic device 200 may provide charging power to the second battery 1142 through the second charging circuit 1705, based on power provided from the external power source 1800. Power provided from the second charging circuit 1705 may be provided to the second battery 1142 through the second connector 1722 and the second protection circuit 1724. Power provided from the second charging circuit 1705 may be provided to the second battery 1142 through the second FET 1152 and the fifth FET 1155 of the second protection circuit 1724. The electronic device 200 (e.g., controller 1160) may control the fifth FET 1155 to provide power (e.g., charging power) from the second charging circuit 1705 to the second battery 1142 through the charging path 1880. While power is provided from the second charging circuit 1705 to the second battery 1142, the electronic device 200 may control the fifth FET 1155 (e.g., the charging FET 1264 in FIG. 12), based on the sensing value (e.g., current value or voltage value) of the second sensing resistor 1132 (e.g., 1230 in FIG. 12) of the second protection circuit 1724. The electronic device 200 may control the gate voltage provided to the fifth FET 1155 (e.g., charging FET 1264 in FIG. 12), based on the sensing value (e.g., current value or voltage value) of the second sensing resistor 1132 (e.g., 1230 in FIG. 12). For example, while power is provided from the second charging circuit 1705 to the second battery 1142, the electronic device 200 may lower the gate voltage provided to the fifth FET 1155 (e.g., the charging FET 1264 in FIG. 12), based on the current (e.g., charging current) of the second sensing resistor 1132 (e.g., 1230 in FIG. 12) being greater than a reference current. While power is provided from the second charging circuit 1705 to the second battery 1142, the electronic device 200 may control the second FET 1152 to operate as a bypass.

Referring to FIGS. 11, 12, 17, and 18, according to various embodiments, the electronic device 200 may include a third connector 1732 (e.g., a battery connector) that electrically connects the components disposed on the third substrate 1730 of the third housing 230 with the third battery 1143. The third connector 1732 may be electrically connected to the third protection circuit 1734. The electronic device 200 may include a second FPCB 1792 that electrically connects the components of the second substrate 1720 of the second housing 220 with the components of the third substrate 1730 of the third housing 230. The second FPCB 1792 may be part of a charging path 1880. Power provided from the first charging circuit 1105 of the first housing 210 may be provided to the third battery 1143 through the first FPCB 1791, the second FPCB 1792, the third connector 1732, and the third protection circuit 1734. Power provided from the first charging circuit 1105 may be provided to the third battery 1143 through the third FET 1153 and the sixth FET 1156 of the third protection circuit 1734. The electronic device 200 (e.g., controller 1160) may control the sixth FET 1156 to provide power (e.g., charging power) from the first charging circuit 1105 to the third battery 1143 through the charging path 1880. While power is provided from the first charging circuit 1105 to the third battery 1143, the electronic device 200 may control the sixth FET 1156 (e.g., the charging FET 1264 in FIG. 12), based on the sensing value (e.g., current value or voltage value) of the third sensing resistor 1133 (e.g., 1230 in FIG. 12) of the third protection circuit 1734. The electronic device 200 may control the gate voltage provided to the sixth FET 1156 (e.g., the charging FET 1264 in FIG. 12), based on the sensing value (e.g., current value or voltage value) of the third sensing resistor 1133 (e.g., 1230 in FIG. 12). For example, while power is provided from the first charging circuit 1105 to the third battery 1143, the electronic device 200 may lower the gate voltage provided to the sixth FET 1156 (e.g., the charging FET 1264 in FIG. 12), based on the current (e.g., charging current) of the third sensing resistor 1133 (e.g., 1230 in FIG. 12) being greater than a reference current. While power is provided from the first charging circuit 1105 to the third battery 1143, the electronic device 200 may control the third FET 1153 to operate as a bypass.

Referring to FIGS. 11, 12, 17, and 18, according to various embodiments, the electronic device 200 may include a first wire 1781 that electrically connects the first load 1101 and the first connector 1711 of the first housing 210. The first wire 1781 may be disposed in the first housing 210. The first wire 1781 may be part of a first discharging path 1891. Power provided from the first battery 1141 may be provided to the first load 1101 through the first protection circuit 1714, the first connector 1711, and the first wire 1781. Power provided from the first battery 1141 may be provided to the first load 1101 through the first FET 1151 and the fourth FET 1154. The electronic device 200 (e.g., controller 1160) may control the first FET 1151 (e.g., the discharging FET 1263 in FIG. 12) to provide power (e.g., discharge power) from the first battery 1141 to the first load 1101 through the first discharging path 1891. While power is provided from the first battery 1141 to the first load 1101, the electronic device 200 may control the first FET 1151 (e.g., the discharging FET 1263 in FIG. 12), based on the sensing value (e.g., current value or voltage value) of the first sensing resistor 1131 (e.g., 1230 in FIG. 12) of the first protection circuit 1714. The electronic device 200 may control the gate voltage provided to the first FET 1151 (e.g., the discharging FET 1263 in FIG. 12), based on the sensing value (e.g., current value or voltage value) of the first sensing resistor 1131 (e.g., 1230 in FIG. 12). For example, while power is provided from the first battery 1141 to the first load 1101, the electronic device 200 may lower the gate voltage provided to the first FET 1151 (e.g., the discharging FET 1263 in FIG. 12), based on the current (e.g., discharging current) of the first sensing resistor 1131 (e.g., 1230 in FIG. 12) being greater than a reference current. While power is provided from the first battery 1141 to the first load 1101, the electronic device 200 may control the fourth FET 1154 to operate as a bypass.

Referring to FIGS. 11, 12, 17, and 18, according to various embodiments, the electronic device 200 may include a fourth connector 1721 (e.g., a battery connector) that electrically connects the components disposed on the second substrate 1720 of the second housing 220 with the second battery 1142. The fourth connector 1721 may be electrically connected to the second protection circuit 1724. The second protection circuit 1724 in FIG. 17 may have a bidirectional structure in which the same is connected to the second connector 1722 and the fourth connector 1721. The electronic device 200 may include a second wire 1782 that electrically connects the second load 1102 and the fourth connector 1721 of the second housing 220. The second wire 1782 may be disposed in the second housing 220. The second wire 1782 may be part of a second discharging path 1892. Power provided from the second battery 1142 may be provided to the second load 1102 through the second protection circuit 1724, the fourth connector 1721, and the second wire 1782. Power provided from the second battery 1142 may be provided to the second load 1102 through the second FET 1152 and the fifth FET 1155. The electronic device 200 (e.g., controller 1160) may control the second FET 1152 (e.g., the discharging FET 1263 in FIG. 12) to provide power (e.g., discharge power) from the second battery 1142 to the second load 1102 through the second discharging path 1892. While power is provided from the second battery 1142 to the second load 1102, the electronic device 200 may control the second FET 1152 (e.g., the discharging FET 1263 in FIG. 12), based on the sensing value (e.g., current value or voltage value) of the second sensing resistor 1132 (e.g., 1230 in FIG. 12) of the second protection circuit 1724. The electronic device 200 may control the gate voltage provided to the second FET 1152 (e.g., the discharging FET 1263 in FIG. 12), based on the sensing value (e.g., current value or voltage value) of the second sensing resistor 1132 (e.g., 1230 in FIG. 12). For example, while power is provided from the second battery 1142 to the second load 1102, the electronic device 200 may lower the gate voltage provided to the second FET 1152 (e.g., the discharging FET 1263 in FIG. 12), based on the current (e.g., discharging current) of the second sensing resistor 1132 (e.g., 1230 in FIG. 12) being greater than a reference current. While power is provided from the second battery 1142 to the second load 1102, the electronic device 200 may control the fifth FET 1155 to operate as a bypass.

Referring to FIGS. 11, 12, 17, and 18, according to various embodiments, the electronic device 200 may include a fifth connector 1731 (e.g., a battery connector) that electrically connects the components disposed on the third substrate 1730 of the third housing 230 with the third battery 1143. The fifth connector 1731 may be electrically connected to the third protection circuit 1734. The third protection circuit 1734 in FIG. 17 may have a bidirectional structure in which the same is connected to the third connector 1732 and the fifth connector 1731. The electronic device 200 may include a third wire 1783 that electrically connects the third load 1103 and the fifth connector 1731 of the third housing 230. The third wire 1783 may be disposed in the third housing 230. The third wire 1783 may be part of a third discharging path 1893. Power provided from the third battery 1143 may be provided to the third load 1103 through the third protection circuit 1734, the fifth connector 1731, and the third wire 1783. Power provided from the third battery 1143 may be provided to the third load 1103 through the third FET 1153 and the sixth FET 1156. The electronic device 200 (e.g., controller 1160) may control the third FET 1153 (e.g., the discharging FET 1263 in FIG. 12) to provide power (e.g., discharge power) from the third battery 1143 to the third load 1103 through the third discharging path 1793. While power is provided from the third battery 1143 to the third load 1103, the electronic device 200 may control the third FET 1153 (e.g., the discharging FET 1263 in FIG. 12), based on the sensing value (e.g., current value or voltage value) of the third sensing resistor 1133 (e.g., 1230 in FIG. 12) of the third protection circuit 1734. The electronic device 200 may control the gate voltage provided to the third FET 1153 (e.g., the discharging FET 1263 in FIG. 12), based on the sensing value (e.g., current value or voltage value) of the third sensing resistor 1133 (e.g., 1230 in FIG. 12). For example, while power is provided from the third battery 1143 to the third load 1103, the electronic device 200 may lower the gate voltage provided to the third FET 1153 (e.g., the discharging FET 1263 in FIG. 12), based on the current (e.g., discharging current) of the third sensing resistor 1133 (e.g., 1230 in FIG. 12) being greater than a reference current. While power is provided from the third battery 1143 to the third load 1103, the electronic device 200 may control the sixth FET 1156 to operate as a bypass.

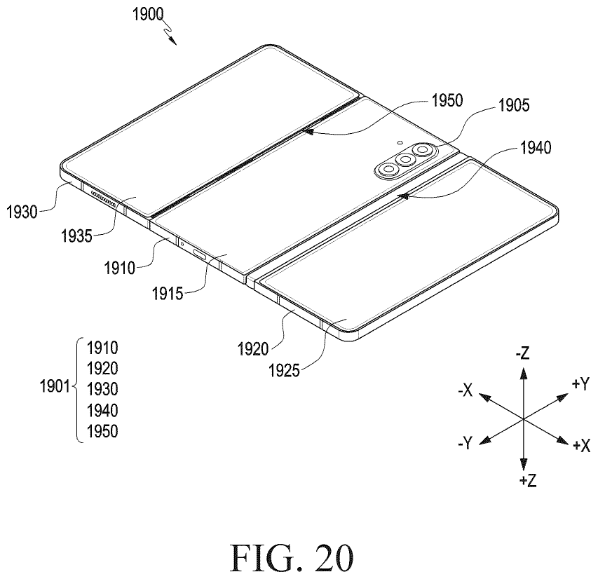

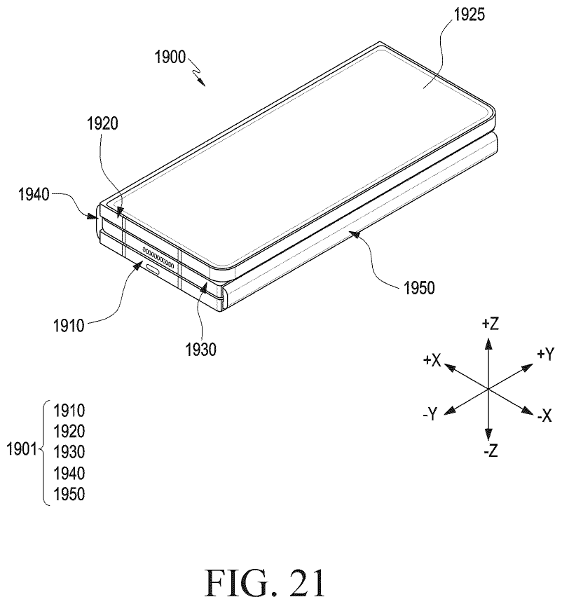

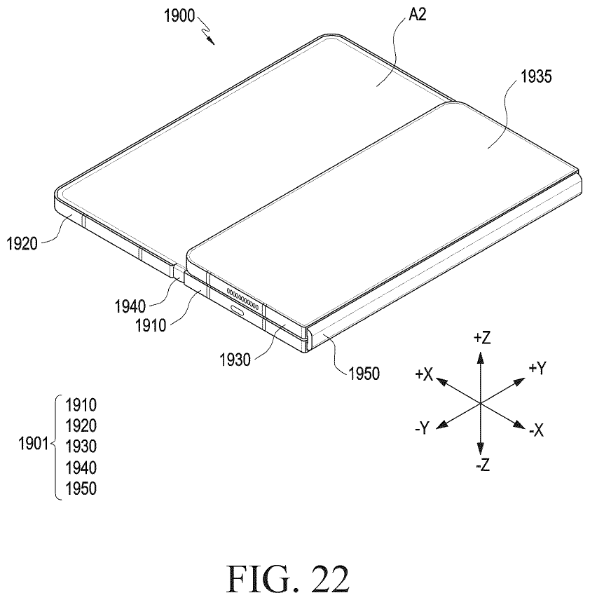

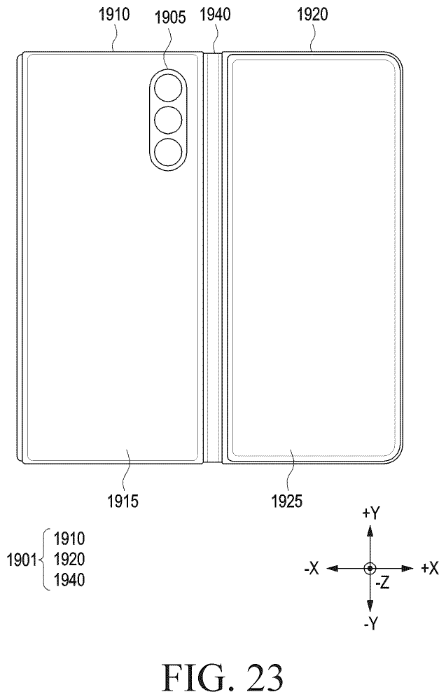

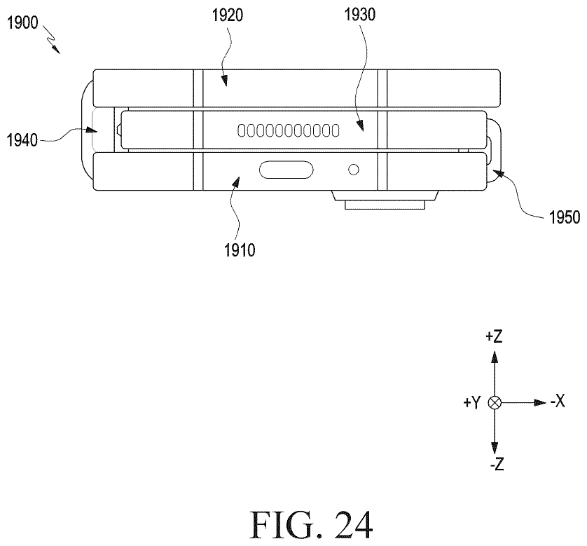

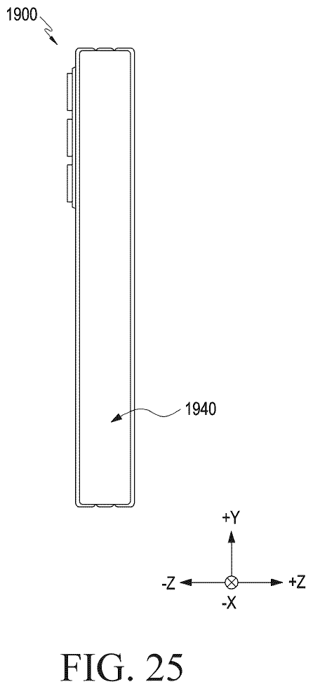

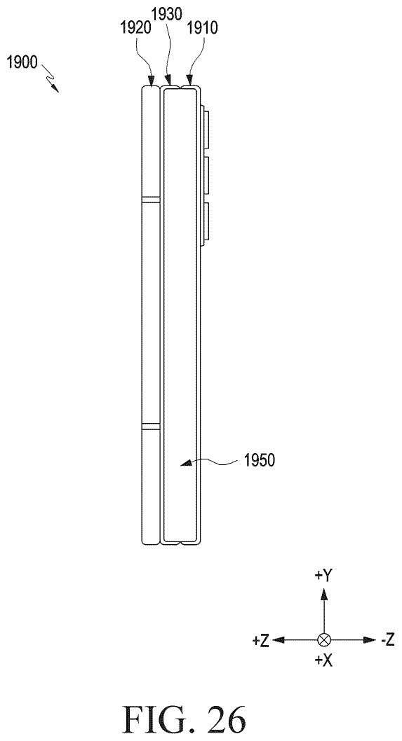

FIG. 19 is a front perspective view of a G-type electronic device in an unfolded state, according to an embodiment of the disclosure. FIG. 20 is a rear perspective view of a G-type electronic device in an unfolded state, according to an embodiment of the disclosure. FIG. 21 is a perspective view of a G-type electronic device in a folded state, according to an embodiment of the disclosure. FIG. 22 is a front perspective view of a G-type electronic device in a single-folded state, according to an embodiment of the disclosure. FIG. 23 is a rear view of a G-type electronic device in a single-folded state, according to an embodiment of the disclosure. FIG. 24 is a lower side view of a G-type electronic device in a folded state, according to an embodiment of the disclosure. FIG. 25 is a left side view of a G-type electronic device in a folded state, according to an embodiment of the disclosure. FIG. 26 is a right side view of a G-type electronic device in a folded state, according to an embodiment of the disclosure.

Referring to FIGS. 19 to 26, the structure of a G-type electronic device 1900 may be described. The electronic device 1900, as an example of the electronic device 101 shown in FIG. 1, may be a foldable or bendable device 1900. The configuration of the electronic device 1900 in FIGS. 19 to 34 may be partially or entirely identical to the configuration of the electronic device 101 in FIG. 1.

Hereinafter, for convenience of description, the drawings may include a spatial coordinate system (or Cartesian coordinate system) including the X-axis, Y-axis, or Z-axis.

According to an embodiment, the electronic device 1900 may include a housing 1901 and a flexible or foldable display (hereinafter abbreviated as “flexible display 1903”) (e.g., the display module 160 in FIG. 1) disposed in a space formed by the housing 1901.

According to an embodiment, the housing 1901 of the electronic device 1900 may be defined and/or referred to as a foldable housing 1901 or a deformable housing 1901.

According to an embodiment, when the electronic device 1900 is in an unfolded state (e.g., FIG. 19), the surface on which the flexible display 1903 is disposed (or the surface where the flexible display 1903 is visible from the outside of the electronic device 1900) may be defined as the front surface of the electronic device 1900. When the electronic device 1900 is in an unfolded state (e.g., FIG. 20), the surface opposite to the front surface may be defined as the rear surface of the electronic device 1900. In addition, the surface surrounding the space between the front surface and the rear surface may be defined as the side surface of the electronic device 1900.

According to an embodiment, the housing 1901 may include a first housing 1910, a second housing 1920, a third housing 1930, a first hinge 1940, or a second hinge 1950. The first hinge 1940 may be defined and/or referred to as a first hinge assembly. The second hinge 1950 may be defined and/or referred to as a second hinge assembly. The first housing 1910 may be disposed between the second housing 1920 and the third housing 1930. The second housing 1920 may be rotatably coupled to the first housing 1910. The third housing 1930 may be rotatably coupled to the first housing 1910.

According to an embodiment, the first hinge 1940 may be disposed between the first housing 1910 and the second housing 1920. The first hinge 1940 may be connected to the first housing 1910 or the second housing 1920. The second housing 1920 may be rotatably connected to the first housing 1910 through the first hinge 1940. According to an embodiment, the second hinge 1950 may be disposed between the first housing 1910 and the third housing 1930. The second hinge 1950 may be connected to the first housing 1910 or the third housing 1930. The third housing 1930 may be rotatably connected to the first housing 1910 through the second hinge 1950.

According to an embodiment, the electronic device 1900 may include a sensor region. The sensor region may be disposed on the housing 1901. An illuminance sensor and an image sensor may be disposed in the sensor region. The illuminance sensor may detect the amount of light around the electronic device 1900, and the image sensor may convert light incident through a camera lens into a digital signal. The illuminance sensor and the image sensor may be visually exposed to the flexible display 1903. According to an embodiment, the illuminance sensor and the image sensor may not be visually exposed. For example, the camera may be configured as an under-display camera (UDC). Pixels in a region of the flexible display 1903 corresponding to the position of the UDC may be configured differently from pixels in other regions such that the image sensor and/or camera are not visually exposed.

According to an embodiment, the first housing 1910 may be connected to the first hinge 1940. The first housing 1910 may include a first front surface facing in a first direction (e.g., in the +Z direction in FIG. 19) and a first rear surface facing in a second direction (e.g., in the −Z direction in FIG. 20) opposite to the first direction. The second housing 1920 may be connected to the first hinge 1940. The second housing 1920 may include a second front surface facing in the first direction (e.g., in the +Z direction in FIG. 19) and a second rear surface facing in the second direction (e.g., in the −Z direction in FIG. 20) opposite to the first direction.

According to an embodiment, the first housing 1910 may be connected to the second hinge 1950. The third housing 1930 may be connected to the second hinge 1950. The third housing 1930 may include a third front surface facing in the first direction (e.g., in the +Z direction in FIG. 19) and a third rear surface facing in the second direction (e.g., in the −Z direction in FIG. 20) opposite to the first direction.

According to an embodiment, the third housing 1930 may rotate relative to the first housing 1910 about the second hinge 1950. The first housing 1910 and the third housing 1930 may be provided in a folded state (e.g., FIGS. 21, 22, 23) or in an unfolded state (e.g., FIGS. 19 and 20). When the first housing 1910 and the third housing 1930 are in the folded state, the first front surface of the first housing 1910 may face the third front surface of the third housing 1930. When the first housing 1910 and the third housing 1930 are in the folded state, the first rear surface of the first housing 1910 may face in a direction opposite to the third rear surface of the third housing 1930. When the first housing 1910 and the third housing 1930 are in the unfolded state, the first front surface of the first housing 1910 may face in the same direction as the third front surface of the third housing 1930. When the first housing 1910 and the third housing 1930 are in the unfolded state, the second rear surface of the first housing 1910 may face in the same direction as the third rear surface of the third housing 1930.

According to an embodiment, the second housing 1920 may rotate relative to the first housing 1910 about the first hinge 1940. The first housing 1910 and the second housing 1920 may be provided in a folded state (e.g., FIG. 21) or in an unfolded state (e.g., FIGS. 19, 20, 22, and 23). When the first housing 1910 and the second housing 1920 are in the folded state, the first rear surface of the first housing 1910 may face in a direction opposite to the second rear surface of the second housing 1920. When the first housing 1910 and the second housing 1920 are in the folded state, the first front surface of the first housing 1910 may face in a direction opposite to the second front surface of the second housing 1920. When the first housing 1910 and the second housing 1920 are in the unfolded state, the first front surface of the first housing 1910 may face in the same direction as the second front surface of the second housing 1920. When the first housing 1910 and the second housing 1920 are in the unfolded state, the first rear surface of the first housing 1910 may face in the same direction as the second rear surface of the second housing 1920. When the first housing 1910 and the third housing 1930 are in the folded state and the first housing 1910 and the second housing 1920 are in the folded state, the second front surface of the second housing 1920 may face the third rear surface of the third housing 1930. When the first housing 1910 and the third housing 1930 are in the folded state and the first housing 1910 and the second housing 1920 are in the folded state, the second rear surface of the second housing 1920 may face in a direction opposite to the first front surface of the third housing 1930. When the first housing 1910 and the third housing 1930 are in the folded state and the first housing 1910 and the second housing 1920 are in the unfolded state, the second front surface of the second housing 1920 may face in the same direction as the third rear surface of the third housing 1930. When the first housing 1910 and the third housing 1930 are in the folded state and the first housing 1910 and the second housing 1920 are in the unfolded state, the second rear surface of the second housing 1920 may face in the same direction as the third front surface of the third housing 1930.

According to an embodiment, the fully folded state of the electronic device 1900 may be defined as a state in which the first housing 1910 and the third housing 1930 are in a folded state, and the first housing 1910 and the second housing 1920 are simultaneously in a folded state. The fully unfolded state of the electronic device 1900 may be defined as a state in which the first housing 1910 and the second housing 1920 are in an unfolded state and the first housing 1910 and the third housing 1930 are simultaneously in an unfolded state.

According to an embodiment, the first housing 1910 and the second housing 1920 may be disposed on both sides of the first hinge 1940 and may have an overall symmetrical shape with respect to the first hinge 1940. However, the first housing 1910 and the second housing 1920 do not necessarily have a symmetrical shape. Depending on whether the state of the first housing 1910 and the second housing 1920 is an unfolded status, a folded status, or an intermediate status (a partially unfolded or partially folded status), the angle or distance between the first housing 1910 and the second housing 1920 may vary.

According to an embodiment, when the first housing 1910 and the third housing 1930 are in a fully folded state, the first front surface and the third front surface may face each other. According to an embodiment, the first housing 1910 and the third housing 1930 may be disposed on both sides of the second hinge 1950 and may have an overall symmetrical shape with respect to the second hinge 1950. However, the first housing 1910 and the third housing 1930 do not necessarily have a symmetrical shape. Depending on whether the state of the first housing 1910 and the third housing 1930 is an unfolded status, a folded status, or an intermediate status (a partially unfolded or partially folded status), the angle or distance between the first housing 1910 and the third housing 1930 may vary.

Referring to FIG. 19, the first housing 1910, the second housing 1920, and the third housing 1930 may collectively form a recess for accommodating the flexible display 1903. According to an embodiment, at least a portion of the first housing 1910, the second housing 1920, and the third housing 1930 may be formed of a metal material or a non-metal material having a degree of rigidity selected to support the flexible display 1903. At least a portion formed of the metal material may provide a ground plane for the electronic device 1900 and may be electrically connected to a ground line formed on a printed circuit board disposed within the foldable housing 1901.

According to an embodiment, the first housing 1910 may include a first rear cover 1915. The first rear cover 1915 may be disposed on one side of the first hinge 1940 or one side of the second hinge 1950 on the rear surface of the electronic device 1900 and may have, for example, a substantially rectangular edge. The edge of the first rear cover 1915 may be surrounded by the side surfaces of the first housing 1910.

According to an embodiment, the second housing 1920 may include a second rear cover 1925. The second rear cover 1925 may be disposed on the other side of the first hinge 1940 on the rear surface of the electronic device 1900 and may have, for example, a substantially rectangular edge. The edge of the second rear cover 1925 may be surrounded by the side surfaces of the second housing 1920. According to an embodiment, the electronic device 1900 may include a display (e.g., a cover display) disposed on the second rear cover 1925.

According to an embodiment, the third housing 1930 may include a third rear cover 1935. The third rear cover 1935 may be disposed on the other side of the second hinge 1950 on the rear surface of the electronic device 1900 and may have, for example, a substantially rectangular edge. The edge of the third rear cover 1935 may be surrounded by the side surfaces of the third housing 1930.

According to an embodiment, the first rear cover 1915 and the second rear cover 1925 may have a substantially symmetrical shape with respect to the first hinge 1940. The first rear cover 1915 and the third rear cover 1935 may have a substantially symmetrical shape with respect to the second hinge 1950. However, the first rear cover 1915, the second rear cover 1925, and the third rear cover 1935 do not necessarily have a mutually symmetrical shape, and in an embodiment, the electronic device 1900 may include a first rear cover 1915, a second rear cover 1925, and a third rear cover 1935 of various shapes. In an embodiment, the first rear cover 1915 may be formed integrally with the first housing 1910. The second rear cover 1925 may be formed integrally with the second housing 1920. The third rear cover 1935 may be formed integrally with the third housing 1930.

According to an embodiment, the first rear cover 1915, the second rear cover 1925, the third rear cover 1935, the first housing 1910, the second housing 1920, and the third housing 1930 may form a space in which various components (e.g., a printed circuit board or a battery) of the electronic device 1900 may be disposed. According to an embodiment, one or more components may be disposed or visually exposed on the rear surface of the electronic device 1900. One or more components or sensors (e.g., a camera 1905) may be visually exposed through the second rear cover 1925.

According to an embodiment, the flexible display 1903 may be disposed in a space formed by the housing 1901. For example, the flexible display 1903 may be seated in a recess formed by the housing 1901 and may be visible from the outside through the front surface (e.g., the first front surface, the second front surface, and/or the third front surface) of the electronic device 1900. According to an embodiment, the flexible display 1903 may constitute most of the front surface (e.g., the first front surface, the second front surface, and/or the third front surface) of the electronic device 1900. Accordingly, the front surface (e.g., the first front surface, the second front surface, and/or the third front surface) of the electronic device 1900 may include the flexible display 1903, a partial region of the first housing 1910 adjacent to the flexible display 1903, a partial region of the second housing 1920 adjacent to the flexible display 1903, and a partial region of the third housing 1930 adjacent to the flexible display 1903. The rear surface (e.g., the first rear surface, the second rear surface, and/or the third rear surface) of the electronic device 1900 may include the first rear cover 1915, a partial region of the first housing 1910 adjacent to the first rear cover 1915, the second rear cover 1925, a partial region of the second housing 1920 adjacent to the second rear cover 1925, the third rear cover 1935, and a partial region of the third housing 1930 adjacent to the third rear cover 1935.

According to an embodiment, the flexible display 1903 may refer to a display configured such that at least a partial region of the flexible display 1903 may be deformed into a flat or curved surface. For example, the flexible display 1903 may be configured to be at least partially folded or at least partially unfolded.

According to an embodiment, the flexible display 1903 may include a first display region A1, a second display region A2, a third display region A3, a first folding region A4, or a second folding region A5. The first display region A1 may be disposed on one side of the first folding region A4, and the second display region A2 may be disposed on the other side of the first folding region A4. The first display region A1 may be disposed on one side of the second folding region A5, and the third display region A3 may be disposed on the other side of the second folding region A5.

According to an embodiment, the first display region A1 may be disposed on the first housing 1910. The second display region A2 may be disposed on the second housing 1920. The third display region A3 may be disposed on the third housing 1930. According to an embodiment, the first folding region A4 may connect the first display region A1 and the second display region A2 and may be disposed in a region corresponding to the first hinge 1940. The second folding region A5 may connect the first display region A1 and the third display region A3 and may be disposed in a region corresponding to the second hinge 1950. The division of the regions of the flexible display 1903 shown in FIG. 19 is exemplary, and the display may be divided into multiple (e.g., six or more, or three) regions depending on the structure or function.

According to an embodiment, the flexible display 1903 may be combined with or disposed adjacent to a touch panel equipped with a touch sensing circuit and a pressure sensor capable of measuring the intensity (pressure) of a touch. For example, as an example of a touch panel, the flexible display 1903 may be combined with or disposed adjacent to an electromagnetic induction panel for detecting a stylus pen operating of an electromagnetic resonance (EMR) type.

According to an embodiment, the first display region A1 and the second display region A2 may have an overall symmetrical shape with respect to the first folding region A4. The first display region A1 and the third display region A3 may have an overall symmetrical shape with respect to the second folding region A5.

According to an embodiment, when the electronic device 1900 is in a fully folded state (e.g., FIG. 21), the first folding region A4 located on the first hinge 1940 and the second folding region A5 located on the second hinge 1950 may be disposed inside the electronic device 1900 and not exposed to the outside. In an embodiment, the first hinge 1940 may be defined and/or referred to as an in-folding hinge that does not expose a portion of the flexible display 1903 to the outside in the folded state. The second hinge 1950 may be defined and/or referred to as an in-folding hinge that does not expose a portion of the flexible display 1903 to the outside in the folded state.

FIG. 27 is a block diagram illustrating a charging circuit, batteries, sensing resistors, and current control FETs of an electronic device, according to an embodiment of the disclosure.

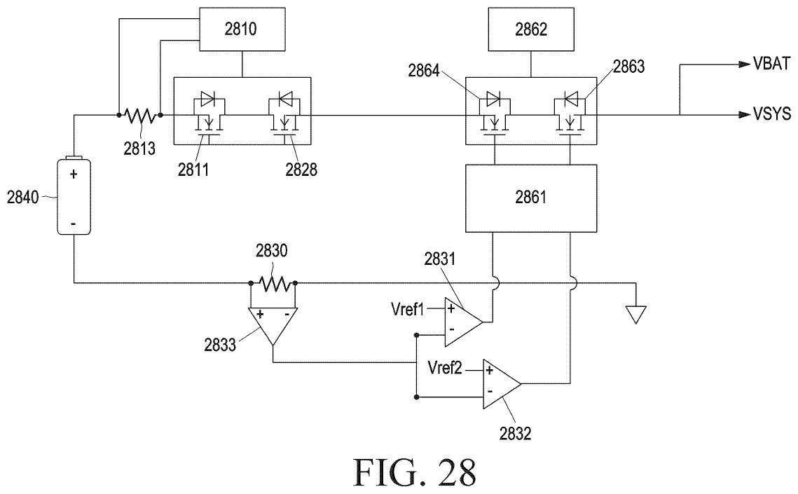

FIG. 28 is a diagram illustrating a protection circuit, a battery, a sensing resistor, and current control FETs of an electronic device, according to an embodiment of the disclosure.

Referring to FIGS. 27 and 28, an electronic device 1900 according to an embodiment may be described. The electronic device 1900 in FIGS. 27 and 28 may be the G-type electronic device 1900 in FIGS. 19 to 23.

As described above, the embodiment in FIG. 11 pertains to an example of a Z-type electronic device 200 but may also be applied to the G-type electronic device 1900 in FIG. 19. The embodiment in FIG. 27 may be described with reference to the embodiment in FIG. 11.

Referring to FIG. 27, according to an embodiment, the electronic device 1900 may include a first housing 1910 including a controller 2740 (e.g., a processor 280), a power management circuit 2760 (e.g., an IF-PMIC), a first charging circuit 2750, a first battery 2721, a first sensing resistor 2731, and a first load 2701. The electronic device 1900 may include a second housing 1920 including a second battery 2722, a second sensing resistor 2732, and a second load 2702. The electronic device 1900 may include a third housing 1930 including a third battery 2723, a third sensing resistor 2733, and a third load 2703. The electronic device 1900 may include a first FET 2711 (e.g., a discharging FET) disposed in the first housing 1910 and electrically connected to the first battery 2721. The discharging FET may be an FET that controls power (e.g., a discharging current) provided from the battery (e.g., 2721). The electronic device 1900 may include a second FET 2712 (e.g., a discharging FET) disposed in the second housing 1920 and electrically connected to the second battery 2722. The electronic device 1900 may include a third FET 2713 (e.g., a discharging FET) disposed in the third housing 1930 and electrically connected to the third battery 2723. The electronic device 1900 may include a fourth FET 2714 (e.g., a charging FET) disposed in the first housing 1910 and electrically connected to the first battery 2721. The charging FET may be an FET that controls power (e.g., a charging current) provided to the battery (e.g., 2721). The electronic device 1900 may include a fifth FET 2715 (e.g., a charging FET) disposed in the second housing 1920 and electrically connected to the second battery 2722. The electronic device 1900 may include a sixth FET 2716 (e.g., a charging FET) disposed in the third housing 1930 and electrically connected to the third battery 2723.

According to an embodiment, the electronic device 1900 (e.g., controller 2740) may provide power to the first battery 2721, the second battery 2722, and/or the third battery 2723 through the first charging circuit 2750, based on power provided from an external power source (e.g., a wired charging device or a wireless charging device). The electronic device 1900 may control the fourth FET 2714 to provide power (e.g., charging power) from the first charging circuit 2750 to the first battery 2721 through a charging path. While power is provided from the first charging circuit 2750 to the first battery 2721, the electronic device 1900 may control the first FET 2711 to operate as a bypass. The electronic device 1900 may control the first FET 2711 to provide power (e.g., discharge power) from the first battery 2721 to the first load 2701 through a first path of the first housing 1910. While power is provided from the first battery 2721 to the first load 2701, the electronic device 1900 may control the fourth FET 2714 to operate as a bypass. The electronic device 1900 may control the fifth FET 2715 to provide power (e.g., charging power) from the first charging circuit 2750 to the second battery 2722 through a charging path. While power is provided from the first charging circuit 2750 to the second battery 2722, the electronic device 1900 may control the second FET 2712 to operate as a bypass. The electronic device 1900 may control the second FET 2712 to provide power (e.g., discharge power) from the second battery 2722 to the second load 2702 through a second path of the second housing 1920. While power is provided from the second battery 2722 to the second load 2702, the electronic device 1900 may control the fifth FET 2715 to operate as a bypass. The electronic device 1900 may control the sixth FET 2716 to provide power (e.g., charging power) from the first charging circuit 2750 to the third battery 2723 through a charging path. While power is provided from the first charging circuit 2750 to the third battery 2723, the electronic device 1900 may control the third FET 2713 to operate as a bypass. The electronic device 1900 may control the third FET 2713 to provide power (e.g., discharge power) from the third battery 2723 to the third load 2703 through a third path of the third housing 1930. While power is provided from the third battery 2723 to the third load 2703, the electronic device 1900 may control the sixth FET 2716 to operate as a bypass.

According to an embodiment, the electronic device 1900 may include a current control block (e.g., a current control block corresponding to 1161 in FIG. 11) (e.g., the current control block 2861 in FIG. 28), a protection block (e.g., a protection block corresponding to 1162 in FIG. 11) (e.g., the protection block 2862 in FIG. 28), a voltage sensing block (e.g., a voltage sensing block corresponding to 1163 in FIG. 11), a fuel gauge (e.g., a fuel gauge corresponding to 1164 in FIG. 11), and/or a current sensing block (e.g., a current sensing block corresponding to 1165 in FIG. 11) (e.g., a current sensing block including 2831, 2832, and 2833 in FIG. 28). The current control block, the protection block, the voltage sensing block, the fuel gauge, and/or the current sensing block of the electronic device 1900 may be disposed in the first housing 1910. The current control block of the electronic device 1900 may control the driving voltage provided to the FETs (e.g., 2711, 2712, 2713, 2714, 2715, and/or 2716). The protection block of the electronic device 1900 may interrupt the current flowing through the FETs (e.g., 2711, 2712, 2713, 2714, 2715, and/or 2716). The voltage sensing block of the electronic device 1900 may sense the voltage of the battery (e.g., 2721, 2722, 2723). The fuel gauge of the electronic device 1900 may identify information (e.g., the state of charging, charging capacity, remaining capacity, lifespan, the number of times of charging/discharging, and battery resistance) of the battery (e.g., 2721, 2722, 2723). The current sensing block of the electronic device 1900 may sense the current flowing through the sensing resistor (e.g., 2731, 2732, 2733) (or the voltage corresponding to the current flowing through the sensing resistor (e.g., 2731, 2732, 2733)). The electronic device 1900 (e.g., controller 2740) may control the first FET 2711, second FET 2712, third FET 2713, fourth FET 2714, fifth FET 2715, and/or sixth FET 2716 by using the current control block, the protection block, the voltage sensing block, fuel gauge, and/or the current sensing block.

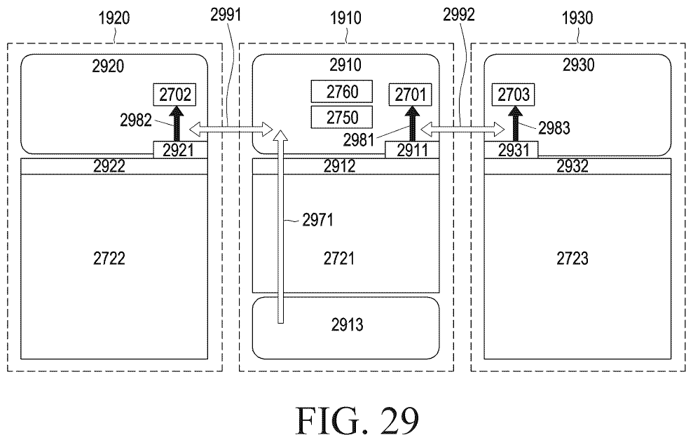

FIG. 28 is a diagram illustrating a protection circuit (e.g., 2912, 2922, 2932 in FIG. 29, 3113, 3123, 3133 in FIG. 31, or 3312, 3322, 3332 in FIG. 33) according to an embodiment of the disclosure. The discharging FET 2863 in FIG. 28 may correspond to the first FET 2711, the second FET 2712, or the third FET 2713 in FIG. 27. The charging FET 2864 in FIG. 28 may correspond to the fourth FET 2714, the fifth FET 2715, or the sixth FET 2716 in FIG. 27. The sensing resistor 2830 in FIG. 28 may correspond to the first sensing resistor 2731, the second sensing resistor 2732, or the third sensing resistor 2733 in FIG. 27. The battery 2840 in FIG. 28 may correspond to the first battery 2721, the second battery 2722, or the third battery 2723 in FIG. 27. Referring to FIG. 28, VBAT may indicate that the circuit in FIG. 28 is electrically connected to the charging path of the battery (e.g., 2840, 2721, 2722, 2723). In FIG. 28, VSYS may indicate that the circuit in FIG. 28 is electrically connected to the discharging path to the load (e.g., 2701, 2702, 2703). The electronic device 1900 (e.g., controller 2740) may compare the current flowing through the sensing resistor 2830 (or the corresponding voltage) with a reference current (or the corresponding reference voltage) by using a current sensing block (e.g., a block including 2831, 2832, and 2833). For example, the electronic device 1900 may identify the current (e.g., sensing current) flowing through the sensing resistor 2830 (or the voltage (e.g., sensing voltage) corresponding to the sensing current) by using the comparator 2833 to compare the voltage across both ends of the sensing resistor 2830. The current (e.g., sensing current) flowing through the sensing resistor 2830 may be a charging current (e.g., current flowing to the battery 2840) or a discharging current (e.g., current flowing from the battery 2840) depending on the direction. The electronic device 1900 may compare the charging current (e.g., current flowing to the battery 2840) (or the voltage corresponding to the charging current) with a reference current (or a reference voltage (e.g., first reference voltage Vref1) corresponding to the reference current) by using the first comparator 2831. The electronic device 1900 may control the FET (e.g., charging FET 2864), based on the current (e.g., charging current) flowing through the sensing resistor 2830 being greater than the reference current (e.g., first reference current). The electronic device 1900 may control the FET (e.g., charging FET 2864) to reduce the current (e.g., charging current) flowing through the sensing resistor 2830, based on the current (e.g., charging current) flowing through the sensing resistor 2830 being greater than the reference current (e.g., first reference current). The electronic device 1900 may lower the gate voltage provided to the FET (e.g., charging FET 2864), based on the current (e.g., charging current) flowing through the sensing resistor 2830 being greater than the reference current (e.g., first reference current). While the charging current is provided to the battery 2840 through the charging FET 2864, the electronic device 1900 may control the discharging FET 2863 to operate as a bypass. The electronic device 1900 may compare the discharging current (e.g., current flowing from the battery 2840) (or the voltage corresponding to the discharging current) with a reference current (or a reference voltage (e.g., second reference voltage Vref2) corresponding to the reference current) by using the second comparator 2832. The electronic device 1900 may control the FET (e.g., discharging FET 2863), based on the current (e.g., discharging current) flowing through the sensing resistor 2830 being greater than the reference current (e.g., second reference current). The electronic device 1900 may control the FET (e.g., discharging FET 2863) to reduce the current (e.g., discharging current) flowing through the sensing resistor 2830, based on the current (e.g., discharging current) flowing through the sensing resistor 2830 being greater than the reference current (e.g., second reference current). The electronic device 1900 may lower the gate voltage provided to the FET (e.g., discharging FET 2863), based on the current (e.g., discharging current) flowing through the sensing resistor 2830 being greater than the reference current (e.g., second reference current). While the discharging current is provided from the battery 2840 through the discharging FET 2863, the electronic device 1900 may control the charging FET 2864 to operate as a bypass.

Referring to FIG. 28, according to an embodiment, the protection circuit (e.g., 2912, 2922, 2932 in FIG. 29, 3113, 3123, 3133 in FIG. 31, or 3312, 3322, 3332 in FIG. 33) may include a base resistor 2813 and base FETs 2811, 2828. The electronic device 1900 (e.g., controller 2740) may control the base FETs 2811, 2828 by using the PCM block 2810, based on the sensing value (e.g., current value or voltage value) of the base resistor 2813. The PCM block 2810 may control the base FETs 2811, 2828 to block power provided to the battery 2840 or power provided from the battery 2840. The electronic device 1900 may block the overcharging, over-discharging, and overcurrent of the battery 2840 by using the PCM block 2810, based on the sensing value (e.g., current value or voltage value) of the base resistor 2813.

Referring to FIG. 28, according to an embodiment, the protection circuit (e.g., 2912, 2922, 2932 in FIG. 29, 3113, 3123, 3133 in FIG. 31, or 3312, 3322, 3332 in FIG. 33) may include a base resistor 2813, base FETs 2811, 2828, a discharging FET 2863, a charging FET 2864, and a sensing resistor 2830. The electronic device 1900 (e.g., controller 2740) may control the base FETs 2811, 2828 of the protection circuit (e.g., 2912, 2922, 2932 in FIG. 29, 3113, 3123, 3133 in FIG. 31, or 3312, 3322, 3332 in FIG. 33) to block power provided to the battery 2840 or power provided from the battery 2840. The electronic device 1900 (e.g., controller 2740) may also control the discharging FET 2863 or the charging FET 2864 of the protection circuit (e.g., 2912, 2922, 2932 in FIG. 29, 3113, 3123, 3133 in FIG. 31, or 3312, 3322, 3332 in FIG. 33) to block power provided to the battery 2840 or power provided from the battery 2840. The electronic device 1900 (e.g., controller 2740) may control the discharging FET 2863 or the charging FET 2864 of the protection circuit (e.g., 2912, 2922, 2932 in FIG. 29, 3113, 3123, 3133 in FIG. 31, or 3312, 3322, 3332 in FIG. 33) to control (e.g., increase or decrease) the current (e.g., charging current) provided to the battery 2840 or the current (e.g., discharging current) provided from the battery 2840.

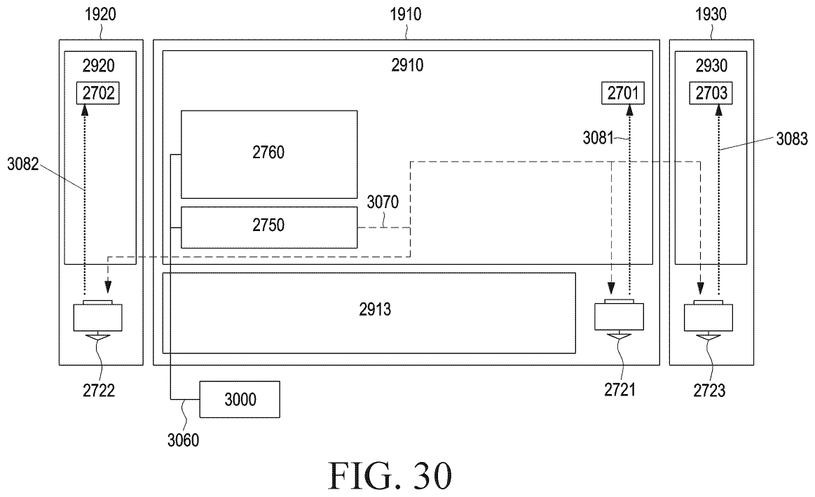

FIG. 29 is a block diagram illustrating a first charging circuit and a direct path disposed in the first housing of an electronic device, according to an embodiment of the disclosure. FIG. 30 is a diagram illustrating a charging path and a discharging path of an electronic device, according to an embodiment of the disclosure. FIGS. 29 and 30 may be described with reference to the previously described embodiments.

The electronic device 1900 in FIG. 29 and FIG. 30 may be the G-type electronic device 1900 in FIGS. 19 to 23.

Referring to FIGS. 29 and 30, a direct path (e.g., 2981, 2982, 2983) of the electronic device 1900 according to various embodiments may be described. The direct path (e.g., 2981, 2982, 2983) is a path through which power is provided from a battery (e.g., 2721, 2722, 2723) to a load (e.g., 2701, 2702, 2703), and may be a path disposed in the same housing (e.g., 1910, 1920, 1930) where the battery (e.g., 2721, 2722, 2723) and the load (e.g., 2701, 2702, 2703) are located.

Referring to FIGS. 29 and 30, according to various embodiments, the electronic device 1900 may include a first housing 1910 including a power management circuit 2760, a first charging circuit 2750, a first battery 2721, a first protection circuit 2912, and a first load 2701. The power management circuit 2760, the first charging circuit 2750, and the first load 2701 may be disposed on the first substrate 2910 of the first housing 1910. The electronic device 1900 may include a second housing 1920 including a second battery 2722, a second protection circuit 2922, and a second load 2702. The second load 2702 may be disposed on the second substrate 2920 of the second housing 1920. The electronic device 1900 may include a third housing 1930 including a third battery 2723, a third protection circuit 2932, and a third load 2703. The third load 2703 may be disposed on the third substrate 2930 of the third housing 1930.

Referring to FIGS. 29 and 28, according to various embodiments, the first protection circuit 2912 may include a base resistor (e.g., 2813 in FIG. 28) and base FETs (e.g., a charging FET (e.g., 2811 in FIG. 28) and a discharging FET (e.g., 2828 in FIG. 28)). The second protection circuit 2922 may include a base resistor (e.g., 2813 in FIG. 28) and base FETs (e.g., a charging FET (e.g., 2811 in FIG. 28) and a discharging FET (e.g., 2828 in FIG. 28)). The third protection circuit 2932 may include a base resistor (e.g., 2813 in FIG. 28) and base FETs (e.g., a charging FET (e.g., 2811 in FIG. 28) and a discharging FET (e.g., 2828 in FIG. 28)). The electronic device 1900 (e.g., controller 2740) may use the protection circuit (e.g., 2912, 2922, 2932) to block the overcharging, over-discharging, and overcurrent of the battery (e.g., 2721, 2722, 2723), based on power provided to the battery (e.g., 2721, 2722, 2723) or power provided from the battery (e.g., 2721, 2722, 2723). The electronic device 1900 may control the base FETs (e.g., the charging FET (e.g., 2811 in FIG. 28) and the discharging FET (e.g., 2828 in FIG. 28)) of the protection circuit (e.g., 2912, 2922, 2932) to block power provided to the battery (e.g., 2721, 2722, 2723) or power provided from the battery (e.g., 2721, 2722, 2723), based on the sensing value of the base resistor (e.g., 2813 in FIG. 28) of the protection circuit (e.g., 2912, 2922, 2932).

Referring to FIGS. 29, 27, and 28, according to various embodiments, the first protection circuit 2912 may include a first sensing resistor 2731 (e.g., 2830 in FIG. 28). The second protection circuit 2922 may include a second sensing resistor 2732 (e.g., 2830 in FIG. 28). The third protection circuit 2932 may include a third sensing resistor 2733 (e.g., 2830 in FIG. 28). The first protection circuit 2912 may include a first FET 2711 (e.g., the discharging FET 2863 in FIG. 28) electrically connected to the first battery 2721. The second protection circuit 2922 may include a second FET 2712 (e.g., the discharging FET 2863 in FIG. 28) electrically connected to the second battery 2722. The third protection circuit 2932 may include a third FET 2713 (e.g., the discharging FET 2863 in FIG. 28) electrically connected to the third battery 2723. The first protection circuit 2912 may include a fourth FET 2714 (e.g., the charging FET 2864 in FIG. 28) electrically connected to the first battery 2721. The second protection circuit 2922 may include a fifth FET 2715 (e.g., the charging FET 2864 in FIG. 28) electrically connected to the second battery 2722. The third protection circuit 2932 may include a sixth FET 2716 (e.g., the charging FET 2864 in FIG. 28) electrically connected to the third battery 2723.

Referring to FIGS. 29 and 30, according to various embodiment, the electronic device 1900 may receive power from an external power source 3000 (e.g., a wired charging device or a wireless charging device). For example, the electronic device 1900 may receive power from the external power source 3000 through a terminal (e.g., a USB terminal). The electronic device 1900 may include an FPCB 2971 that electrically connects the terminal (e.g., a USB terminal disposed on the USB substrate 2913) of the first housing 1910 with the power management circuit 2760 and/or the first charging circuit 2750 of the first substrate 2910. The FPCB 2971 may be part of a power reception path 3060. The electronic device 1900 may provide charging power to the first battery 2721, the second battery 2722, and/or the third battery 2723 through the first charging circuit 2750, based on power provided from the external power source 3000.

Referring to FIGS. 27, 28, 29, and 30, according to various embodiments, the electronic device 1900 may include a first connector 2911 (e.g., a battery connector) that electrically connects the components disposed on the first substrate 2910 of the first housing 1910 with the first battery 2721. The first connector 2911 may be electrically connected to the first protection circuit 2912. Power provided from the first charging circuit 2750 may be provided to the first battery 2721 through the first connector 2911 and the first protection circuit 2912. Power provided from the first charging circuit 2750 may be provided to the first battery 2721 through the first FET 2711 and the fourth FET 2714 of the first protection circuit 2912. The electronic device 1900 (e.g., controller 2740) may control the fourth FET 2714 to provide power (e.g., charging power) from the first charging circuit 2750 to the first battery 2721 through a charging path 3070. While power is provided from the first charging circuit 2750 to the first battery 2721, the electronic device 1900 may control the fourth FET 2714 (e.g., the charging FET 2864 in FIG. 28), based on the sensing value (e.g., current value or voltage value) of the first sensing resistor 2731 (e.g., 2830 in FIG. 28) of the first protection circuit 2912. The electronic device 1900 may control the gate voltage provided to the fourth FET 2714 (e.g., the charging FET 2864 in FIG. 28), based on the sensing value (e.g., current value or voltage value) of the first sensing resistor 2731 (e.g., 2830 in FIG. 28). For example, while power is provided from the first charging circuit 2750 to the first battery 2721, the electronic device 1900 may lower the gate voltage provided to the fourth FET 2714 (e.g., the charging FET 2864 in FIG. 28), based on the current (e.g., charging current) of the first sensing resistor 2731 (e.g., 2830 in FIG. 28) being greater than a reference current. While power is provided from the first charging circuit 2750 to the first battery 2721, the electronic device 1900 may control the first FET 2711 to operate as a bypass.

Referring to FIGS. 27, 28, 29, and 30, according to various embodiments, the electronic device 1900 may include a second connector 2921 (e.g., a battery connector) that electrically connects the components disposed on the second substrate 2920 of the second housing 1920 with the second battery 2722. The second connector 2921 may be electrically connected to the second protection circuit 2922. The electronic device 1900 may include a first FPCB 2991 that electrically connects the components of the first substrate 2910 of the first housing 1910 with the components of the second substrate 2920 of the second housing 1920. The first FPCB 2991 may be part of a charging path 3070. Power provided from the first charging circuit 2750 of the first housing 1910 may be provided to the second battery 2722 through the first FPCB 2991, the second connector 2921, and the second protection circuit 2922. Power provided from the first charging circuit 2750 may be provided to the second battery 2722 through the second FET 2712 and the fifth FET 2715 of the second protection circuit 2922. The electronic device 1900 (e.g., controller 2740) may control the fifth FET 2715 to provide power (e.g., charging power) from the first charging circuit 2750 to the second battery 2722 through the charging path 3070. While power is provided from the first charging circuit 2750 to the second battery 2722, the electronic device 1900 may control the fifth FET 2715 (e.g., the charging FET 2864 in FIG. 28), based on the sensing value (e.g., current value or voltage value) of the second sensing resistor 2732 (e.g., 2830 in FIG. 28) of the second protection circuit 2922. The electronic device 1900 may control the gate voltage provided to the fifth FET 2715 (e.g., the charging FET 2864 in FIG. 28), based on the sensing value (e.g., current value or voltage value) of the second sensing resistor 2732 (e.g., 2830 in FIG. 28). For example, while power is provided from the first charging circuit 2750 to the second battery 2722, the electronic device 1900 may lower the gate voltage provided to the fifth FET 2715 (e.g., the charging FET 2864 in FIG. 28), based on the current (e.g., charging current) of the second sensing resistor 2732 (e.g., 2830 in FIG. 28) being greater than a reference current. While power is provided from the first charging circuit 2750 to the second battery 2722, the electronic device 1900 may control the second FET 2712 to operate as a bypass.

Referring to FIGS. 27, 28, 29, and 30, according to various embodiments, the electronic device 1900 may include a third connector 2931 (e.g., a battery connector) that electrically connects the components disposed on the third substrate 2930 of the third housing 1930 with the third battery 2723. The third connector 2931 may be electrically connected to the third protection circuit 2932. The electronic device 1900 may include a second FPCB 2992 that electrically connects the components of the first substrate 2910 of the first housing 1910 with the components of the third substrate 2930 of the third housing 1930. The second FPCB 2992 may be part of a charging path 3070. Power provided from the first charging circuit 2750 of the first housing 1910 may be provided to the third battery 2723 through the second FPCB 2992, the third connector 2931, and the third protection circuit 2932. Power provided from the first charging circuit 2750 may be provided to the third battery 2723 through the third FET 2713 and the sixth FET 2716 of the third protection circuit 2932. The electronic device 1900 (e.g., controller 2740) may control the sixth FET 2716 to provide power (e.g., charging power) from the first charging circuit 2750 to the third battery 2723 through the charging path 3070. While power is provided from the first charging circuit 2750 to the third battery 2723, the electronic device 1900 may control the sixth FET 2716 (e.g., the charging FET 2864 in FIG. 28), based on the sensing value (e.g., current value or voltage value) of the third sensing resistor 2733 (e.g., 2830 in FIG. 28) of the third protection circuit 2932. The electronic device 1900 may control the gate voltage provided to the sixth FET 2716 (e.g., the charging FET 2864 in FIG. 28), based on the sensing value (e.g., current value or voltage value) of the third sensing resistor 2733 (e.g., 2830 in FIG. 28). For example, while power is provided from the first charging circuit 2750 to the third battery 2723, the electronic device 1900 may lower the gate voltage provided to the sixth FET 2716 (e.g., the charging FET 2864 in FIG. 28), based on the current (e.g., charging current) of the third sensing resistor 2733 (e.g., 2830 in FIG. 28) being greater than a reference current. While power is provided from the first charging circuit 2750 to the third battery 2723, the electronic device 1900 may control the third FET 2713 to operate as a bypass.

Referring to FIGS. 27, 28, 29, and 30, according to various embodiments, the electronic device 1900 may include a first wire 2981 that electrically connects the first load 2701 and the first connector 2911 of the first housing 1910. The first wire 2981 may be disposed in the first housing 1910. The first wire 2981 may be part of a first discharging path 3081. Power provided from the first battery 2721 may be provided to the first load 2701 through the first protection circuit 2912, the first connector 2911, and the first wire 2981. Power provided from the first battery 2721 may be provided to the first load 2701 through the first FET 2711 and the fourth FET 2714. The electronic device 1900 (e.g., controller 2740) may control the first FET 2711 (e.g., the discharging FET 2863 in FIG. 28) to provide power (e.g., discharge power) from the first battery 2721 to the first load 2701 through the first discharging path 3081. While power is provided from the first battery 2721 to the first load 2701, the electronic device 1900 may control the first FET 2711 (e.g., the discharging FET 2863 in FIG. 28), based on the sensing value (e.g., current value or voltage value) of the first sensing resistor 2731 (e.g., 2830 in FIG. 28) of the first protection circuit 2912. The electronic device 1900 may control the gate voltage provided to the first FET 2711 (e.g., the discharging FET 2863 in FIG. 28), based on the sensing value (e.g., current value or voltage value) of the first sensing resistor 2731 (e.g., 2830 in FIG. 28). For example, while power is provided from the first battery 2721 to the first load 2701, the electronic device 1900 may lower the gate voltage provided to the first FET 2711 (e.g., the discharging FET 2863 in FIG. 28), based on the current (e.g., discharging current) of the first sensing resistor 2731 (e.g., 2830 in FIG. 28) being greater than a reference current. While power is provided from the first battery 2721 to the first load 2701, the electronic device 1900 may control the fourth FET 2714 to operate as a bypass.

Referring to FIGS. 27, 28, 29, and 30, according to various embodiments, the electronic device 1900 may include a second wire 2982 that electrically connects the second load 2702 and the second connector 2921 of the second housing 1920. The second wire 2982 may be disposed in the second housing 1920. The second wire 2982 may be part of a second discharging path 3082. Power provided from the second battery 2722 may be provided to the second load 2702 through the second protection circuit 2922, the second connector 2921, and the second wire 2982. Power provided from the second battery 2722 may be provided to the second load 2702 through the second FET 2712 and the fifth FET 2715. The electronic device 1900 (e.g., controller 2740) may control the second FET 2712 (e.g., the discharging FET 2863 in FIG. 28) to provide power (e.g., discharge power) from the second battery 2722 to the second load 2702 through the second discharging path 3082. While power is provided from the second battery 2722 to the second load 2702, the electronic device 1900 may control the second FET 2712 (e.g., the discharging FET 2863 in FIG. 28), based on the sensing value (e.g., current value or voltage value) of the second sensing resistor 2732 (e.g., 2830 in FIG. 28) of the second protection circuit 2922. The electronic device 1900 may control the gate voltage provided to the second FET 2712 (e.g., the discharging FET 2863 in FIG. 28), based on the sensing value (e.g., current value or voltage value) of the second sensing resistor 2732 (e.g., 2830 in FIG. 28). For example, while power is provided from the second battery 2722 to the second load 2702, the electronic device 1900 may lower the gate voltage provided to the second FET 2712 (e.g., the discharging FET 2863 in FIG. 28), based on the current (e.g., discharging current) of the second sensing resistor 2732 (e.g., 2830 in FIG. 28) being greater than a reference current. While power is provided from the second battery 2722 to the second load 2702, the electronic device 1900 may control the fifth FET 2715 to operate as a bypass.

Referring to FIGS. 27, 28, 29, and 30, according to various embodiments, the electronic device 1900 may include a third wire 2983 that electrically connects the third load 2703 and the third connector 2931 of the third housing 1930. The third wire 2983 may be disposed in the third housing 1930. The third wire 2983 may be part of a third discharging path 3083. Power provided from the third battery 2723 may be provided to the third load 2703 through the third protection circuit 2932, the third connector 2931, and the third wire 2983. Power provided from the third battery 2723 may be provided to the third load 2703 through the third FET 2713 and the sixth FET 2716. The electronic device 1900 (e.g., controller 2740) may control the third FET 2713 (e.g., the discharging FET 2863 in FIG. 28) to provide power (e.g., discharge power) from the third battery 2723 to the third load 2703 through the third discharging path 3083. While power is provided from the third battery 2723 to the third load 2703, the electronic device 1900 may control the third FET 2713 (e.g., the discharging FET 2863 in FIG. 28), based on the sensing value (e.g., current value or voltage value) of the third sensing resistor 2733 (e.g., 2830 in FIG. 28) of the third protection circuit 2932. The electronic device 1900 may control the gate voltage provided to the third FET 2713 (e.g., discharging FET 2863 in FIG. 28), based on the sensing value (e.g., current value or voltage value) of the third sensing resistor 2733 (e.g., 2830 in FIG. 28). For example, while power is provided from the third battery 2723 to the third load 2703, the electronic device 1900 may lower the gate voltage provided to the third FET 2713 (e.g., the discharging FET 2863 in FIG. 28), based on the current (e.g., discharging current) of the third sensing resistor 2733 (e.g., 2830 in FIG. 28) being greater than a reference current. While power is provided from the third battery 2723 to the third load 2703, the electronic device 1900 may control the sixth FET 2716 to operate as a bypass.

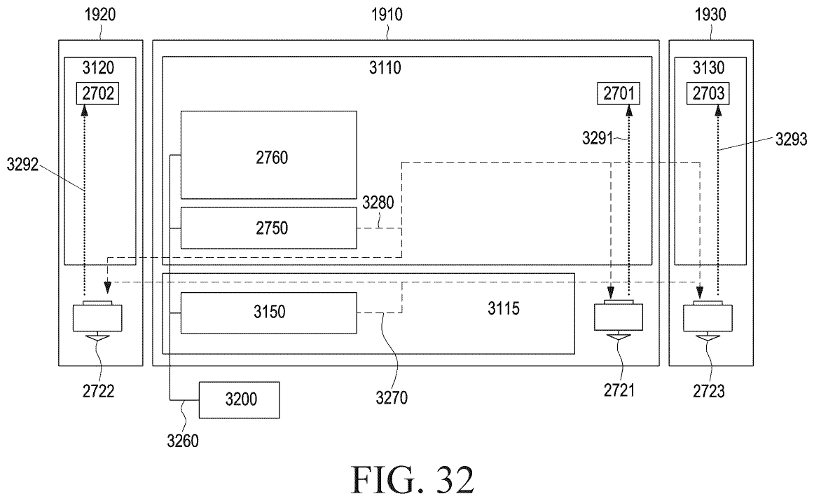

FIG. 31 is a block diagram illustrating a second charging circuit and a direct path disposed in the first housing of an electronic device, according to an embodiment of the disclosure. FIG. 32 is a diagram illustrating a charging path and a discharging path of an electronic device, according to an embodiment of the disclosure. FIGS. 31 and 32 may be described with reference to the previously described embodiments.

The electronic device 1900 in FIGS. 31 and 32 may be the G-type electronic device 1900 in FIGS. 19 to 23.

Referring to FIGS. 31 and 32, a direct path (e.g., 3181, 3182, 3183) of the electronic device 1900 according to various embodiments may be described.

Referring to FIGS. 31 and 32, according to various embodiments, the electronic device 1900 may include a first housing 1910 including a power management circuit 2760, a first charging circuit 2750, a second charging circuit 3150, a first battery 2721, a first protection circuit 3113, and a first load 2701. The power management circuit 2760, the first charging circuit 2750, and the first load 2701 may be disposed on the first substrate 3110 of the first housing 1910. The electronic device 1900 may include a second housing 1920 including a second battery 2722, a second protection circuit 3123, and a second load 2702. The second load 2702 may be disposed on the second substrate 3120 of the second housing 1920. The electronic device 1900 may include a third housing 1930 including a third battery 2723, a third protection circuit 3133, and a third load 2703. The third load 2703 may be disposed on the third substrate 3130 of the third housing 1930. The second charging circuit 3150 may be disposed on the fourth substrate 3115 (e.g., USB substrate) of the first housing 1910.

Referring to FIGS. 31 and 28, according to various embodiments, the first protection circuit 3113 may include a base resistor (e.g., 2813 in FIG. 28) and base FETs (e.g., a charging FET (e.g., 2811 in FIG. 28) and a discharging FET (e.g., 2828 in FIG. 28)). The second protection circuit 3123 may include a base resistor (e.g., 2813 in FIG. 28) and base FETs (e.g., a charging FET (e.g., 2811 in FIG. 28) and a discharging FET (e.g., 2828 in FIG. 28)). The third protection circuit 3133 may include a base resistor (e.g., 2813 in FIG. 28) and base FETs (e.g., a charging FET (e.g., 2811 in FIG. 28) and a discharging FET (e.g., 2828 in FIG. 28)). The electronic device 1900 (e.g., controller 2740) may use the protection circuit (e.g., 3113, 3123, 3133) to block the overcharging, over-discharging, and overcurrent of the battery (e.g., 2721, 2722, 2723), based on power provided to the battery (e.g., 2721, 2722, 2723) or power provided from the battery (e.g., 2721, 2722, 2723). The electronic device 1900 may control the base FETs (e.g., the charging FET (e.g., 2811 in FIG. 28) and the discharging FET (e.g., 2828 in FIG. 28)) of the protection circuit (e.g., 3113, 3123, 3133) to block power provided to the battery (e.g., 2721, 2722, 2723) or power provided from the battery (e.g., 2721, 2722, 2723), based on the sensing value of the base resistor (e.g., 2813 in FIG. 28) of the protection circuit (e.g., 3113, 3123, 3133).

Referring to FIGS. 31, 27, and 28, according to various embodiments, the first protection circuit 3113 may include a first sensing resistor 2731 (e.g., 2830 in FIG. 28). The second protection circuit 3123 may include a second sensing resistor 2732 (e.g., 2830 in FIG. 28). The third protection circuit 3133 may include a third sensing resistor 2733 (e.g., 2830 in FIG. 28). The first protection circuit 3113 may include a first FET 2711 (e.g., the discharging FET 2863 in FIG. 28) electrically connected to the first battery 2721. The second protection circuit 3123 may include a second FET 2712 (e.g., the discharging FET 2863 in FIG. 28) electrically connected to the second battery 2722. The third protection circuit 3133 may include a third FET 2713 (e.g., the discharging FET 2863 in FIG. 28) electrically connected to the third battery 2723. The first protection circuit 3113 may include a fourth FET 2714 (e.g., the charging FET 2864 in FIG. 28) electrically connected to the first battery 2721. The second protection circuit 3123 may include a fifth FET 2715 (e.g., the charging FET 2864 in FIG. 28) electrically connected to the second battery 2722. The third protection circuit 3133 may include a sixth FET 2716 (e.g., the charging FET 2864 in FIG. 28) electrically connected to the third battery 2723.

Referring to FIGS. 31 and 32, according to various embodiments, the electronic device 1900 may receive power from an external power source 3200 (e.g., a wired charging device or a wireless charging device). For example, the electronic device 1900 may receive power from the external power source 3200 through a terminal (e.g., a USB terminal). The electronic device 1900 may include an FPCB 3171 that electrically connects the terminal (e.g., USB terminal) of the first housing 1910 with the power management circuit 2760 and/or the first charging circuit 2750 of the first substrate 2910. The FPCB 3171 may be part of a power reception path 3260. The electronic device 1900 may provide charging power to the first battery 2721, the second battery 2722, and/or the third battery 2723 through the first charging circuit 2750, based on power provided from the external power source 3200.

Referring to FIGS. 27, 28, 31, and 32, according to various embodiments, the electronic device 1900 may include a first connector 3111 (e.g., a battery connector) that electrically connects the components disposed on the first substrate 3110 of the first housing 1910 with the first battery 2721. The first connector 3111 may be electrically connected to the first protection circuit 3113. Power provided from the first charging circuit 2750 may be provided to the first battery 2721 through the first connector 3111 and the first protection circuit 3113. Power provided from the first charging circuit 2750 may be provided to the first battery 2721 through the first FET 2711 and the fourth FET 2714 of the first protection circuit 3113. The electronic device 1900 (e.g., controller 2740) may control the fourth FET 2714 to provide power (e.g., charging power) from the first charging circuit 2750 to the first battery 2721 through a charging path 3280. While power is provided from the first charging circuit 2750 to the first battery 2721, the electronic device 1900 may control the fourth FET 2714 (e.g., the charging FET 2864 in FIG. 28), based on the sensing value (e.g., current value or voltage value) of the first sensing resistor 2731 (e.g., 2830 in FIG. 28) of the first protection circuit 2912. The electronic device 1900 may control the gate voltage provided to the fourth FET 2714 (e.g., the charging FET 2864 in FIG. 28), based on the sensing value (e.g., current value or voltage value) of the first sensing resistor 2731 (e.g., 2830 in FIG. 28). For example, while power is provided from the first charging circuit 2750 to the first battery 2721, the electronic device 1900 may lower the gate voltage provided to the fourth FET 2714 (e.g., the charging FET 2864 in FIG. 28), based on the current (e.g., charging current) of the first sensing resistor 2731 (e.g., 2830 in FIG. 28) being greater than a reference current. While power is provided from the first charging circuit 2750 to the first battery 2721, the electronic device 1900 may control the first FET 2711 to operate as a bypass.

Referring to FIGS. 27, 28, 31, and 32, according to various embodiments, power received from an external power source 3200 (e.g., a wired charging device or a wireless charging device) may be provided to the second charging circuit 3150 through the wire of the fourth substrate 3115 (e.g., USB substrate). The electronic device 1900 may provide power (e.g., charging power) to the first battery 2721, the second battery 2722, and/or the third battery 2723 through the second charging circuit 3150, based on power received from an external power source 3200 (e.g., a wired charging device or a wireless charging device).

Referring to FIGS. 27, 28, 31, and 32, according to various embodiments, the electronic device 1900 may include a second connector 3112 (e.g., a battery connector) that electrically connects the components disposed on the fourth substrate 3115 of the first housing 1910 with the first battery 2721. The second connector 3112 may be electrically connected to the first protection circuit 3113. Power provided from the second charging circuit 3150 may be provided to the first battery 2721 in path 3161 through the second connector 3112 and the first protection circuit 3113. Power provided from the second charging circuit 3150 may be provided to the first battery 2721 through the first FET 2711 and the fourth FET 2714 of the first protection circuit 3113. The electronic device 1900 (e.g., controller 2740) may control the fourth FET 2714 to provide power (e.g., charging power) from the second charging circuit 3150 to the first battery 2721 through a charging path 3270. While power is provided from the second charging circuit 3150 to the first battery 2721, the electronic device 1900 may control the fourth FET 2714 (e.g., the charging FET 2864 in FIG. 28), based on the sensing value (e.g., current value or voltage value) of the first sensing resistor 2731 (e.g., 2830 in FIG. 28) of the first protection circuit 2912. The electronic device 1900 may control the gate voltage provided to the fourth FET 2714 (e.g., the charging FET 2864 in FIG. 28), based on the sensing value (e.g., current value or voltage value) of the first sensing resistor 2731 (e.g., 2830 in FIG. 28). For example, while power is provided from the second charging circuit 3150 to the first battery 2721, the electronic device 1900 may lower the gate voltage provided to the fourth FET 2714 (e.g., the charging FET 2864 in FIG. 28), based on the current (e.g., charging current) of the first sensing resistor 2731 (e.g., 2830 in FIG. 28) being greater than a reference current. While power is provided from the twenty-second charging circuit 3150 to the first battery 2721, the electronic device 1900 may control the first FET 2711 to operate as a bypass.

Referring to FIGS. 29 and 31, according to various embodiments, in the case of FIG. 29, the first protection circuit 2912 of the first housing 1910 may be mounted adjacent to the first substrate 2910. In the case of FIG. 31, the first protection circuit 3113 of the first housing 1910 may be mounted adjacent to the first substrate 3110 and the fourth substrate 3115. The first protection circuit 3113 in FIG. 31 may have a bidirectional structure in which the same is connected to the first connector 3111 and the second connector 3112. The first protection circuit 3113 in FIG. 31 may be electrically connected to the components of the first substrate 3110 through the first connector 3111 and may be electrically connected to the components of the fourth substrate 3115 through the second connector 3112.

Referring to FIGS. 27, 28, 31, and 32, according to various embodiments, the electronic device 1900 may include a third connector 3121 (e.g., a battery connector) that electrically connects the components disposed on the second substrate 3120 of the second housing 1920 with the second battery 2722. The third connector 3121 may be electrically connected to the second protection circuit 3123. The electronic device 1900 may include a first FPCB 3191 that electrically connects the components of the first substrate 3110 of the first housing 1910 with the components of the second substrate 3120 of the second housing 1920. The first FPCB 3191 may be part of a charging path 3280. Power provided from the first charging circuit 2750 of the first housing 1910 may be provided to the second battery 2722 through the first FPCB 3191, the third connector 3121, and the second protection circuit 3123. Power provided from the first charging circuit 2750 may be provided to the second battery 2722 through the second FET 2712 and the fifth FET 2715 of the second protection circuit 3123. The electronic device 1900 (e.g., controller 2740) may control the fifth FET 2715 to provide power (e.g., charging power) from the first charging circuit 2750 to the second battery 2722 through the charging path 3280. While power is provided from the first charging circuit 2750 to the second battery 2722, the electronic device 1900 may control the fifth FET 2715 (e.g., the charging FET 2864 in FIG. 28), based on the sensing value (e.g., current value or voltage value) of the second sensing resistor 2732 (e.g., 2830 in FIG. 28) of the second protection circuit 3123. The electronic device 1900 may control the gate voltage provided to the fifth FET 2715 (e.g., the charging FET 2864 in FIG. 28), based on the sensing value (e.g., current value or voltage value) of the second sensing resistor 2732 (e.g., 2830 in FIG. 28). For example, while power is provided from the first charging circuit 2750 to the second battery 2722, the electronic device 1900 may lower the gate voltage provided to the fifth FET 2715 (e.g., the charging FET 2864 in FIG. 28), based on the current (e.g., charging current) of the second sensing resistor 2732 (e.g., 2830 in FIG. 28) being greater than a reference current. While power is provided from the first charging circuit 2750 to the second battery 2722, the electronic device 1900 may control the second FET 2712 to operate as a bypass.

Referring to FIGS. 27, 28, 31, and 32, according to various embodiments, the electronic device 1900 may include a fourth connector 3122 (e.g., a battery connector) electrically connected to the second battery 2722. The fourth connector 3122 may be electrically connected to the second protection circuit 3123. The second protection circuit 3123 in FIG. 31 may have a bidirectional structure in which the same is connected to the third connector 3121 and the fourth connector 3122. The electronic device 1900 may include a second FPCB 3162 that electrically connects the components of the fourth substrate 3115 of the first housing 1910 with the components of the second housing 1920. The second FPCB 3162 may be part of a charging path 3270. Power provided from the second charging circuit 3150 of the first housing 1910 may be provided to the second battery 2722 through the second FPCB 3162, the fourth connector 3122, and the second protection circuit 3123. Power provided from the second charging circuit 3150 may be provided to the second battery 2722 through the second FET 2712 and the fifth FET 2715 of the second protection circuit 3123. The electronic device 1900 (e.g., controller 2740) may control the fifth FET 2715 to provide power (e.g., charging power) from the second charging circuit 3150 to the second battery 2722 through the charging path 3270. While power is provided from the second charging circuit 3150 to the second battery 2722, the electronic device 1900 may control the fifth FET 2715 (e.g., the charging FET 2864 in FIG. 28), based on the sensing value (e.g., current value or voltage value) of the second sensing resistor 2732 (e.g., 2830 in FIG. 28) of the second protection circuit 3123. The electronic device 1900 may control the gate voltage provided to the fifth FET 2715 (e.g., the charging FET 2864 in FIG. 28), based on the sensing value (e.g., current value or voltage value) of the second sensing resistor 2732 (e.g., 2830 in FIG. 28). For example, while power is provided from the first charging circuit 2750 to the second battery 2722, the electronic device 1900 may lower the gate voltage provided to the fifth FET 2715 (e.g., the charging FET 2864 in FIG. 28), based on the current (e.g., charging current) of the second sensing resistor 2732 (e.g., 2830 in FIG. 28) being greater than a reference current. While power is provided from the first charging circuit 2750 to the second battery 2722, the electronic device 1900 may control the second FET 2712 to operate as a bypass.

Referring to FIGS. 27, 28, 31, and 32, according to various embodiments, the electronic device 1900 may include a fifth connector 3131 (e.g., a battery connector) that electrically connects the components disposed on the third substrate 3130 of the third housing 1930 with the third battery 2723. The fifth connector 3131 may be electrically connected to the third protection circuit 3133. The electronic device 1900 may include a third FPCB 3192 that electrically connects the components of the first substrate 3110 of the first housing 1910 with the components of the third substrate 3130 of the third housing 1930. The third FPCB 3192 may be part of a charging path 3280. Power provided from the first charging circuit 2750 of the first housing 1910 may be provided to the third battery 2723 through the third FPCB 3192, the fifth connector 3131, and the third protection circuit 3133. Power provided from the first charging circuit 2750 may be provided to the third battery 2723 through the third FET 2713 and the sixth FET 2716 of the third protection circuit 3133. The electronic device 1900 (e.g., controller 2740) may control the sixth FET 2716 to provide power (e.g., charging power) from the first charging circuit 2750 to the third battery 2723 through the charging path 3280. While power is provided from the first charging circuit 2750 to the third battery 2723, the electronic device 1900 may control the sixth FET 2716 (e.g., the charging FET 2864 in FIG. 28), based on the sensing value (e.g., current value or voltage value) of the third sensing resistor 2733 (e.g., 2830 in FIG. 28) of the third protection circuit 3133. The electronic device 1900 may control the gate voltage provided to the sixth FET 2716 (e.g., the charging FET 2864 in FIG. 28), based on the sensing value (e.g., current value or voltage value) of the third sensing resistor 2733 (e.g., 2830 in FIG. 28). For example, while power is provided from the first charging circuit 2750 to the third battery 2723, the electronic device 1900 may lower the gate voltage provided to the sixth FET 2716 (e.g., the charging FET 2864 in FIG. 28), based on the current (e.g., charging current) of the third sensing resistor 2733 (e.g., 2830 in FIG. 28) being greater than a reference current. While power is provided from the first charging circuit 2750 to the third battery 2723, the electronic device 1900 may control the third FET 2713 to operate as a bypass.

Referring to FIGS. 27, 28, 31, and 32, according to various embodiments, the electronic device 1900 may include a sixth connector 3132 (e.g., a battery connector) electrically connected to the third battery 2723. The sixth connector 3132 may be electrically connected to the third protection circuit 3133. The third protection circuit 3133 in FIG. 31 may have a bidirectional structure in which the same is connected to the fifth connector 3131 and the sixth connector 3132. The electronic device 1900 may include a fourth FPCB 3163 that electrically connects the components of the fourth substrate 3115 of the first housing 1910 with the components of the third housing 1930. The fourth FPCB 3163 may be part of a charging path 3270. Power provided from the second charging circuit 3150 of the first housing 1910 may be provided to the third battery 2723 through the fourth FPCB 3163, the sixth connector 3132, and the third protection circuit 3133. Power provided from the second charging circuit 3150 may be provided to the third battery 2723 through the third FET 2713 and the sixth FET 2716 of the third protection circuit 3133. The electronic device 1900 (e.g., controller 2740) may control the sixth FET 2716 to provide power (e.g., charging power) from the second charging circuit 3150 to the third battery 2723 through the charging path 3270. While power is provided from the second charging circuit 3150 to the third battery 2723, the electronic device 1900 may control the sixth FET 2716 (e.g., the charging FET 2864 in FIG. 28), based on the sensing value (e.g., current value or voltage value) of the third sensing resistor 2733 (e.g., 2830 in FIG. 28) of the third protection circuit 3133. The electronic device 1900 may control the gate voltage provided to the sixth FET 2716 (e.g., the charging FET 2864 in FIG. 28), based on the sensing value (e.g., current value or voltage value) of the third sensing resistor 2733 (e.g., 2830 in FIG. 28). For example, while power is provided from the second charging circuit 3150 to the third battery 2723, the electronic device 1900 may lower the gate voltage provided to the sixth FET 2716 (e.g., the charging FET 2864 in FIG. 28), based on the current (e.g., charging current) of the third sensing resistor 2733 (e.g., 2830 in FIG. 28) being greater than a reference current. While power is provided from the first charging circuit 2750 to the third battery 2723, the electronic device 1900 may control the third FET 2713 to operate as a bypass.

Referring to FIGS. 27, 28, 31, and 32, according to various embodiments, the electronic device 1900 may include a first wire 3181 that electrically connects the first load 2701 and the first connector 3111 of the first housing 1910. The first wire 3181 may be disposed in the first housing 1910. The first wire 3181 may be part of a first discharging path 3291. Power provided from the first battery 2721 may be provided to the first load 2701 through the first protection circuit 3113, the first connector 3111, and the first wire 3181. Power provided from the first battery 2721 may be provided to the first load 2701 through the first FET 2711 and the fourth FET 2714. The electronic device 1900 (e.g., controller 2740) may control the first FET 2711 (e.g., the discharging FET 2863 in FIG. 28) to provide power (e.g., discharge power) from the first battery 2721 to the first load 2701 through the first discharging path 3291. While power is provided from the first battery 2721 to the first load 2701, the electronic device 1900 may control the first FET 2711 (e.g., the discharging FET 2863 in FIG. 28), based on the sensing value (e.g., current value or voltage value) of the first sensing resistor 2731 (e.g., 2830 in FIG. 28) of the first protection circuit 3113. The electronic device 1900 may control the gate voltage provided to the first FET 2711 (e.g., the discharging FET 2863 in FIG. 28), based on the sensing value (e.g., current value or voltage value) of the first sensing resistor 2731 (e.g., 2830 in FIG. 28). For example, while power is provided from the first battery 2721 to the first load 2701, the electronic device 1900 may lower the gate voltage provided to the first FET 2711 (e.g., the discharging FET 2863 in FIG. 28), based on the current (e.g., discharging current) of the first sensing resistor 2731 (e.g., 2830 in FIG. 28) being greater than a reference current. While power is provided from the first battery 2721 to the first load 2701, the electronic device 1900 may control the fourth FET 2714 to operate as a bypass.

Referring to FIGS. 27, 28, 31, and 32, according to various embodiments, the electronic device 1900 may include a second wire 3182 that electrically connects the second load 2702 and the third connector 3121 of the second housing 1920. The second wire 3182 may be disposed in the second housing 1920. The second wire 3182 may be part of a second discharging path 3292. Power provided from the second battery 2722 may be provided to the second load 2702 through the second protection circuit 3123, the third connector 3121, and the second wire 3182. Power provided from the second battery 2722 may be provided to the second load 2702 through the second FET 2712 and the fifth FET 2715. The electronic device 1900 (e.g., controller 2740) may control the second FET 2712 (e.g., the discharging FET 2863 in FIG. 28) to provide power (e.g., discharge power) from the second battery 2722 to the second load 2702 through the second discharging path 3292. While power is provided from the second battery 2722 to the second load 2702, the electronic device 1900 may control the second FET 2712 (e.g., the discharging FET 2863 in FIG. 28), based on the sensing value (e.g., current value or voltage value) of the second sensing resistor 2732 (e.g., 2830 in FIG. 28) of the second protection circuit 3123. The electronic device 1900 may control the gate voltage provided to the second FET 2712 (e.g., the discharging FET 2863 in FIG. 28), based on the sensing value (e.g., current value or voltage value) of the second sensing resistor 2732 (e.g., 2830 in FIG. 28). For example, while power is provided from the second battery 2722 to the second load 2702, the electronic device 1900 may lower the gate voltage provided to the second FET 2712 (e.g., the discharging FET 2863 in FIG. 28), based on the current (e.g., discharging current) of the second sensing resistor 2732 (e.g., 2830 in FIG. 28) being greater than a reference current. While power is provided from the second battery 2722 to the second load 2702, the electronic device 1900 may control the fifth FET 2715 to operate as a bypass.

Referring to FIGS. 27, 28, 31, and 32, according to various embodiments, the electronic device 1900 may include a third wire 3183 that electrically connects the third load 2703 and the fifth connector 3131 of the third housing 1930. The third wire 3183 may be disposed in the third housing 1930. The third wire 3183 may be part of a third discharging path 3293. Power provided from the third battery 2723 may be provided to the third load 2703 through the third protection circuit 3133, the fifth connector 3131, and the third wire 3183. Power provided from the third battery 2723 may be provided to the third load 2703 through the third FET 2713 and the sixth FET 2716. The electronic device 1900 (e.g., controller 2740) may control the third FET 2713 (e.g., the discharging FET 2863 in FIG. 28) to provide power (e.g., discharge power) from the third battery 2723 to the third load 2703 through the third discharging path 3293. While power is provided from the third battery 2723 to the third load 2703, the electronic device 1900 may control the third FET 2713 (e.g., the discharging FET 2863 in FIG. 28), based on the sensing value (e.g., current value or voltage value) of the third sensing resistor 2733 (e.g., 2830 in FIG. 28) of the third protection circuit 3133. The electronic device 1900 may control the gate voltage provided to the third FET 2713 (e.g., the discharging FET 2863 in FIG. 28), based on the sensing value (e.g., current value or voltage value) of the third sensing resistor 2733 (e.g., 2830 in FIG. 28). For example, while power is provided from the third battery 2723 to the third load 2703, the electronic device 1900 may lower the gate voltage provided to the third FET 2713 (e.g., the discharging FET 2863 in FIG. 28), based on the current (e.g., discharging current) of the third sensing resistor 2733 (e.g., 2830 in FIG. 28) being greater than a reference current. While power is provided from the third battery 2723 to the third load 2703, the electronic device 1900 may control the sixth FET 2716 to operate as a bypass.

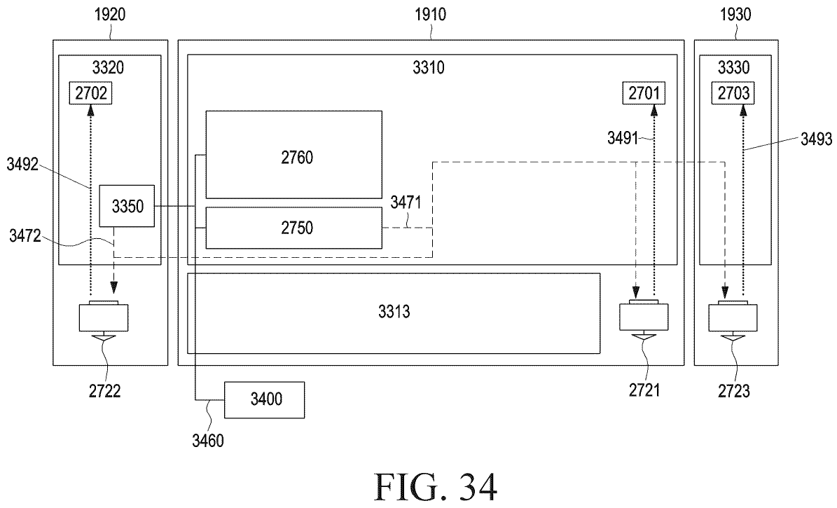

FIG. 33 is a block diagram illustrating a second charging circuit and a direct path disposed in the second housing of an electronic device, according to an embodiment of the disclosure. FIG. 34 is a diagram illustrating a charging path and a discharging path of an electronic device, according to an embodiment of the disclosure. FIG. 33 and FIG. 34 may be described with reference to the previously described embodiments.

The electronic device 1900 in FIGS. 33 and 34 may be the G-type electronic device 1900 in FIGS. 19 to 23.

Referring to FIGS. 33 and 34, a direct path (e.g., 3381, 3382, 3383) of the electronic device 1900 according to various embodiments may be described.

Referring to FIGS. 33 and 34, according to various embodiments, the electronic device 1900 may include a first housing 1910 including a power management circuit 2760, a first charging circuit 2750, a first battery 2721, a first protection circuit 3312, and a first load 2701. The power management circuit 2760, the first charging circuit 2750, and the first load 2701 may be disposed on the first substrate 3310 of the first housing 1910. The electronic device 1900 may include a second housing 1920 including a second charging circuit 3350, a second battery 2722, a second protection circuit 3322, and a second load 2702. The second charging circuit 3350 and the second load 2702 may be disposed on the second substrate 3320 of the second housing 1920. The electronic device 1900 may include a third housing 1930 including a third battery 2723, a third protection circuit 3332, and a third load 2703. The third load 2703 may be disposed on the third substrate 3330 of the third housing 1930.

Referring to FIGS. 33 and 28, according to various embodiments, the first protection circuit 3312 may include a base resistor (e.g., 2813 in FIG. 28) and base FETs (e.g., a charging FET (e.g., 2811 in FIG. 28) and a discharging FET (e.g., 2828 in FIG. 28)). The second protection circuit 3322 may include a base resistor (e.g., 2813 in FIG. 28) and base FETs (e.g., a charging FET (e.g., 2811 in FIG. 28) and a discharging FET (e.g., 2828 in FIG. 28)). The third protection circuit 3332 may include a base resistor (e.g., 2813 in FIG. 28) and base FETs (e.g., a charging FET (e.g., 2811 in FIG. 28) and a discharging FET (e.g., 2828 in FIG. 28)). The electronic device 1900 (e.g., controller 2740) may use the protection circuit (e.g., 3312, 3322, 3332) to block the overcharging, over-discharging, and overcurrent of the battery (e.g., 2721, 2722, 2723), based on power provided to the battery (e.g., 2721, 2722, 2723) or power provided from the battery (e.g., 2721, 2722, 2723). The electronic device 1900 may control the base FETs (e.g., the charging FET (e.g., 2811 in FIG. 28) and the discharging FET (e.g., 2828 in FIG. 28)) of the protection circuit (e.g., 3312, 3322, 3332) to block power provided to the battery (e.g., 2721, 2722, 2723) or power provided from the battery (e.g., 2721, 2722, 2723), based on the sensing value of the base resistor (e.g., 2813 in FIG. 28) of the protection circuit (e.g., 3312, 3322, 3332).

Referring to FIGS. 33, 27, and 28, according to various embodiment, the first protection circuit 3312 may include a first sensing resistor 2731 (e.g., 2830 in FIG. 28). The second protection circuit 3322 may include a second sensing resistor 2732 (e.g., 2830 in FIG. 28). The third protection circuit 3332 may include a third sensing resistor 2733 (e.g., 2830 in FIG. 28). The first protection circuit 3312 may include a first FET 2711 (e.g., the discharging FET 2863 in FIG. 28) electrically connected to the first battery 2721. The second protection circuit 3322 may include a second FET 2712 (e.g., the discharging FET 2863 in FIG. 28) electrically connected to the second battery 2722. The third protection circuit 3332 may include a third FET 2713 (e.g., the discharging FET 2863 in FIG. 28) electrically connected to the third battery 2723. The first protection circuit 3312 may include a fourth FET 2714 (e.g., the charging FET 2864 in FIG. 28) electrically connected to the first battery 2721. The second protection circuit 3322 may include a fifth FET 2715 (e.g., the charging FET 2864 in FIG. 28) electrically connected to the second battery 2722. The third protection circuit 3332 may include a sixth FET 2716 (e.g., the charging FET 2864 in FIG. 28) electrically connected to the third battery 2723.

Referring to FIGS. 33 and 34, according to various embodiments, the electronic device 1900 may receive power from an external power source 3400 (e.g., a wired charging device or a wireless charging device). For example, the electronic device 1900 may receive power from an external power source 3400 through a terminal (e.g., a USB terminal). The electronic device 1900 may include an FPCB 3371 that electrically connects the terminal (e.g., a USB terminal disposed on the USB substrate 3313) of the first housing 1910 with the power management circuit 2760 and/or the first charging circuit 2750 of the first substrate 3310. The FPCB 3371 may be part of a power reception path 3460. The electronic device 1900 may provide charging power to the first battery 2721, the second battery 2722, and/or the third battery 2723 through the first charging circuit 2750, based on power provided from the external power source 3400.

Referring to FIGS. 27, 28, 33, and 34, according to various embodiments, the electronic device 1900 may include a first connector 3311 (e.g., a battery connector) that electrically connects the components disposed on the first substrate 3310 of the first housing 1910 with the first battery 2721. The first connector 3311 may be electrically connected to the first protection circuit 3312. Power provided from the first charging circuit 2750 may be provided to the first battery 2721 through the first connector 3311 and the first protection circuit 3312. Power provided from the first charging circuit 2750 may be provided to the first battery 2721 through the first FET 2711 and the fourth FET 2714 of the first protection circuit 3312. The electronic device 1900 (e.g., controller 2740) may control the fourth FET 2714 to provide power (e.g., charging power) from the first charging circuit 2750 to the first battery 2721 through a charging path 3471. While power is provided from the first charging circuit 2750 to the first battery 2721, the electronic device 1900 may control the fourth FET 2714 (e.g., the charging FET 2864 in FIG. 28), based on the sensing value (e.g., current value or voltage value) of the first sensing resistor 2731 (e.g., 2830 in FIG. 28) of the first protection circuit 2912. The electronic device 1900 may control the gate voltage provided to the fourth FET 2714 (e.g., the charging FET 2864 in FIG. 28), based on the sensing value (e.g., current value or voltage value) of the first sensing resistor 2731 (e.g., 2830 in FIG. 28). For example, while power is provided from the first charging circuit 2750 to the first battery 2721, the electronic device 1900 may lower the gate voltage provided to the fourth FET 2714 (e.g., the charging FET 2864 in FIG. 28), based on the current (e.g., charging current) of the first sensing resistor 2731 (e.g., 2830 in FIG. 28) being greater than a reference current. While power is provided from the first charging circuit 2750 to the first battery 2721, the electronic device 1900 may control the first FET 2711 to operate as a bypass.

Referring to FIGS. 27, 28, 33, and 34, according to various embodiments, the electronic device 1900 may include a second connector 3321 (e.g., a battery connector) that electrically connects the components disposed on the second substrate 3320 of the second housing 1920 with the second battery 2722. The second connector 3321 may be electrically connected to the second protection circuit 3322. The electronic device 1900 may include a first FPCB 3391 that electrically connects the components of the first substrate 3310 of the first housing 1910 with the components of the second substrate 3320 of the second housing 1920. The first FPCB 3391 may be part of a charging path 3471. Power provided from the first charging circuit 2750 of the first housing 1910 may be provided to the second battery 2722 through the first FPCB 3391, the second connector 3321, and the second protection circuit 3322. Power provided from the first charging circuit 2750 may be provided to the second battery 2722 through the second FET 2712 and the fifth FET 2715 of the second protection circuit 3322. The electronic device 1900 (e.g., controller 2740) may control the fifth FET 2715 to provide power (e.g., charging power) from the first charging circuit 2750 to the second battery 2722 through the charging path 3471. While power is provided from the first charging circuit 2750 to the second battery 2722, the electronic device 1900 may control the fifth FET 2715 (e.g., the charging FET 2864 in FIG. 28), based on the sensing value (e.g., current value or voltage value) of the second sensing resistor 2732 (e.g., 2830 in FIG. 28) of the second protection circuit 3123. The electronic device 1900 may control the gate voltage provided to the fifth FET 2715 (e.g., the charging FET 2864 in FIG. 28), based on the sensing value (e.g., current value or voltage value) of the second sensing resistor 2732 (e.g., 2830 in FIG. 28). For example, while power is provided from the first charging circuit 2750 to the second battery 2722, the electronic device 1900 may lower the gate voltage provided to the fifth FET 2715 (e.g., the charging FET 2864 in FIG. 28), based on the current (e.g., charging current) of the second sensing resistor 2732 (e.g., 2830 in FIG. 28) being greater than a reference current. While power is provided from the first charging circuit 2750 to the second battery 2722, the electronic device 1900 may control the second FET 2712 to operate as a bypass.

Referring to FIGS. 27, 28, 33, and 34, according to various embodiments, the electronic device 1900 may include an FPCB 3372 that electrically connects the components of the first substrate 3310 of the first housing 1910 with the components of the second substrate 3320 of the second housing 1920. The FPCB 3372 may be part of a power reception path 3460. The second charging circuit 3350 may receive power from the external power source 3400 through the FPCB 3371 and the FPCB 3372. The electronic device 1900 may provide charging power to the second battery 2722 through the second charging circuit 3350, based on power provided from the external power source 3400. Power provided from the second charging circuit 3350 may be provided to the second battery 2722 through the second connector 3321 and the second protection circuit 3322. Power provided from the second charging circuit 3350 may be provided to the second battery 2722 through the second FET 2712 and the fifth FET 2715 of the second protection circuit 3322. The electronic device 1900 (e.g., controller 2740) may control the fifth FET 2715 to provide power (e.g., charging power) from the second charging circuit 3350 to the second battery 2722 through the charging path 3472. While power is provided from the second charging circuit 3350 to the second battery 2722, the electronic device 1900 may control the fifth FET 2715 (e.g., the charging FET 2864 in FIG. 28), based on the sensing value (e.g., current value or voltage value) of the second sensing resistor 2732 (e.g., 2830 in FIG. 28) of the second protection circuit 3322. The electronic device 1900 may control the gate voltage provided to the fifth FET 2715 (e.g., the charging FET 2864 in FIG. 28), based on the sensing value (e.g., current value or voltage value) of the second sensing resistor 2732 (e.g., 2830 in FIG. 28). For example, while power is provided from the second charging circuit 3350 to the second battery 2722, the electronic device 1900 may lower the gate voltage provided to the fifth FET 2715 (e.g., the charging FET 2864 in FIG. 28), based on the current (e.g., charging current) of the second sensing resistor 2732 (e.g., 2830 in FIG. 28) being greater than a reference current. While power is provided from the second charging circuit 3350 to the second battery 2722, the electronic device 1900 may control the second FET 2712 to operate as a bypass.

Referring to FIGS. 27, 28, 33, and 34, according to various embodiments, the electronic device 1900 may include a third connector 3331 (e.g., a battery connector) that electrically connects the components disposed on the third substrate 3330 of the third housing 1930 with the third battery 2723. The third connector 3331 may be electrically connected to the third protection circuit 3332. The electronic device 1900 may include a second FPCB 3392 that electrically connects the components of the first substrate 3310 of the first housing 1910 with the components of the third substrate 3330 of the third housing 1930. The second FPCB 3392 may be part of a charging path 3471. Power provided from the first charging circuit 2750 of the first housing 1910 may be provided to the third battery 2723 through the second FPCB 3392, the third connector 3331, and the third protection circuit 3332. Power provided from the first charging circuit 2750 may be provided to the third battery 2723 through the third FET 2713 and the sixth FET 2716 of the third protection circuit 3332. The electronic device 1900 (e.g., controller 2740) may control the sixth FET 2716 to provide power (e.g., charging power) from the first charging circuit 2750 to the third battery 2723 through the charging path 3471. While power is provided from the first charging circuit 2750 to the third battery 2723, the electronic device 1900 may control the sixth FET 2716 (e.g., the charging FET 2864 in FIG. 28), based on the sensing value (e.g., current value or voltage value) of the third sensing resistor 2733 (e.g., 2830 in FIG. 28) of the third protection circuit 3332. The electronic device 1900 may control the gate voltage provided to the sixth FET 2716 (e.g., the charging FET 2864 in FIG. 28), based on the sensing value (e.g., current value or voltage value) of the third sensing resistor 2733 (e.g., 2830 in FIG. 28). For example, while power is provided from the first charging circuit 2750 to the third battery 2723, the electronic device 1900 may lower the gate voltage provided to the sixth FET 2716 (e.g., the charging FET 2864 in FIG. 28), based on the current (e.g., charging current) of the third sensing resistor 2733 (e.g., 2830 in FIG. 28) being greater than a reference current. While power is provided from the first charging circuit 2750 to the third battery 2723, the electronic device 1900 may control the third FET 2713 to operate as a bypass.

Referring to FIGS. 27, 28, 33, and 34, according to various embodiments, the electronic device 1900 may include a first wire 3381 that electrically connects the first load 2701 and the first connector 3311 of the first housing 1910. The first wire 3381 may be disposed in the first housing 1910. The first wire 3381 may be part of a first discharging path 3491. Power provided from the first battery 2721 may be provided to the first load 2701 through the first protection circuit 3312, the first connector 3311, and the first wire 3381. Power provided from the first battery 2721 may be provided to the first load 2701 through the first FET 2711 and the fourth FET 2714. The electronic device 1900 (e.g., controller 2740) may control the first FET 2711 (e.g., the discharging FET 2863 in FIG. 28) to provide power (e.g., discharge power) from the first battery 2721 to the first load 2701 through the first discharging path 3491. While power is provided from the first battery 2721 to the first load 2701, the electronic device 1900 may control the first FET 2711 (e.g., the discharging FET 2863 in FIG. 28), based on the sensing value (e.g., current value or voltage value) of the first sensing resistor 2731 (e.g., 2830 in FIG. 28) of the first protection circuit 3312. The electronic device 1900 may control the gate voltage provided to the first FET 2711 (e.g., the discharging FET 2863 in FIG. 28), based on the sensing value (e.g., current value or voltage value) of the first sensing resistor 2731 (e.g., 2830 in FIG. 28). For example, while power is provided from the first battery 2721 to the first load 2701, the electronic device 1900 may lower the gate voltage provided to the first FET 2711 (e.g., the discharging FET 2863 in FIG. 28), based on the current (e.g., discharging current) of the first sensing resistor 2731 (e.g., 2830 in FIG. 28) being greater than a reference current. While power is provided from the first battery 2721 to the first load 2701, the electronic device 1900 may control the fourth FET 2714 to operate as a bypass.

Referring to FIGS. 27, 28, 33, and 34, according to various embodiments, the electronic device 1900 may include a second wire 3382 that electrically connects the second load 2702 and the second connector 3321 of the second housing 1920. The second wire 3382 may be disposed in the second housing 1920. The second wire 3382 may be part of a second discharging path 3492. Power provided from the second battery 2722 may be provided to the second load 2702 through the second protection circuit 3322, the second connector 3321, and the second wire 3382. Power provided from the second battery 2722 may be provided to the second load 2702 through the second FET 2712 and the fifth FET 2715. The electronic device 1900 (e.g., controller 2740) may control the second FET 2712 (e.g., the discharging FET 2863 in FIG. 28) to provide power (e.g., discharge power) from the second battery 2722 to the second load 2702 through the second discharging path 3492. While power is provided from the second battery 2722 to the second load 2702, the electronic device 1900 may control the second FET 2712 (e.g., the discharging FET 2863 in FIG. 28), based on the sensing value (e.g., current value or voltage value) of the second sensing resistor 2732 (e.g., 2830 in FIG. 28) of the second protection circuit 3322. The electronic device 1900 may control the gate voltage provided to the second FET 2712 (e.g., the discharging FET 2863 in FIG. 28), based on the sensing value (e.g., current value or voltage value) of the second sensing resistor 2732 (e.g., 2830 in FIG. 28). For example, while power is provided from the second battery 2722 to the second load 2702, the electronic device 1900 may lower the gate voltage provided to the second FET 2712 (e.g., the discharging FET 2863 in FIG. 28), based on the current (e.g., discharging current) of the second sensing resistor 2732 (e.g., 2830 in FIG. 28) being greater than a reference current. While power is provided from the second battery 2722 to the second load 2702, the electronic device 1900 may control the fifth FET 2715 to operate as a bypass.

Referring to FIGS. 27, 28, 33, and 34, according to various embodiments, the electronic device 1900 may include a third wire 3383 that electrically connects the third load 2703 and the third connector 3331 of the third housing 1930. The third wire 3383 may be disposed in the third housing 1930. The third wire 3383 may be part of a third discharging path 3493. Power provided from the third battery 2723 may be provided to the third load 2703 through the third protection circuit 3332, the third connector 3331, and the third wire 3383. Power provided from the third battery 2723 may be provided to the third load 2703 through the third FET 2713 and the sixth FET 2716. The electronic device 1900 (e.g., controller 2740) may control the third FET 2713 (e.g., the discharging FET 2863 in FIG. 28) to provide power (e.g., discharge power) from the third battery 2723 to the third load 2703 through the third discharging path 3493. While power is provided from the third battery 2723 to the third load 2703, the electronic device 1900 may control the third FET 2713 (e.g., the discharging FET 2863 in FIG. 28), based on the sensing value (e.g., current value or voltage value) of the third sensing resistor 2733 (e.g., 2830 in FIG. 28) of the third protection circuit 3332. The electronic device 1900 may control the gate voltage provided to the third FET 2713 (e.g., the discharging FET 2863 in FIG. 28), based on the sensing value (e.g., current value or voltage value) of the third sensing resistor 2733 (e.g., 2830 in FIG. 28). For example, while power is provided from the third battery 2723 to the third load 2703, the electronic device 1900 may lower the gate voltage provided to the third FET 2713 (e.g., the discharging FET 2863 in FIG. 28), based on the current (e.g., discharging current) of the third sensing resistor 2733 (e.g., 2830 in FIG. 28) being greater than a reference current. While power is provided from the third battery 2723 to the third load 2703, the electronic device 1900 may control the fifth FET 2715 to operate as a bypass.

FIG. 35 is a block diagram of an N-order foldable electronic device, according to an embodiment of the disclosure.

According to an embodiment, the electronic device 3500 in FIG. 35 may be an N-order foldable device.

FIG. 35 may be understood by those skilled in the art with reference to the embodiments in FIGS. 2 to 34, and thus redundant descriptions will be omitted.

The embodiment in FIG. 35 may be described with reference to the embodiment in FIG. 31. For example, the first housing 3510, the second housing 3520, and the third housing 3530 in FIG. 35 may correspond to the first housing 1910, the second housing 1920, and the third housing 1930 in FIG. 31, respectively. According to an embodiment, the electronic device 3500 may include a fourth housing 3540. The fourth housing 3540 may form the back surface (e.g., the lowermost surface in contact with the ground) when the electronic device 3500 is in a fully folded state. According to an embodiment, the electronic device 3500 may also include a fifth housing 3550, a sixth housing 3560, and an N^{th} housing 3570.

According to an embodiment, the electronic device 3500 may include a first housing 3510 including a first battery 3515, a first protection circuit 3514, a first connector 3513, a second connector 3516, a first wire 3561, and a first load 3512.

According to an embodiment, the electronic device 3500 may include a second housing 3520 including a power management circuit 3509 (e.g., an IF PMIC), a first charging circuit 3501, a second charging circuit 3527, a second battery 3525, a second protection circuit 3524, a third connector 3523, a fourth connector 3526, a second wire 3562, and a second load 3522.

According to an embodiment, the electronic device 3500 may include a third housing 3530 including a third battery 3535, a third protection circuit 3534, a fifth connector 3533, a sixth connector 3536, a third wire 3563, and a third load 3532.

According to an embodiment, the electronic device 3500 may include a fourth housing 3540 including a third charging circuit 3502, a wireless charging circuit 3508, a fourth battery 3545, a fourth protection circuit 3544, a seventh connector 3543, an eighth connector 3546, a fourth wire 3564, and a fourth load 3542.

According to an embodiment, the electronic device 3500 may receive power from an external power source (e.g., a wired charging device or a wireless charging device). For example, the electronic device 3500 may receive power from an external power source through a terminal (e.g., a USB terminal). The electronic device 3500 may include an FPCB 3571 that electrically connects the terminal (e.g., a USB terminal) of the second housing 3520 with the power management circuit 3509 and/or the first charging circuit 3501 of the second substrate 3521.

According to an embodiment, the electronic device 3500 may include a first FPCB 3581 that electrically connects the components of the first substrate 3511 of the first housing 3510 with the components of the second substrate 3521 of the second housing 3520.

According to an embodiment, the electronic device 3500 may include a second FPCB 3582 that electrically connects the components of the second substrate 3521 of the second housing 3520 with the components of the third substrate 3531 of the third housing 3530.

According to an embodiment, the electronic device 3500 may include a third FPCB 3583 that electrically connects the components of the third substrate 3531 of the third housing 3530 with the components of the fourth substrate 3541 of the fourth housing 3540.

According to an embodiment, the electronic device 3500 may include a fourth FPCB 3591 that electrically connects the components of the first housing 3510 with the components of the fifth substrate 3528 of the second housing 3520.

According to an embodiment, the electronic device 3500 may include a fifth FPCB 3593 that electrically connects the components of the third housing 3530 with the components of the fifth substrate 3528 of the second housing 3520.

According to an embodiment, the electronic device 3500 may include a sixth FPCB 3594 that electrically connects the components of the third housing 3530 with the components of the fourth housing 3540.

According to an embodiment, the electronic device 3500 may include a wire 3592 that electrically connects the second charging circuit 3527 and the fourth connector 3526 on the fifth substrate 3528 of the second housing 3520.

According to an embodiment, the first protection circuit 3514, the second protection circuit 3524, the third protection circuit 3534, and the fourth protection circuit 3544 may each include a base resistor, base FETs, a charging FET, a discharging FET, and a sensing resistor.

Based on the structure in FIG. 35, power may be provided from the charging circuits (e.g., the first charging circuit 3501, the second charging circuit 3527, the third charging circuit 3502, and the wireless charging circuit 3508) to the batteries (e.g., the first battery 3515, the second battery 3525, the third battery 3535, and the fourth battery 3545) respectively, via no FET of the power management circuit 3509.

The embodiments in FIGS. 36 to 40 may be applied to the electronic device 101 in FIG. 1, the electronic device 200 in FIG. 2, the electronic device 1900 in FIG. 19, and the electronic device 3500 in FIG. 35, respectively.

FIG. 36 is a flowchart of a method of operating an electronic device, according to an embodiment of the disclosure. FIG. 36 may be described with reference to the previously described embodiments.

At least some operations in FIG. 36 may be omitted. The operating sequence of operations in FIG. 36 may be changed. At least two of the operations in FIG. 36 may be performed in parallel. Operations other than those in FIG. 36 may be performed before, during, or after the execution of the operations in FIG. 36.

Referring to FIG. 36, in operation 3601, according to an embodiment, the electronic device (e.g., 101, 200, 1900, 3500) (e.g., controller (e.g., 120, 1160, 2740)) may identify the discharging current of the batteries (e.g., 1141, 1142, 1143 in FIG. 11, 2721, 2722, 2723 in FIG. 27, or 3515, 3525, 3535, 3545 in FIG. 35), based on the sensing value of the sensing resistors (e.g., 1131, 1132, 1133 in FIG. 11, 2731, 2732, 2733 in FIG. 27, or the sensing resistors included in the first protection circuit 3514, the second protection circuit 3524, the third protection circuit 3534, and the fourth protection circuit 3544 in FIG. 35) of each housing (e.g., 210, 220, 230 in FIG. 2, 1910, 1920, 1930 in FIG. 19, or 3510, 3520, 3530, 3540, 3550, 3560, 3570 in FIG. 35).

In operation 3603, according to an embodiment, the electronic device (e.g., 101, 200, 1900, 3500) (e.g., controller (e.g., 120, 1160, 2740)) may identify, among the discharging currents identified, in operation 3601, a current exceeding a reference current.

In operation 3605, according to an embodiment, the electronic device (e.g., 101, 200, 1900, 3500) (e.g., controller (e.g., 120, 1160, 2740)) may, based on the result of the identification in operation 3603, lower the gate voltage provided to the corresponding discharging FET (e.g., at least one of 1151, 1152, 1153 in FIG. 11, 2711, 2712, 2713 in FIG. 27, or the discharging FETs in FIG. 35) so as to control (e.g., reduce) the discharging current of at least one battery (e.g., at least one of 1141, 1142, 1143 in FIG. 11, 2721, 2722, 2723 in FIG. 27, or 3515, 3525, 3535, 3545 in FIG. 35) corresponding to the discharging current exceeding the reference current.

According to an embodiment, the electronic device (e.g., 101, 200, 1900, 3500) (e.g., controller (e.g., 120, 1160, 2740)) may, based on the result of the identification in operation 3603, increase the gate voltage provided to the corresponding discharging FET (e.g., at least one of 1151, 1152, 1153 in FIG. 11, 2711, 2712, 2713 in FIG. 27, or the discharging FETs in FIG. 35) so as to control (e.g., increase) the discharging current of at least one battery (e.g., at least one of 1141, 1142, 1143 in FIG. 11, 2721, 2722, 2723 in FIG. 27, or 3515, 3525, 3535, 3545 in FIG. 35) corresponding to a discharging current equal to or less than the reference current.

FIG. 37 is a flowchart of a method of operating an electronic device, according to an embodiment of the disclosure. FIG. 37 may be described with reference to the previously described embodiments.

At least some operations in FIG. 37 may be omitted. The operating sequence of operations in FIG. 37 may be changed. At least two of the operations in FIG. 37 may be performed in parallel. Operations other than those in FIG. 37 may be performed before, during, or after the execution of the operations in FIG. 37.

Referring to FIG. 37, in operation 3701, according to an embodiment, the electronic device (e.g., 101, 200, 1900, 3500) (e.g., controller (e.g., 120, 1160, 2740)) may identify the temperature of batteries (e.g., 1141, 1142, 1143 in FIG. 11, 2721, 2722, 2723 in FIG. 27, or 3515, 3525, 3535, 3545 in FIG. 35) of each housing (e.g., 210, 220, 230 in FIG. 2, 1910, 1920, 1930 in FIG. 19, or 3510, 3520, 3530, 3540, 3550, 3560, 3570 in FIG. 35) by using a sensor (e.g., a temperature sensor included in the sensor module 176 in FIG. 1). For example, the electronic device (e.g., 101, 200, 1900, 3500) (e.g., controller (e.g., 120, 1160, 2740)) may identify at least one battery (e.g., at least one of 1141, 1142, 1143 in FIG. 11, 2721, 2722, 2723 in FIG. 27, or 3515, 3525, 3535, 3545 in FIG. 35) with a temperature equal to or higher than a reference temperature.

In operation 3703, according to an embodiment, the electronic device (e.g., 101, 200, 1900, 3500) (e.g., controller (e.g., 120, 1160, 2740)) may, based on the temperature identified in operation 3701, lower the gate voltage provided to a corresponding charging FET (e.g., at least one of 1154, 1155, 1156 in FIG. 11, 2714, 2715, 2716 in FIG. 27, or the charging FETs in FIG. 35) or discharging FET (e.g., at least one of 1151, 1152, 1153 in FIG. 11, 2711, 2712, 2713 in FIG. 27, or the discharging FETs in FIG. 35) so as to control (e.g., reduce) the charging current or discharging current of at least one battery (e.g., at least one of 1141, 1142, 1143 in FIG. 11, 2721, 2722, 2723 in FIG. 27, or 3515, 3525, 3535, 3545 in FIG. 35) with a temperature equal to or higher than the reference temperature.

According to an embodiment, the electronic device (e.g., 101, 200, 1900, 3500) (e.g., controller (e.g., 120, 1160, 2740)) may, based on the temperature identified in operation 3701, increase the gate voltage provided to a corresponding charging FET (e.g., at least one of 1154, 1155, 1156 in FIG. 11, 2714, 2715, 2716 in FIG. 27, or the charging FETs in FIG. 35) or discharging FET (e.g., at least one of 1151, 1152, 1153 in FIG. 11, 2711, 2712, 2713 in FIG. 27, or the discharging FETs in FIG. 35) so as to control (e.g., increase) the charging current or discharging current of at least one battery (e.g., at least one of 1141, 1142, 1143 in FIG. 11, 2721, 2722, 2723 in FIG. 27, or 3515, 3525, 3535, 3545 in FIG. 35) with a temperature less than the reference temperature.

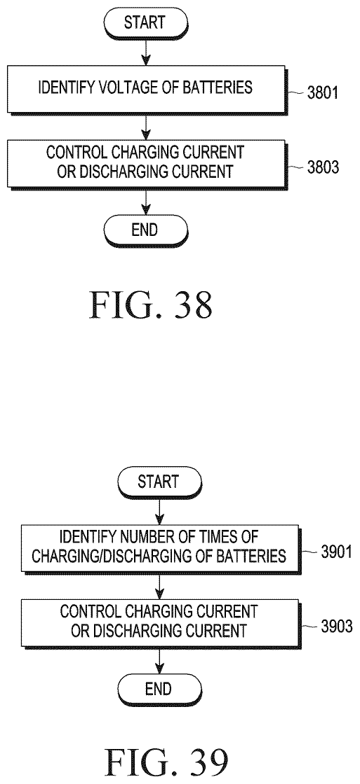

FIG. 38 is a flowchart of a method of operating an electronic device, according to an embodiment of the disclosure. FIG. 38 may be described with reference to the previously described embodiments.

At least some operations in FIG. 38 may be omitted. The operating sequence of operations in FIG. 38 may be changed. At least two of the operations in FIG. 38 may be performed in parallel. Operations other than those in FIG. 38 may be performed before, during, or after the execution of the operations in FIG. 38.

Referring to FIG. 38, in operation 3801, according to an embodiment, the electronic device (e.g., 101, 200, 1900, 3500) (e.g., controller (e.g., 120, 1160, 2740)) may identify the battery voltage of batteries (e.g., 1141, 1142, 1143 in FIG. 11, 2721, 2722, 2723 in FIG. 27, or 3515, 3525, 3535, 3545 in FIG. 35) of each housing (e.g., 210, 220, 230 in FIG. 2, 1910, 1920, 1930 in FIG. 19, or 3510, 3520, 3530, 3540, 3550, 3560, 3570 in FIG. 35). For example, the electronic device (e.g., 101, 200, 1900, 3500) (e.g., controller (e.g., 120, 1160, 2740)) may identify at least one battery (e.g., at least one of 1141, 1142, 1143 in FIG. 11, 2721, 2722, 2723 in FIG. 27, or 3515, 3525, 3535, 3545 in FIG. 35) with a battery voltage equal to or higher than a reference voltage.

In operation 3803, according to an embodiment, the electronic device (e.g., 101, 200, 1900, 3500) (e.g., controller (e.g., 120, 1160, 2740)) may, based on the battery voltage identified in operation 3801, lower the gate voltage provided to a corresponding charging FET (e.g., at least one of 1154, 1155, 1156 in FIG. 11, 2714, 2715, 2716 in FIG. 27, or the charging FETs in FIG. 35) or may increase the gate voltage provided to a corresponding discharging FET (e.g., at least one of 1151, 1152, 1153 in FIG. 11, 2711, 2712, 2713 in FIG. 27, or the discharging FETs in FIG. 35) so as to control (e.g., reduce) the charging current or to control (e.g., increase) the discharging current of at least one battery (e.g., at least one of 1141, 1142, 1143 in FIG. 11, 2721, 2722, 2723 in FIG. 27, or 3515, 3525, 3535, 3545 in FIG. 35) with a battery voltage equal to or higher than the reference voltage.

According to an embodiment, the electronic device (e.g., 101, 200, 1900, 3500) (e.g., controller (e.g., 120, 1160, 2740)) may, based on the battery voltage identified in operation 3801, increase the gate voltage provided to a corresponding charging FET (e.g., at least one of 1154, 1155, 1156 in FIG. 11, 2714, 2715, 2716 in FIG. 27, or the charging FETs in FIG. 35) or may lower the gate voltage provided to a corresponding discharging FET (e.g., at least one of 1151, 1152, 1153 in FIG. 11, 2711, 2712, 2713 in FIG. 27, or the discharging FETs in FIG. 35) so as control (e.g., increase) the charging current or control (e.g., reduce) the discharging current of at least one battery (e.g., at least one of 1141, 1142, 1143 in FIG. 11, 2721, 2722, 2723 in FIG. 27, or 3515, 3525, 3535, 3545 in FIG. 35) with a battery voltage less than the reference voltage.

FIG. 39 is a flowchart of a method of operating an electronic device, according to an embodiment of the disclosure. FIG. 39 may be described with reference to the previously described embodiments.

At least some operations in FIG. 39 may be omitted. The sequence of operations in FIG. 39 may be changed. At least two of the operations in FIG. 39 may be performed in parallel. Operations other than those in FIG. 39 may be performed before, during, or after the execution of the operations in FIG. 39.

Referring to FIG. 39, in operation 3901, according to an embodiment, the electronic device (e.g., 101, 200, 1900, 3500) (e.g., controller (e.g., 120, 1160, 2740)) may identify the number of times of charging/discharging of batteries (e.g., 1141, 1142, 1143 in FIG. 11, 2721, 2722, 2723 in FIG. 27, or 3515, 3525, 3535, 3545 in FIG. 35) of each housing (e.g., 210, 220, 230 in FIG. 2, 1910, 1920, 1930 in FIG. 19, or 3510, 3520, 3530, 3540, 3550, 3560, 3570 in FIG. 35). For example, the electronic device (e.g., 101, 200, 1900, 3500) (e.g., controller (e.g., 120, 1160, 2740)) may identify at least one battery (e.g., at least one of 1141, 1142, 1143 in FIG. 11, 2721, 2722, 2723 in FIG. 27, or 3515, 3525, 3535, 3545 in FIG. 35), the number of times of charging/discharging of which is equal to or greater than a reference number of times.

In operation 3903, according to an embodiment, the electronic device (e.g., 101, 200, 1900, 3500) (e.g., controller (e.g., 120, 1160, 2740)) may, based on the number of times of charging/discharging identified in operation 3901, lower the gate voltage provided to a corresponding charging FET (e.g., at least one of 1154, 1155, 1156 in FIG. 11, 2714, 2715, 2716 in FIG. 27, or the charging FETs in FIG. 35) or may lower the gate voltage provided to a corresponding discharging FET (e.g., at least one of 1151, 1152, 1153 in FIG. 11, 2711, 2712, 2713 in FIG. 27, or the discharging FETs in FIG. 35) so as to control (e.g., reduce) the charging current or control (e.g., reduce) the discharging current of at least one battery (e.g., at least one of 1141, 1142, 1143 in FIG. 11, 2721, 2722, 2723 in FIG. 27, or 3515, 3525, 3535, 3545 in FIG. 35), the number of times of charging/discharging of which is equal to or greater than a reference number of times.

According to an embodiment, the electronic device (e.g., 101, 200, 1900, 3500) (e.g., controller (e.g., 120, 1160, 2740)) may, based on the number of times of charging/discharging identified in operation 3901, increase the gate voltage provided to a corresponding charging FET (e.g., at least one of 1154, 1155, 1156 in FIG. 11, 2714, 2715, 2716 in FIG. 27, or the charging FETs in FIG. 35) or may increase the gate voltage provided to a corresponding discharging FET (e.g., at least one of 1151, 1152, 1153 in FIG. 11, 2711, 2712, 2713 in FIG. 27, or the discharging FETs in FIG. 35) so as to control (e.g., increase) the charging current or control (e.g., increase) the discharging current of at least one battery (e.g., at least one of 1141, 1142, 1143 in FIG. 11, 2721, 2722, 2723 in FIG. 27, or 3515, 3525, 3535, 3545 in FIG. 35), the number of times of charging/discharging of which is less than the reference number of times.

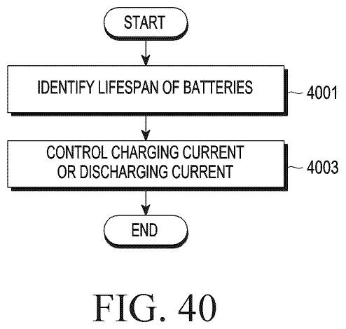

FIG. 40 is a flowchart of a method of operating an electronic device, according to an embodiment of the disclosure. FIG. 40 may be described with reference to the previously described embodiments.

At least some operations in FIG. 40 may be omitted. The operating sequence of operations in FIG. 40 may be changed. At least two of the operations in FIG. 40 may be performed in parallel. Operations other than those in FIG. 40 may be performed before, during, or after the execution of the operations in FIG. 40.

Referring to FIG. 40, in operation 4001, according to an embodiment, the electronic device (e.g., 101, 200, 1900, 3500) (e.g., controller (e.g., 120, 1160, 2740)) may identify the lifespan of the batteries (e.g., 1141, 1142, 1143 in FIG. 11, 2721, 2722, 2723 in FIG. 27, or 3515, 3525, 3535, 3545 in FIG. 35) of each housing (e.g., 210, 220, 230 in FIG. 2, 1910, 1920, 1930 in FIG. 19, or 3510, 3520, 3530, 3540, 3550, 3560, 3570 in FIG. 35). For example, the electronic device (e.g., 101, 200, 1900, 3500) (e.g., controller (e.g., 120, 1160, 2740)) may identify at least one battery (e.g., at least one of 1141, 1142, 1143 in FIG. 11, 2721, 2722, 2723 in FIG. 27, or 3515, 3525, 3535, 3545 in FIG. 35) with a lifespan equal to or longer than a reference lifespan.

In operation 4003, according to an embodiment, the electronic device (e.g., 101, 200, 1900, 3500) (e.g., controller (e.g., 120, 1160, 2740)) may, based on the battery lifespan identified in operation 4001, lower the gate voltage provided to a corresponding charging FET (e.g., at least one of 1154, 1155, 1156 in FIG. 11, 2714, 2715, 2716 in FIG. 27, or the charging FETs in FIG. 35) or may lower the gate voltage provided to a corresponding discharging FET (e.g., at least one of 1151, 1152, 1153 in FIG. 11, 2711, 2712, 2713 in FIG. 27, or the discharging FETs in FIG. 35) so as to control (e.g., reduce) the charging current or control (e.g., reduce) the discharging current of at least one battery (e.g., at least one of 1141, 1142, 1143 in FIG. 11, 2721, 2722, 2723 in FIG. 27, or 3515, 3525, 3535, 3545 in FIG. 35) with a lifespan equal to or longer than the reference lifespan.

According to an embodiment, the electronic device (e.g., 101, 200, 1900, 3500) (e.g., controller (e.g., 120, 1160, 2740)) may, based on the battery lifespan identified in operation 3901, increase the gate voltage provided to a corresponding charging FET (e.g., at least one of 1154, 1155, 1156 in FIG. 11, 2714, 2715, 2716 in FIG. 27, or the charging FETs in FIG. 35) or may increase the gate voltage provided to a corresponding discharging FET (e.g., at least one of 1151, 1152, 1153 in FIG. 11, 2711, 2712, 2713 in FIG. 27, or the discharging FETs in FIG. 35) so as to control (e.g., increase) the charging current or control (e.g., increase) the discharging current of at least one battery (e.g., at least one of 1141, 1142, 1143 in FIG. 11, 2721, 2722, 2723 in FIG. 27, or 3515, 3525, 3535, 3545 in FIG. 35) with a lifespan less than the reference lifespan.

Those skilled in the art will understand that the embodiments described in this specification may be applied interchangeably within the applicable scope. For example, those skilled in the art will understand that at least some operations of an embodiment described in this specification may be omitted and applied, or at least some operations of the embodiments may be applied interchangeably.

The technical objectives to be achieved in this document are not limited to the technical objectives mentioned above, and other technical objectives not mentioned herein may be clearly understood by those of ordinary skill in the art to which this document pertains from the description below.

The advantageous effects obtainable from the disclosure are not limited to the advantageous effects mentioned above, and other advantageous effects not mentioned herein may be clearly understood by those of ordinary skill in the art to which the disclosure pertains from the description below.

According to an embodiment, an electronic device 101; 1900 may include a first housing 1910 having a first charging circuit 2750, a first battery 2721; 2840, a first load 2701, and a first sensing resistor 2731; 2830 disposed therein, a second housing 1920 having a second battery 2722; 2840, a second load 2702, and a second sensing resistor 2732; 2830 disposed therein, a third housing 1930 having a third battery 2723; 2840, a third load 2703, and a third sensing resistor 2733; 2830 disposed therein, a first hinge 1940 rotatably connecting the first housing 1910 and the second housing 1920, a second hinge 1950 rotatably connecting the first housing 1910 and the third housing 1930, a flexible display 160; 1903 disposed in the first housing 1910, the second housing 1920, and the third housing 1930, memory 130 configured to store a program including instructions, and at least one controller 120; 2740. The instructions may be configured to, when executed by the at least one controller 120; 2740, cause the electronic device 101; 1900 to control the first discharge power provided from the first battery 2721; 2840 to the first load 2701, based on the first current of the first sensing resistor 2731; 2830. The instructions may be configured to, when executed by the at least one controller 120; 2740, cause the electronic device 101; 1900 to control the second discharge power provided from the second battery 2722; 2840 to the second load 2702, based on the second current of the second sensing resistor 2732; 2830. The instructions may be configured to, when executed by the at least one controller 120; 2740, cause the electronic device 101; 1900 to control the third discharge power provided from the third battery 2723; 2840 to the third load 2703, based on the third current of the third sensing resistor 2733; 2830.

According to an embodiment, the electronic device 101; 1900 may include a first field effect transistor (FET) 2711; 2863 disposed in the first housing 1910 and electrically connected to the first battery 2721; 2840, a second FET 2712; 2863 disposed in the second housing 1920 and electrically connected to the second battery 2722; 2840, and a third FET 2713; 2863 disposed in the third housing 1930 and electrically connected to the third battery 2723; 2840. The instructions may be configured to, when executed by the at least one controller 120; 2740, cause the electronic device 101; 1900 to control the first FET 2711; 2863 so as to control the first discharge power, based on the first current. The instructions may be configured to, when executed by the at least one controller 120; 2740, cause the electronic device 101; 1900 to control the second FET 2712; 2863 so as to control the second discharge power, based on the second current. The instructions may be configured to, when executed by the at least one controller 120; 2740, cause the electronic device 101; 1900 to control the third FET 2713; 2863 so as to control the third discharge power, based on the third current.

According to an embodiment, the electronic device 101; 1900 may include a first connector 2911; 3111 disposed in the first housing 1910 and configured to be electrically connected to the first battery 2721; 2840, and a first wire 2981; 3181 disposed in the first housing 1910 and configured to electrically connect the first connector 2911; 3111 with the first load 2701. The first discharge power may be transferred from the first battery 2721; 2840 to the first load 2701 through the first connector 2911; 3111 and the first wire 2981; 3181.

According to an embodiment, the electronic device 101; 1900 may include a fourth FET 2714; 2864 disposed in the first housing 1910 and configured to be electrically connected to the first battery 2721; 2840. The first connector 2911; 3111 may be configured to be electrically connected to the first charging circuit 2750. The instructions may be configured to, when executed by the at least one controller 120; 2740, cause the electronic device 101; 1900 to control the fourth FET 2714; 2864 so as to control the first charging power provided from the first charging circuit 2750 to the first battery 2721; 2840 through the first connector 2911; 3111, based on the first current of the first sensing resistor 2731; 2830.

According to an embodiment, the instructions may be configured to, when executed by the at least one controller 120; 2740, cause the electronic device 101; 1900 to control the fourth FET 2714; 2864 so as to operate as a bypass while the first discharge power is transferred from the first battery 2721; 2840 to the first load 2701. The instructions may be configured to, when executed by the at least one controller 120; 2740, cause the electronic device 101; 1900 to control the first FET 2711; 2863 so as to operate as a bypass while the first charging power is transferred from the first charging circuit 2750 to the first battery 2721; 2840.

According to an embodiment, the electronic device 101; 1900 may include a second connector 3112 disposed in the first housing 1910 and configured to be electrically connected to the first battery 2721; 2840, and a second charging circuit 3150 disposed in the first housing 1910. The second connector 3112 may be configured to be electrically connected to the second charging circuit 3150. The instructions may be configured to, when executed by the at least one controller 120; 2740, cause the electronic device 101; 1900 to control the fourth FET 2714; 2864 so as to control the second charging power provided from the second charging circuit 3150 to the first battery 2721; 2840 through the second connector 3112, based on the first current of the first sensing resistor 2731; 2830.

According to an embodiment, the instructions may be configured to, when executed by the at least one controller 120; 2740, cause the electronic device 101; 1900 to lower the gate voltage provided to the first FET 2711; 2863, based on the first current exceeding a first reference current.

According to an embodiment, the electronic device 101; 1900 may include a base resistor 2813 and base FETs 2811; 2828. The instructions may be configured to, when executed by the at least one controller 120; 2740, cause the electronic device 101; 1900 to control the first base FETs 2811; 2828 so as to block power provided to the first battery 2721; 2840 or power provided from the first battery 2721; 2840, based on the sensing value of the base resistor 2813.

According to an embodiment, the electronic device 101; 1900 may include a third connector 2921; 3121 disposed in the second housing 1920 and configured to be electrically connected to the second battery 2722; 2840, and a second wire 2982; 3182 disposed in the second housing 1920 and configured to electrically connect the second connector 3112 with the second load 2702. The second discharge power may be transferred from the second battery 2722; 2840 to the second load 2702 through the second connector 3112 and the second wire 2982; 3182.

According to an embodiment, the electronic device 101; 1900 may include a fifth FET 2715; 2864 disposed in the second housing 1920 and configured to be electrically connected to the second battery 2722; 2840, and a first FPCB 2991; 3191 configured to electrically connect the components of the first housing 1910 with the components of the second housing 1920. The third connector 2921; 3121 may be configured to be electrically connected to the first charging circuit 2750 through the first FPCB 2991; 3191. The instructions may be configured to, when executed by the at least one controller 120; 2740, cause the electronic device 101; 1900 to control the fifth FET 2715; 2864 so as to control the third charging power provided from the first charging circuit 2750 to the second battery 2722; 2840 through the third connector 2921; 3121, based on the second current of the second sensing resistor 2732; 2830.

According to an embodiment, the electronic device 101; 1900 may include a fourth connector 3122 disposed in the second housing 1920 and configured to be electrically connected to the second battery 2722; 2840, and a second FPCB 3162 configured to electrically connect the components of the first housing 1910 with the components of the second housing 1920. The fourth connector 3122 may be configured to be electrically connected to the second charging circuit 3150 through the second FPCB 3162. The instructions may be configured to, when executed by the at least one controller 120; 2740, cause the electronic device 101; 1900 to control the fifth FET 2715; 2864 so as to control the fourth charging power provided from the second charging circuit 3150 to the second battery 2722; 2840 through the fourth connector 3122, based on the second current of the second sensing resistor 2732; 2830.

According to an embodiment, a method of operating an electronic device 101; 1900 may include an operation of controlling, based on a first current of a first sensing resistor 2731; 2830 disposed in a first housing 1910 of the electronic device 101; 1900, first discharge power provided from a first battery 2721; 2840 of the electronic device 101; 1900 disposed in the first housing 1910 to a first load 2701 of the electronic device 101; 1900 disposed in the first housing 1910. The method may include an operation of controlling, based on a second current of a second sensing resistor 2732; 2830 disposed in a second housing 1920 of the electronic device 101; 1900, second discharge power provided from a second battery 2722; 2840 of the electronic device 101; 1900 disposed in the second housing 1920 to a second load 2702 of the electronic device 101; 1900 disposed in the second housing 1920. The method may include an operation of controlling, based on a third current of a third sensing resistor 2733; 2830 disposed in a third housing 1930 of the electronic device 101; 1900, third discharge power provided from a third battery 2723; 2840 of the electronic device 101; 1900 disposed in the third housing 1930 to a third load 2703 of the electronic device 101; 1900 disposed in the third housing 1930. The electronic device 101; 1900 may include a first charging circuit 2750 disposed in the first housing 1910, and a flexible display 160; 1903 disposed in the first housing 1910, the second housing 1920, and the third housing 1930.

According to an embodiment, the electronic device 101; 1900 may include a first hinge 1940 rotatably connecting the first housing 1910 and the second housing 1920, and a second hinge 1950 rotatably connecting the first housing 1910 and the third housing 1930.

According to an embodiment, the operation of controlling the first discharge power may include an operation of controlling a first field effect transistor (FET) 2711; 2863 disposed in the first housing 1910 and electrically connected to the first battery 2721; 2840. The operation of controlling the second discharge power may include an operation of controlling a second FET 2712; 2863 disposed in the second housing 1920 and electrically connected to the second battery 2722; 2840. The operation of controlling the third discharge power may include an operation of controlling a third FET 2713; 2863 disposed in the third housing 1930 and electrically connected to the third battery 2723; 2840.

According to an embodiment, the first discharge power may be transferred from the first battery 2721; 2840 to the first load 2701 through the first connector 2911; 3111 of the electronic device 101; 1900 and the first wire 2981; 3181 of the electronic device 101; 1900. The first connector 2911; 3111 may be disposed in the first housing 1910 and configured to be electrically connected to the first battery 2721; 2840. The first wire 2981; 3181 may be disposed in the first housing 1910 and configured to electrically connect the first connector 2911; 3111 with the first load 2701.

According to an embodiment, the method may include an operation of controlling a fourth FET 2714; 2864 of the electronic device 101; 1900 so as to control first charging power provided from the first charging circuit 2750 to the first battery 2721; 2840 through the first connector 2911; 3111, based on the first current of the first sensing resistor 2731; 2830. The fourth FET 2714; 2864 may be disposed in the first housing 1910 and configured to be electrically connected to the first battery 2721; 2840. The first connector 2911; 3111 may be configured to be electrically connected to the first charging circuit 2750.

According to an embodiment, the method may include an operation of controlling the fourth FET 2714; 2864 to operate as a bypass while the first discharge power is transferred from the first battery 2721; 2840 to the first load 2701. The method may include an operation of controlling the first FET 2711; 2863 to operate as a bypass while the first charging power is transferred from the first charging circuit 2750 to the first battery 2721; 2840.

According to an embodiment, the method may include an operation of controlling the fourth FET 2714; 2864 so as to control second charging power provided from the second charging circuit 3150 of the electronic device 101; 1900 to the first battery 2721; 2840 through the second connector 3112 of the electronic device 101; 1900, based on the first current of the first sensing resistor 2731; 2830. The second connector 3112 may be disposed in the first housing 1910 and configured to be electrically connected to the first battery 2721; 2840. The second charging circuit 3150 may be disposed in the first housing 1910. The second connector 3112 may be configured to be electrically connected to the second charging circuit 3150.

According to an embodiment, the method may include an operation of lowering a gate voltage provided to the first FET 2711; 2863, based on the first current exceeding a first reference current.

According to an embodiment, the method may include an operation of controlling first base FETs 2811; 2828 of the electronic device 101; 1900 so as to block power provided to the first battery 2721; 2840 or power provided from the first battery 2721; 2840, based on a sensing value regarding the base resistor 2813 of the electronic device 101; 1900.

According to an embodiment, the third connector 2921; 3121 of the electronic device 101; 1900 may be disposed in the second housing 1920 and configured to be electrically connected to the second battery 2722; 2840. The second wire 2982; 3182 of the electronic device 101; 1900 may be disposed in the second housing 1920 and configured to electrically connect the second connector 3112 with the second load 2702. The second discharge power may be transferred from the second battery 2722; 2840 to the second load 2702 through the second connector 3112 and the second wire 2982; 3182.

According to an embodiment, the fifth FET 2715; 2864 of the electronic device 101; 1900 may be disposed in the second housing 1920 and configured to be electrically connected to the second battery 2722; 2840. The first FPCB 2991; 3191 of the electronic device 101; 1900 may be configured to electrically connect components of the first housing 1910 with components of the second housing 1920. The third connector 2921; 3121 may be configured to be electrically connected to the first charging circuit 2750 through the first FPCB 2991; 3191. The method may include an operation of controlling the fifth FET 2715; 2864 so as to control third charging power provided from the first charging circuit 2750 to the second battery 2722; 2840 through the third connector 2921; 3121, based on the second current of the second sensing resistor 2732; 2830.

According to an embodiment, the fourth connector 3122 of the electronic device 101; 1900 may be disposed in the second housing 1920 and configured to be electrically connected to the second battery 2722; 2840. The second FPCB 3162 of the electronic device 101; 1900 may be configured to electrically connect components of the first housing 1910 with components of the second housing 1920. The fourth connector 3122 may be configured to be electrically connected to the second charging circuit 3150 through the second FPCB 3162. The method may include an operation of controlling the fifth FET 2715; 2864 so as to control fourth charging power provided from the second charging circuit 3150 to the second battery 2722; 2840 through the fourth connector 3122, based on the second current of the second sensing resistor 2732; 2830.

According to an embodiment, a computer-readable recording medium may store instructions configured to perform at least one operation by a controller 260 of an electronic device 101. The at least one operation may include an operation of controlling, based on a first current of a first sensing resistor 2731; 2830 disposed in a first housing 1910 of the electronic device 101; 1900, first discharge power provided from a first battery 2721; 2840 of the electronic device 101; 1900 disposed in the first housing 1910 to a first load 2701 of the electronic device 101; 1900 disposed in the first housing 1910. The at least one operation may include an operation of controlling, based on a second current of a second sensing resistor 2732; 2830 disposed in a second housing 1920 of the electronic device 101; 1900, second discharge power provided from a second battery 2722; 2840 of the electronic device 101; 1900 disposed in the second housing 1920 to a second load 2702 of the electronic device 101; 1900 disposed in the second housing 1920. The at least one operation may include an operation of controlling, based on a third current of a third sensing resistor 2733; 2830 disposed in a third housing 1930 of the electronic device 101; 1900, third discharge power provided from a third battery 2723; 2840 of the electronic device 101; 1900 disposed in the third housing 1930 to a third load 2703 of the electronic device 101; 1900 disposed in the third housing 1930. The electronic device 101; 1900 may include a first charging circuit 2750 disposed in the first housing 1910, and a flexible display 160; 1903 disposed in the first housing 1910, the second housing 1920, and the third housing 1930.

According to an embodiment, the electronic device 101; 1900 may include a first hinge 1940 rotatably connecting the first housing 1910 and the second housing 1920, and a second hinge 1950 rotatably connecting the first housing 1910 and the third housing 1930.

According to an embodiment, the operation of controlling the first discharge power may include an operation of controlling a first field effect transistor (FET) 2711; 2863 disposed in the first housing 1910 and electrically connected to the first battery 2721; 2840. The operation of controlling the second discharge power may include an operation of controlling a second FET 2712; 2863 disposed in the second housing 1920 and electrically connected to the second battery 2722; 2840. The operation of controlling the third discharge power may include an operation of controlling a third FET 2713; 2863 disposed in the third housing 1930 and electrically connected to the third battery 2723; 2840.

According to an embodiment, the first discharge power may be transferred from the first battery 2721; 2840 to the first load 2701 through the first connector 2911; 3111 of the electronic device 101; 1900 and the first wire 2981; 3181 of the electronic device 101; 1900. The first connector 2911; 3111 may be disposed in the first housing 1910 and configured to be electrically connected to the first battery 2721; 2840. The first wire 2981; 3181 may be disposed in the first housing 1910 and configured to electrically connect the first connector 2911; 3111 with the first load 2701.

According to an embodiment, the at least one operation may include an operation of controlling a fourth FET 2714; 2864 of the electronic device 101; 1900 so as to control first charging power provided from the first charging circuit 2750 to the first battery 2721; 2840 through the first connector 2911; 3111, based on the first current of the first sensing resistor 2731; 2830. The fourth FET 2714; 2864 may be disposed in the first housing 1910 and configured to be electrically connected to the first battery 2721; 2840. The first connector 2911; 3111 may be configured to be electrically connected to the first charging circuit 2750.

According to an embodiment, the at least one operation may include an operation of controlling the fourth FET 2714; 2864 to operate as a bypass while the first discharge power is transferred from the first battery 2721; 2840 to the first load 2701. The at least one operation may include an operation of controlling the first FET 2711; 2863 to operate as a bypass while the first charging power is transferred from the first charging circuit 2750 to the first battery 2721; 2840.

According to an embodiment, the at least one operation may include an operation of controlling the fourth FET 2714; 2864 so as to control second charging power provided from a second charging circuit 3150 of the electronic device 101; 1900 to the first battery 2721; 2840 through a second connector 3112 of the electronic device 101; 1900, based on the first current of the first sensing resistor 2731; 2830. The second connector 3112 may be disposed in the first housing 1910 and configured to be electrically connected to the first battery 2721; 2840. The second charging circuit 3150 may be disposed in the first housing 1910. The second connector 3112 may be configured to be electrically connected to the second charging circuit 3150.

According to an embodiment, the at least one operation may include an operation of lowering the gate voltage provided to the first FET 2711; 2863, based on the first current exceeding a first reference current.

According to an embodiment, the at least one operation may include an operation of controlling first base FETs 2811; 2828 of the electronic device 101; 1900 so as to block power provided to the first battery 2721; 2840 or power provided from the first battery 2721; 2840, based on a sensing value regarding a base resistor 2813 of the electronic device 101; 1900.

According to an embodiment, the third connector 2921; 3121 of the electronic device 101; 1900 may be disposed in the second housing 1920 and configured to be electrically connected to the second battery 2722; 2840. The second wire 2982; 3182 of the electronic device 101; 1900 may be disposed in the second housing 1920 and configured to electrically connect the second connector 3112 with the second load 2702. The second discharge power may be transferred from the second battery 2722; 2840 to the second load 2702 through the second connector 3112 and the second wire 2982; 3182.

According to an embodiment, the fifth FET 2715; 2864 of the electronic device 101; 1900 may be disposed in the second housing 1920 and configured to be electrically connected to the second battery 2722; 2840. The first FPCB 2991; 3191 of the electronic device 101; 1900 may be configured to electrically connect components of the first housing 1910 with components of the second housing 1920. The third connector 2921; 3121 may be configured to be electrically connected to the first charging circuit 2750 through the first FPCB 2991; 3191. The at least one operation may include an operation of controlling the fifth FET 2715; 2864 so as to control third charging power provided from the first charging circuit 2750 to the second battery 2722; 2840 through the third connector 2921; 3121, based on the second current of the second sensing resistor 2732; 2830.

According to an embodiment, the fourth connector 3122 of the electronic device 101; 1900 may be disposed in the second housing 1920 and configured to be electrically connected to the second battery 2722; 2840. The second FPCB 3162 of the electronic device 101; 1900 may be configured to electrically connect components of the first housing 1910 with components of the second housing 1920. The fourth connector 3122 may be configured to be electrically connected to the second charging circuit 3150 through the second FPCB 3162. The at least one operation may include an operation of controlling the fifth FET 2715; 2864 so as to control fourth charging power provided from the second charging circuit 3150 to the second battery 2722; 2840 through the fourth connector 3122, based on the second current of the second sensing resistor 2732; 2830.

According to an embodiment, an electronic device 101, 200 may include a first housing 210 having a first charging circuit 1105, a first battery 1141; 1240, a first load 1101, and a first sensing resistor 1131; 1230 disposed therein, a second housing 220 having a second battery 1142; 1240, a second load 1102, and a second sensing resistor 1132; 1230 disposed therein, a third housing 230 having a third battery 1143; 1240, a third load 1103, and a third sensing resistor 1133; 1230 disposed therein, a first hinge 240 rotatably connecting the first housing 210 and the second housing 220, a second hinge 250 rotatably connecting the second housing 220 and the third housing 230, a flexible display 160; 203 disposed in the first housing 210, the second housing 220, and the third housing 230, memory 130 configured to store a program including instructions, and at least one controller 120; 1160. The instructions may be configured to, when executed by the at least one controller 120; 1160, cause the electronic device 101, 200 to control first discharge power provided from the first battery 1141; 1240 to the first load 1101, based on a first current of the first sensing resistor 1131; 1230. The instructions may be configured to, when executed by the at least one controller 120; 1160, cause the electronic device 101, 200 to control second discharge power provided from the second battery 1142; 1240 to the second load 1102, based on a second current of the second sensing resistor 1132; 1230. The instructions may be configured to, when executed by the at least one controller 120; 1160, cause the electronic device 101, 200 to control third discharge power provided from the third battery 1143; 1240 to the third load 1103, based on a third current of the third sensing resistor 1133; 1230.

According to an embodiment, the electronic device 101, 200 may include a first field effect transistor (FET) 1151; 1263 disposed in the first housing 210 and electrically connected to the first battery 1141; 1240, a second FET 1152; 1263 disposed in the second housing 220 and electrically connected to the second battery 1142; 1240, and a third FET 1153; 1263 disposed in the third housing 230 and electrically connected to the third battery 1143; 1240. The instructions may be configured to, when executed by the at least one controller 120; 1160, cause the electronic device 101, 200 to control the first FET 1151; 1263 so as to control the first discharge power, based on the first current. The instructions may be configured to, when executed by the at least one controller 120; 1160, cause the electronic device 101, 200 to control the second FET 1152; 1263 so as to control the second discharge power, based on the second current. The instructions may be configured to, when executed by the at least one controller 120; 1160, cause the electronic device 101, 200 to control the third FET 1153; 1263 so as to control the third discharge power, based on the third current.

According to an embodiment, the electronic device 101, 200 may include a first connector 1311; 1511 disposed in the first housing 210 and configured to be electrically connected to the first battery 1141; 1240, and a first wire 1381; 1581 disposed in the first housing 210 and configured to electrically connect the first connector 1311; 1511 with the first load 1101. The first discharge power may be transferred from the first battery 1141; 1240 to the first load 1101 through the first connector 1311; 1511 and the first wire 1381; 1581.

According to an embodiment, the electronic device 101, 200 may include a fourth FET 1154; 1264 disposed in the first housing 210 and configured to be electrically connected to the first battery 1141; 1240. The first connector 1311; 1511 may be configured to be electrically connected to the first charging circuit 1105. The instructions may be configured to, when executed by the at least one controller 120; 1160, cause the electronic device 101, 200 to control the fourth FET 1154; 1264 so as to control first charging power provided from the first charging circuit 1105 to the first battery 1141; 1240 through the first connector 1311; 1511, based on the first current of the first sensing resistor 1131; 1230.

According to an embodiment, the electronic device 101, 200 may include a second connector 1321; 1521 disposed in the second housing 220 and configured to be electrically connected to the second battery 1142; 1240, and a second wire 1382; 1582 disposed in the second housing 220 and configured to electrically connect the second connector 1321; 1521 with the second load 1102. The second discharge power may be transferred from the second battery 1142; 1240 to the second load 1102 through the second connector 1321; 1521 and the second wire 1382; 1582.

According to an embodiment, the electronic device 101, 200 may include a fifth FET 1155; 1264 disposed in the second housing 220 and configured to be electrically connected to the second battery 1142; 1240, a third connector 1522 disposed in the second housing 220 and configured to be electrically connected to the second battery 1142; 1240, and a first flexible printed circuit board (FPCB) 1591 configured to electrically connect components of the first housing 210 with components of the second housing 220. The third connector 1522 may be configured to be electrically connected to the first charging circuit 1105 through the first FPCB 1591. The instructions may be configured to, when executed by the at least one controller 120; 1160, cause the electronic device 101, 200 to control the fifth FET 1155; 1264 so as to control second charging power provided from the first charging circuit 1105 to the second battery 1142; 1240 through the third connector 1522, based on the second current of the second sensing resistor 1132; 1230.

According to an embodiment, a method of operating an electronic device 101, 200 may include an operation of controlling, based on a first current of a first sensing resistor 1131; 1230 disposed in a first housing 210 of the electronic device 101, 200, first discharge power provided from a first battery 1141; 1240 disposed in the first housing 210 to a first load 1101 disposed in the first housing 210. The method may include an operation of controlling, based on a second current of a second sensing resistor 1132; 1230 disposed in a second housing 220 of the electronic device 101, 200, second discharge power provided from a second battery 1142; 1240 disposed in the second housing 220 to a second load 1102 disposed in the second housing 220. The method may include an operation of controlling, based on a third current of a third sensing resistor 1133; 1230 disposed in a third housing 230 of the electronic device 101, 200, third discharge power provided from a third battery 1143; 1240 disposed in the third housing 230 to a third load 1103 disposed in the third housing 230. The electronic device 101, 200 may include a first charging circuit 1105 disposed in the first housing 210, and a flexible display 160; 203 disposed in the first housing 210, the second housing 220, and the third housing 230.

According to an embodiment, the electronic device 101; 200 may include a first hinge 240 rotatably connecting the first housing 210 and the second housing 220, and a second hinge 250 rotatably connecting the first housing 210 and the third housing 230.

According to an embodiment, the operation of controlling the first discharge power may include an operation of controlling a first field effect transistor (FET) 1151; 1263 disposed in the first housing 210 and electrically connected to the first battery 1141; 1240. The operation of controlling the second discharge power may include an operation of controlling a second FET 1152; 1263 disposed in the second housing 220 and electrically connected to the second battery 1142; 1240. The operation of controlling the third discharge power may include an operation of controlling a third FET 1153; 1263 disposed in the third housing 230 and electrically connected to the third battery 1143; 1240.

According to an embodiment, the electronic device 101, 200 may include a first connector 1311; 1511 disposed in the first housing 210 and configured to be electrically connected to the first battery 1141; 1240, and a first wire 1381; 1581 disposed in the first housing 210 and configured to electrically connect the first connector 1311; 1511 with the first load 1101. The first discharge power may be transferred from the first battery 1141; 1240 to the first load 1101 through the first connector 1311; 1511 and the first wire 1381; 1581.

According to an embodiment, the electronic device 101, 200 may include a fourth FET 1154; 1264 disposed in the first housing 210 and configured to be electrically connected to the first battery 1141; 1240. The first connector 1311; 1511 may be configured to be electrically connected to the first charging circuit 1105. The method may include an operation of controlling the fourth FET 1154; 1264 so as to control first charging power provided from the first charging circuit 1105 to the first battery 1141; 1240 through the first connector 1311; 1511, based on the first current of the first sensing resistor 1131; 1230.

According to an embodiment, the electronic device 101, 200 may include a second connector 1321; 1521 disposed in the second housing 220 and configured to be electrically connected to the second battery 1142; 1240, and a second wire 1382; 1582 disposed in the second housing 220 and configured to electrically connect the second connector 1321; 1521 with the second load 1102. The second discharge power may be transferred from the second battery 1142; 1240 to the second load 1102 through the second connector 1321; 1521 and the second wire 1382; 1582.

According to an embodiment, the electronic device 101, 200 may include a fifth FET 1155; 1264 disposed in the second housing 220 and configured to be electrically connected to the second battery 1142; 1240, a third connector 1522 disposed in the second housing 220 and configured to be electrically connected to the second battery 1142; 1240, and a first flexible printed circuit board (FPCB) 1591 configured to electrically connect components of the first housing 210 with components of the second housing 220. The third connector 1522 may be configured to be electrically connected to the first charging circuit 1105 through the first FPCB 1591. The method may include an operation of controlling the fifth FET 1155; 1264 so s to control second charging power provided from the first charging circuit 1105 to the second battery 1142; 1240 through the third connector 1522, based on the second current of the second sensing resistor 1132; 1230.

According to an embodiment, a non-transitory computer-readable recording medium may store instructions configured to perform at least one operation by a controller 260 of an electronic device 101. The at least one operation may include an operation of controlling, based on a first current of a first sensing resistor 1131; 1230 disposed in a first housing 210 of the electronic device 101, 200, first discharge power provided from a first battery 1141; 1240 disposed in the first housing 210 to a first load 1101 disposed in the first housing 210. The at least one operation may include an operation of controlling, based on a second current of a second sensing resistor 1132; 1230 disposed in a second housing 220 of the electronic device 101, 200, second discharge power provided from a second battery 1142; 1240 disposed in the second housing 220 to a second load 1102 disposed in the second housing 220. The at least one operation may include an operation of controlling, based on a third current of a third sensing resistor 1133; 1230 disposed in a third housing 230 of the electronic device 101, 200, third discharge power provided from a third battery 1143; 1240 disposed in the third housing 230 to a third load 1103 disposed in the third housing 230. The electronic device 101, 200 may include a first charging circuit 1105 disposed in the first housing 210, and a flexible display 160; 203 disposed in the first housing 210, the second housing 220, and the third housing 230.

According to an embodiment, the electronic device 101; 200 may include a first hinge 240 rotatably connecting the first housing 210 and the second housing 220, and a second hinge 250 rotatably connecting the first housing 210 and the third housing 230.

According to an embodiment, the operation of controlling the first discharge power may include an operation of controlling a first field effect transistor (FET) 1151; 1263 disposed in the first housing 210 and electrically connected to the first battery 1141; 1240. The operation of controlling the second discharge power may include an operation of controlling a second FET 1152; 1263 disposed in the second housing 220 and electrically connected to the second battery 1142; 1240. The operation of controlling the third discharge power may include an operation of controlling a third FET 1153; 1263 disposed in the third housing 230 and electrically connected to the third battery 1143; 1240.

According to an embodiment, the electronic device 101, 200 may include a first connector 1311; 1511 disposed in the first housing 210 and configured to be electrically connected to the first battery 1141; 1240, and a first wire 1381; 1581 disposed in the first housing 210 and configured to electrically connect the first connector 1311; 1511 with the first load 1101. The first discharge power may be transferred from the first battery 1141; 1240 to the first load 1101 through the first connector 1311; 1511 and the first wire 1381; 1581.

According to an embodiment, the electronic device 101, 200 may include a fourth FET 1154; 1264 disposed in the first housing 210 and configured to be electrically connected to the first battery 1141; 1240. The first connector 1311; 1511 may be configured to be electrically connected to the first charging circuit 1105. The at least one operation may include an operation of controlling the fourth FET 1154; 1264 so as to control first charging power provided from the first charging circuit 1105 to the first battery 1141; 1240 through the first connector 1311; 1511, based on the first current of the first sensing resistor 1131; 1230.

According to an embodiment, the electronic device 101, 200 may include a second connector 1321; 1521 disposed in the second housing 220 and configured to be electrically connected to the second battery 1142; 1240, and a second wire 1382; 1582 disposed in the second housing 220 and configured to electrically connect the second connector 1321; 1521 with the second load 1102. The second discharge power may be transferred from the second battery 1142; 1240 to the second load 1102 through the second connector 1321; 1521 and the second wire 1382; 1582.

According to an embodiment, the electronic device 101, 200 may include a fifth FET 1155; 1264 disposed in the second housing 220 and configured to be electrically connected to the second battery 1142; 1240, a third connector 1522 disposed in the second housing 220 and configured to be electrically connected to the second battery 1142; 1240, and a first flexible printed circuit board (FPCB) 1591 configured to electrically connect components of the first housing 210 with components of the second housing 220. The third connector 1522 may be configured to be electrically connected to the first charging circuit 1105 through the first FPCB 1591. The at least one operation may include an operation of controlling the fifth FET 1155; 1264 so as to control second charging power provided from the first charging circuit 1105 to the second battery 1142; 1240 through the third connector 1522, based on the second current of the second sensing resistor 1132; 1230.

According to an embodiment, the electronic device 101, 200, 1900, 3500 may improve the charging/discharge power efficiency by optimizing charging and discharging systems. The electronic device 101, 200, 1900, 3500 may extend the battery lifespan by controlling charging/discharging currents of individual batteries mounted in multiple housings through sensing resistors and current control FETs provided for each housing. The electronic device 101, 200, 1900, 3500 may reduce the mounting area of FPCBs between multiple housings by introducing a bidirectional protection circuit structure through multiple battery connectors, and minimize noise interference that may occur due to power wiring.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program) including one or more instructions that are stored in a storage medium that is readable by a machine. For example, a processor (e.g., the controller) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a first housing in which a first charging circuit, a first battery, a first load, and a first sensing resistor are disposed;
a second housing in which a second battery, a second load, and a second sensing resistor are disposed;
a third housing in which a third battery, a third load, and a third sensing resistor are disposed;
a first hinge rotatably connecting the first housing and the second housing;
a second hinge rotatably connecting the first housing and the third housing;
a flexible display disposed on the first housing, the second housing, and the third housing;
memory configured to store a program containing instructions; and
at least one processor,
wherein the instructions are configured to, when executed by the at least one processor individually or collectively, cause the electronic device to:
based on a first current of the first sensing resistor, control a first discharge power provided from the first battery to the first load,
based on a second current of the second sensing resistor, control a second discharge power provided from the second battery to the second load, and
based on a third current of the third sensing resistor, control a third discharge power provided from the third battery to the third load.

2. The electronic device of claim 1, further comprising:
a first field effect transistor (FET) disposed in the first housing and configured to be electrically connected to the first battery;
a second FET disposed in the second housing and configured to be electrically connected to the second battery; and
a third FET disposed in the third housing and configured to be electrically connected to the third battery,
wherein the instructions are configured to, when executed by the at least one processor individually or collectively, cause the electronic device to:
based on the first current, control the first FET to control the first discharge power,
based on the second current, control the second FET to control the second discharge power, and
based on the third current, control the third FET to control the third discharge power.

3. The electronic device of claim 2, further comprising:
a first connector disposed in the first housing and configured to be electrically connected to the first battery; and
a first wire disposed in the first housing and configured to electrically connect the first connector and the first load,
wherein the first discharge power is provided from the first battery to the first load through the first connector and the first wire.

4. The electronic device of claim 3, further comprising:
a fourth FET disposed in the first housing and configured to be electrically connected to the first battery,
wherein the first connector is configured to be electrically connected to the first charging circuit, and
wherein the instructions are configured to, when executed by the at least one processor individually or collectively, cause the electronic device to:
based on the first current of the first sensing resistor, control the fourth FET to control a first charging power provided to the first battery from the first charging circuit through the first connector.

5. The electronic device of claim 4, wherein the instructions are configured to, when executed by the at least one processor individually or collectively, cause the electronic device to:
control the fourth FET to operate as a bypass while the first discharge power is provided from the first battery to the first load, and
control the first FET to operate as a bypass while the first charging power is provided from the first charging circuit to the first battery.

6. The electronic device of claim 4, further comprising:
a second connector disposed in the first housing and configured to be electrically connected to the first battery; and
a second charging circuit disposed in the first housing,
wherein the second connector is configured to be electrically connected to the second charging circuit, and
wherein the instructions are configured to, when executed by the at least one processor individually or collectively, cause the electronic device to:
based on the first current of the first sensing resistor, control the fourth FET to control a second charging power provided to the first battery from the second charging circuit through the second connector.

7. The electronic device of claim 2, wherein the instructions are configured to, when executed by the at least one processor individually or collectively, cause the electronic device to:
lower a gate voltage provided to the first FET, based on the first current exceeding a first reference current.

8. The electronic device of claim 1, further comprising:
a basic resistance and basic field effect transistor (FET)s,
wherein the instructions are configured to, when executed by the at least one processor individually or collectively, cause the electronic device to:
based on a sensed value of the basic resistance, control the basic FETs to cut-off power provided to the first battery or power provided from the first battery.

9. The electronic device of claim 1, further comprising:
a third connector disposed in the second housing and configured to be electrically connected to the second battery; and
a second wire disposed in the second housing and configured to electrically connect the second connector and the second load,
wherein the second discharge power is provided from the second battery to the second load through the second connector and the second wire.

10. The electronic device of claim 9, further comprising:
a fifth FET disposed in the second housing and configured to be electrically connected to the second battery; and
a first flexible printed circuit board (FPCB) configured to electrically connect a component of the first housing and a component of the second housing,
wherein the third connector is configured to be electrically connected to the first charging circuit through the first FPCB, and
wherein the instructions are configured to, when executed by the at least one processor individually or collectively, cause the electronic device to:
based on the second current of the second sensing resistor, control the fifth FET to control a third charging power provided to the second battery from the first charging circuit through the third connector.

11. The electronic device of claim 10, further comprising:
a fourth connector disposed in the second housing and configured to be electrically connected to the second battery; and
a second FPCB configured to electrically connect a component of the first housing and a component of the second housing,
wherein the fourth connector is configured to be electrically connected to the second charging circuit through the second FPCB, and
wherein the instructions are configured to, when executed by the at least one processor individually or collectively, cause the electronic device to:
based on the second current of the second sensing resistor, control the fifth FET to control the third charging power provided to the second battery from a fourth charging circuit through the fourth connector.

12. A method performed by an electronic device, the method comprising:
based on a first current of a first sensing resistor disposed in a first housing of the electronic device, controlling a first discharge power provided from a first battery of the electronic device disposed in the first housing to a first load of the electronic device disposed in the first housing;
based on a second current of a second sensing resistor disposed in a second housing of the electronic device, controlling a second discharge power provided from a second battery of the electronic device disposed in the second housing to a second load of the electronic device disposed in the second housing; and
based on a third current of a third sensing resistor disposed in a third housing of the electronic device, controlling a third discharge power provided from a third battery of the electronic device disposed in the third housing to a third load of the electronic device disposed in the third housing,
wherein the electronic device comprises:
a first charging circuit disposed in the first housing, and
a flexible display disposed in the first housing, the second housing, and the third housing.

13. The method of claim 12, wherein the electronic device comprises:
a first hinge rotatably connecting the first housing and the second housing; and
a second hinge rotatably connecting the first housing and the third housing.

14. The method of claim 12,
wherein the controlling of the first discharge power comprises controlling a first field effect transistor (FET) disposed in the first housing and electrically connected to the first battery,
wherein the controlling of the second discharge power comprises controlling a second FET disposed in the second housing and electrically connected to the second battery, and
wherein the controlling of the third discharge power comprises controlling a third FET disposed in the third housing and electrically connected to the third battery.

15. The method of claim 14,
wherein the first discharge power is transferred from the first battery to the first load through a first connector of the electronic device and a first wire of the electronic device,
wherein the first connector is disposed in the first housing and configured to be electrically connected to the first battery, and
wherein the first wire is disposed in the first housing and configured to electrically connect the first connector with the first load.

16. The method of claim 15, further comprising:
controlling a fourth FET of the electronic device so as to control a first charging power provided from the first charging circuit to the first battery through the first connector, based on the first current of the first sensing resistor,
wherein the fourth FET is disposed in the first housing and configured to be electrically connected to the first battery, and
wherein the first connector is configured to be electrically connected to the first charging circuit.

17. The method of claim 16, further comprising:
controlling the fourth FET to operate as a bypass while the first discharge power is transferred from the first battery to the first load; and
controlling the first FET to operate as a bypass while the first charging power is transferred from the first charging circuit to the first battery.

18. The method of claim 17, further comprising:
controlling the fourth FET so as to control a second charging power provided from the second charging circuit of the electronic device to the first battery through a second connector of the electronic device, based on the first current of the first sensing resistor,
wherein the second connector is disposed in the first housing and configured to be electrically connected to the first battery,
wherein the second charging circuit is disposed in the first housing, and
wherein the second connector is configured to be electrically connected to the second charging circuit.

19. One or more non-transitory computer-readable storage media storing one or more computer programs including computer-executable instructions configured to, when executed by at least one processor of an electronic device individually or collectively, cause the electronic device to perform operations, the operations comprising:
based on a first current of a first sensing resistor disposed in a first housing of the electronic device, controlling a first discharge power provided from a first battery of the electronic device disposed in the first housing to a first load of the electronic device disposed in the first housing;
based on a second current of a second sensing resistor disposed in a second housing of the electronic device, controlling a second discharge power provided from a second battery of the electronic device disposed in the second housing to a second load of the electronic device disposed in the second housing; and
based on a third current of a third sensing resistor disposed in a third housing of the electronic device, controlling a third discharge power provided from a third battery of the electronic device disposed in the third housing to a third load of the electronic device disposed in the third housing,
wherein the electronic device comprises:
a first charging circuit disposed in the first housing, and
a flexible display disposed in the first housing, the second housing, and the third housing.

20. The one or more non-transitory computer-readable storage media of claim 19,
wherein the controlling of the first discharge power comprises controlling a first field effect transistor (FET) disposed in the first housing and electrically connected to the first battery,
wherein the controlling of the second discharge power comprises controlling a second FET disposed in the second housing and electrically connected to the second battery, and
wherein the controlling of the third discharge power comprises controlling a third FET disposed in the third housing and electrically connected to the third battery.
